(19) United States
(12) Patent Application Publication
(10) Pub. No.: US 2026/0133493 A1
(43) Pub. Date: May 14, 2026

(54) RADIATION-SENSITIVE COMPOSITION, RESIST PATTERN FORMATION METHOD, POLYMER, AND METHOD FOR PRODUCING THE POLYMER, AND COMPOUND

(71) Applicant: JSR CORPORATION, Tokyo (JP)

(72) Inventors: Motohiro SHIRATANI, Tokyo (JP); Kazuki MOTOYAMA, Tokyo (JP); Igor ROZHANSKII, Tokyo (JP); Katsuaki NISHIKORI, Tokyo (JP); Hiromu MIYATA, Tokyo (JP); Shin-Ya ABE, Tokyo (JP)

(73) Assignee: JSR CORPORATION, Tokyo (JP)

(21) Appl. No.: 19/440,863

(22) Filed: Jan. 6, 2026

Related U.S. Application Data
(63) Continuation of application No. PCT/JP2024/022828, filed on Jun. 24, 2024.

(30) Foreign Application Priority Data
Jul. 6, 2023 (JP) 2023-111759

(51) Int. Cl. G03F 7/039; C08F 293/00

(52) U.S. Cl. CPC G03F 7/0397; C08F 293/005; C08F 2438/03

(57) ABSTRACT

A radiation-sensitive composition includes a polymer represented by formula (1). Each of A¹ and A² independently represents a group represented by formula (a-1), (a-2), (a-3), or (a-4). Each of R³, R⁴, and R⁵ independently represents a monovalent hydrocarbon group; *1 represents a chemical bond to P¹ or P²; and * represents a chemical bond; B¹ represents a divalent group comprising a partial structure that can cleave the bond between A¹ and A² via B¹ by an action of acid; and each of P¹ and P² independently represents a molecular chain.

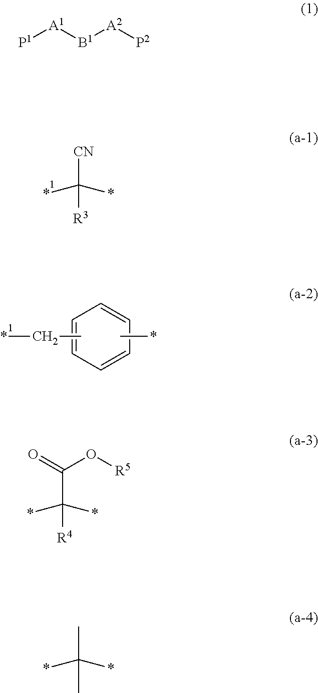

### CROSS-REFERENCE TO RELATED APPLICATIONS

The present application is a continuation application of International Patent Application No. PCT/JP2024/022828, which claims priority to Japanese Patent Application No. 2023-111759 filed on Jul. 6, 2023. The contents of these applications are incorporated herein by reference in their entirety.

### BACKGROUND OF THE INVENTION

### Field of the Invention

The present disclosure relates to a radiation-sensitive composition, to a method for forming a resist pattern (hereinafter may also be referred to as a “resist pattern formation method”), to a polymer and a method for producing the polymer, and to a compound.

### Discussion of the Background

In a lithography technique employed in production of various electronic devices including semiconductor devices and liquid crystal devices, a process target formed of a radiation-sensitive composition is irradiated with a far-UV ray (e.g., ArF excimer laser light), an extreme UV (EUV) ray, an electron beam, or the like, to thereby generate acid in a light-exposed part. Through chemical reaction involving the generated acid, difference in dissolution rate with respect to a developer is provided between the light-exposed part and the light-unexposed part. Thus, a resist pattern is formed on a substrate.

Meanwhile, structures of such electronic devices have been further miniaturized steeply. Under such circumstances, further fine resist patterns are required in lithography steps. In order to satisfy such a requirement, there have been investigated various techniques for improving resolution of a chemical amplification-type radiation-sensitive composition employed in lithographic micro-processing, rectangularity of the formed resist pattern, and the like. For example, Japanese Patent Application Laid-Open (kokai) Nos. 2011-154216 and 2014-2359 disclose such studies.

### SUMMARY

According to an aspect of the present disclosure, a radiation-sensitive composition includes a polymer represented by formula (1).

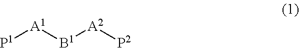

Each of A¹ and A² independently represents a group represented by the following formula (a-1), (a-2), (a-3), or (a-4).

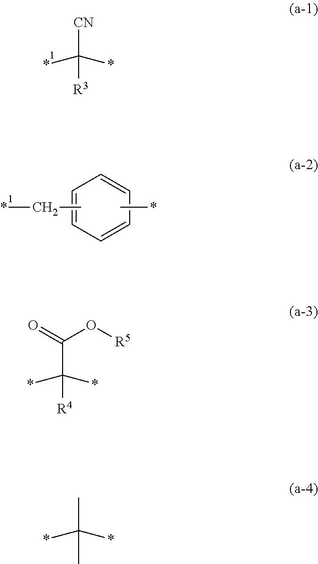

Each of R³, R⁴, and R⁵ independently represents a monovalent hydrocarbon group; *1 represents a chemical bond to P¹ or P²; and * represents a chemical bond; B¹ represents a divalent group having a partial structure that can cleave the bond between A¹ and A² via B¹ by an action of acid; and each of P¹ and P² independently represents a molecular chain.

According to another aspect of the present disclosure, a resist pattern formation method includes: forming a resist film on a substrate by applying the aforementioned radiation-sensitive composition; exposing the resist film to light; and developing the light-exposed resist film.

According to a still another aspect of the present disclosure, a method for producing a polymer includes polymerizing a monomer in a presence of a compound represented by formula (2).

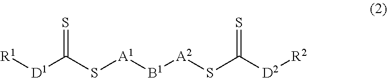

Each of A¹ and A² independently represents a group represented by formula (a-1), (a-2), (a-3), or (a-4).

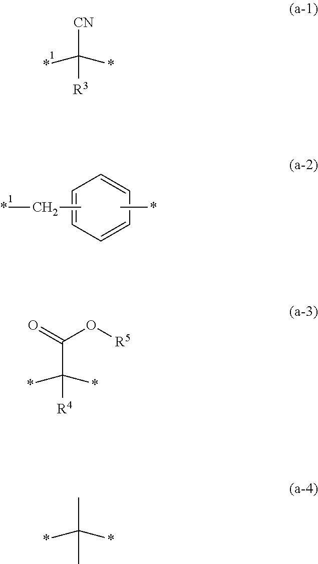

Each of R³, R⁴, and R⁵ independently represents a monovalent hydrocarbon group; *1 represents a chemical bond to the sulfur atom; and * represents a chemical bond; B¹ represents a divalent group having a partial structure in which the bonding between A¹ and A² via B¹ can be broken by an action of acid; each of D¹ and D² independently represents a sulfur atom, an oxygen atom, —NR⁷—, a phenylene group, or a divalent nitrogen-containing heterocyclic group; R⁷ represents a hydrogen atom or a monovalent hydrocarbon group; and each of R¹ and R² independently represents a hydrogen atom or a monovalent organic group.

According to a still another aspect of the present disclosure, a polymer represented by the above formula (1) is provided. According to a yet another aspect of the present disclosure, a compound represented by the above formula (2) is provided.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In recent years, attempts have been made to form a micro-pattern having, for example, a line width of 40 nm or less. Thus, the radiation-sensitive composition for forming a resist film must provide such a fine resist patten by small a dose as possible and exhibit line width roughness (LWR) performance and resolution enhanced in a well-balanced manner.

According to the radiation-sensitive composition and the resist pattern formation method of the present disclosure, sensitivity, resolution, and LWR performance can be improved in a well-balanced manner.

Hereinafter, carrying out of the present disclosure will be described in detail. In the present specification, the numerical range described with “A to B” refers to include “A” as a lower limit value and “B” as an upper limit value. Also, unless otherwise specified, components (i.e., ingredients) contained in the present composition may be used singly or in combination of two or more species.

As used herein, the term “hydrocarbon group” encompasses a chain hydrocarbon group, an alicyclic hydrocarbon group, and an aromatic hydrocarbon group. The term “chain hydrocarbon group” refers to a linear-chain hydrocarbon group or a branched hydrocarbon group including one which is composed of only a chain structure and no ring structure. However, the chain hydrocarbon group may be saturated or unsaturated. The term “alicyclic hydrocarbon group” refers to a hydrocarbon group which contains only an alicyclic hydrocarbon moiety as a ring structure and contains no aromatic ring structure. However, the alicyclic hydrocarbon group is not necessarily formed only of an alicyclic hydrocarbon moiety and may contain a chain structure as a partial structure. The term “aromatic hydrocarbon group” refers to a hydrocarbon group which contains an aromatic ring structure as a ring structure. However, the aromatic hydrocarbon group is not necessarily formed only of an aromatic ring structure and may contain a chain structure or an alicyclic hydrocarbon moiety as a partial structure. The term “aromatic ring group” refers to an n-valent group formed by removing n (n: an integer of 1 or greater) hydrogen atoms from a ring moiety of a substituted or unsubstituted aromatic ring. The term “organic group” refers to an atomic group formed by removing any hydrogen atom from a carbon-containing compound (i.e., an organic compound). The term “aromatic ring” encompasses an aromatic hydrocarbon ring and an aromatic heterocycle.

The term “main chain” of a polymer refers to a part of “trunk” formed of the longest atomic chain of the polymer. The “trunk” may include a ring structure. For example, the expression “main chain having a particular structure” refers to that the particular structure forms a part of the main chain of the polymer. The term “side chain” refers to a part branched from the “trunk” of the polymer. The term “structural unit” refers to a unit which mainly forms a main chain structure, and at least two structural units are included in the main chain structure. Typically, the structural unit is a monomer unit. The term “(meth)acrylate” encompasses “acrylate” and “methacrylate,” and “(thio)acetal” encompasses acetal and thioacetal.

The expression “substituted or unsubstituted p-valent hydrocarbon group (p: an integer of 1 or greater)” encompasses a p-valent hydrocarbon group (i.e., an unsubstituted p-valent hydrocarbon group) and a group formed by removing p hydrogen atoms from a hydrocarbon moiety from a substituted hydrocarbon group. Examples of the substituted or unsubstituted p-valent hydrocarbon group include an alkyl group and a fluoroalkyl group (i.e., p=1) and an alkanediyl group and a fluoroalkanediyl group (i.e., p=2). Among them, the fluoroalkyl group corresponds to a “substituted monovalent hydrocarbon group,” and the fluoroalkanediyl group corresponds to a “substituted divalent hydrocarbon group.” The same convention applies to other groups with “substituted or unsubstituted.”

### <<Radiation-Sensitive Composition>>

The radiation-sensitive composition of the present disclosure (hereinafter may also be referred to as “the present composition”) contains a polymer represented by the following formula (1) (hereinafter may also be referred to as a “polymer (A)”):

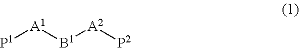

wherein each of A¹ and A² independently represents a group represented by the following formula (a-1), (a-2), (a-3), or (a-4):

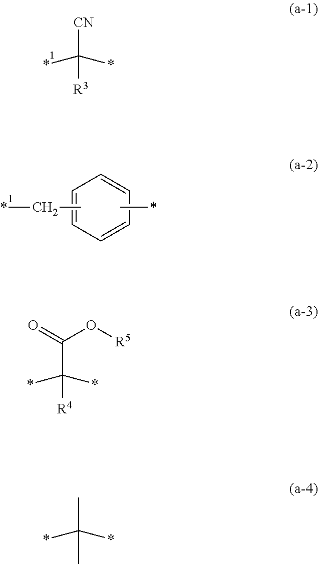

wherein each of R³, R⁴, and R⁵ independently represents a monovalent hydrocarbon group; “*1” represents a chemical bond to P¹ or P²; and “*” represents a chemical bond;
B¹ represents a divalent group having a partial structure that can cleave the bond between A¹ and A² by the mediation of B¹ by the action of acid; and each of P¹ and P² independently represents a molecular chain.

### <Polymer (A)>

The polymer (A) is a polymer represented by the above formula (1) and includes a site that can be cloven by the action of acid in the main chain. The polymer (A) may be produced through polymerization of a monomer or monomers in the presence of a compound represented by the following formula (2) (hereinafter may also be referred to as a “compound (RA)”). In this case, the compound (RA) serves as a reversible addition-fragmentation chain transfer agent (RAFT agent).

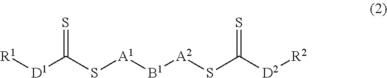

In formula (2), each of D¹ and D² independently represents a sulfur atom, an oxygen atom, —NR⁷—, a phenylene group, or a divalent nitrogen-containing heterocyclic group; R⁷ represents a hydrogen atom or a monovalent hydrocarbon group; each of R¹ and R² independently represents a hydrogen atom or a monovalent organic group; and A¹, A², and B¹ have the same meanings as those defined in the above formula (1).

In the above formulas (1) and (2), A¹ and A² are represented by the above formulas (a-1), (a-2), (a-3), and (a-4), respectively. In the above formulas (a-1) to (a-4), examples of the monovalent hydrocarbon group represented by R³, R⁴, or R⁵ include a C1 to C10 monovalent chain hydrocarbon group, a C3 to C12 monovalent alicyclic hydrocarbon group, and a C6 to C12 monovalent aromatic hydrocarbon group.

Examples of the C1 to C10 monovalent chain hydrocarbon group include alkyl groups such as methyl, ethyl, n-propyl, i-propyl, n-butyl, and t-butyl; alkenyl groups such as ethenyl, propenyl, and butenyl; and alkynyl groups such as ethynyl, propynyl, and butynyl. Among them, the C1 to C10 monovalent chain hydrocarbon group represented by R³, R⁴, or R⁵ is preferably an alkyl group, more preferably an alkyl group, more preferably a C1 to C4 alkyl group, still more preferably a methyl group.

Examples of the C3 to C12 monovalent alicyclic hydrocarbon group include monovalent monocyclic alicyclic saturated hydrocarbon groups such as cyclopentyl, cyclohexyl, methylcyclopentyl, ethylcyclopentyl, methylcyclohexyl, and ethylcyclohexyl; monovalent monocyclic alicyclic unsaturated hydrocarbon groups such as cyclopentenyl, cyclohexenyl, methylcyclopentenyl, and methylcyclohexenyl; monovalent polycyclic alicyclic saturated hydrocarbon groups such as norbornyl, adamantyl, and tricyclodecyl; and monovalent polycyclic alicyclic unsaturated hydrocarbon groups such as norbornenyl, tricyclodecenyl, and indanyl.

Examples of the C6 to C12 monovalent aromatic hydrocarbon group include aryl groups such as phenyl, tolyl, xylyl, mesityl, naphthyl, methyl naphthyl, anthryl, methylanthryl, indenyl; and aralkyl groups such as benzyl, phenethyl, naphtylmethyl, and anthrylmethyl.

Each of R³ and R⁴ is preferably a C1 to C10 monovalent chain hydrocarbon group, more preferably a C1 to C10 alkyl group, still more preferably a C1 to C4 alkyl group, yet more preferably a methyl group. R⁵ is preferably a C1 to C10 monovalent chain hydrocarbon group, more preferably a C1 to C10 alkyl group.

In the case where D¹ or D² is —NR⁷— and R⁷ is a monovalent hydrocarbon group, specific examples of the monovalent hydrocarbon group represented by R⁷ include the same groups exemplified as the monovalent hydrocarbon group represented by R³, R⁴, or R⁵. R⁷ is preferably a hydrogen atom or an alkyl group, more preferably a hydrogen atom or a C1 to C3 alkyl group.

Examples of the divalent nitrogen-containing heterocyclic group include a group formed by removing two hydrogen atoms from a nitrogen-containing heterocycle such as pyrrolidine, pyrrole, imidazolidine, imidazole, pyrazolidine, pyrazole, oxazolidine, isoxazolidine, oxazole, isoxazole, piperidine, pyridine, piperazine, diazine, morpholine, oxazine, and triazine.

From the viewpoint of further enhancing flexibility in selection of a monomer, each of D¹ and D² is preferably a sulfur atom, —NR⁷—, or a phenylene group, more preferably a sulfur atom or a phenylene group.

No particular limitation is imposed on the monovalent organic group represented by R¹ or R², so long as the compound (PA) can serve as a chain transfer agent in polymerization of a monomer or monomers in the presence of the compound (PA). Examples of the monovalent organic group include a C1 to C20 monovalent chain hydrocarbon group, a C3 to C20 monovalent alicyclic hydrocarbon group, a C6 to C20 monovalent aromatic hydrocarbon group, a C3 to C20 monovalent aliphatic heterocyclic group, and a C5 to C20 monovalent aromatic heterocyclic group. Specific examples of the C1 to C20 monovalent chain hydrocarbon group, the C3 to C20 monovalent alicyclic hydrocarbon group, and the C6 to C20 monovalent aromatic hydrocarbon group include the same groups exemplified as the monovalent hydrocarbon group represented by R³, R⁴, and R⁵.

Examples of the C3 to C20 monovalent aliphatic heterocycle group include, as an aliphatic heterocycle structure, a cyclic ether structure, a lactone structure, a cyclic acetal structure, a cyclic carbonate structure, and a sultone structure. The aliphatic heterocycle structure may be a monocyclic structure or a polycyclic structure. The polycyclic structure may be any of a bridged structure, a condensed ring structure, and a spiro ring structure, or may be a combination of two or more of a bridged structure, a condensed ring structure, and a spiro ring structure. In the case of a condensed ring structure or a spiro ring structure, two or more rings forming the ring structure may be an aliphatic heterocycle singly or a combination of an aliphatic heterocycle and an alicyclic hydrocarbon ring.

Examples of the C5 to C20 monovalent aromatic heterocyclic group include, as an aromatic heterocycle structure, oxygen-containing heterocycle structures such as a furan structure, a pyran structure, a benzopyran structure; nitrogen-containing heterocycle structures such as a pyrrole structure, an imidazole structure, a pyrazole structure, a triazole structure, a pyridine structure, a pyrimidine structure, a pyridazine structure, a pyrazine structure, an indole structure, and a benzimidazole structure; and sulfur-containing heterocycle structures such as a thiophene structure.

In each of the groups exemplified as the monovalent organic group represented by R¹ or R², any hydrogen atom may be substituted. Alternatively, any methylene group may be substituted by a divalent linking group. Examples of the substituent include a halogen group, a hydroxy group, a carboxy group, a cyano group, a nitro group, an alkoxy group, an alkoxycarbonyl group, an alkoxycarbonyloxy group, an acryl group, and an acyloxy group. Examples of the divalent linking group include a carbonyl group, an ether group, a carbonyloxy group, a sulfide group, a thiocarbonyl group, a sulfonyl group, and an amide group. When R¹ is a hydrogen atom, D¹ is preferably a phenylene group or a divalent nitrogen-containing heterocyclic group. When R² is a hydrogen atom, D² is preferably a phenylene group or a divalent nitrogen-containing heterocyclic group.

B¹ is a group which links A¹ and A² in the above formula (1) or (2) and has a divalent group having a partial structure that can cleave the intramolecular bond between A¹ and A² in the above formula (1) or (2) by the action of acid. By virtue of such a group (B¹) present in the main chain of the polymer (A), the intramolecular bond is cleaved at the site of B¹ by the acid generated in the present composition, whereby the main chain of the polymer (A) can be degraded.

Specific examples of B¹ including a tertiary carbon atom bound to an oxygen atom, a benzyl-position carbon atom bound to an oxygen atom, an allyl-position carbon atom bound to an oxygen atom, and a group having a (thio)acetal ring (hereinafter may also be referred to as a “cleavage site”) at a site allowing the bond between A¹ and A² to cleave by the mediation of B¹ (more specifically, the main chain of the compound).

Further specific examples of B¹ having the aforementioned cleavage site include divalent groups each having a partial structure represented by the following formula (b-1), (b-2), or (b-3):

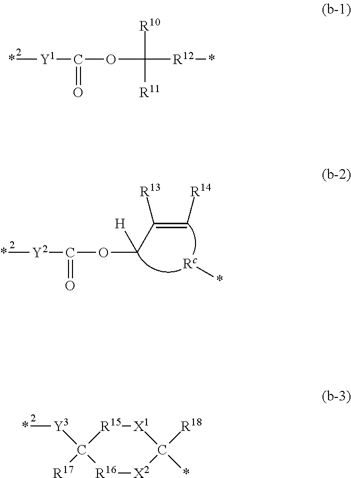

wherein, in formula (b-1), R¹⁰ represents a C1 to C10 monovalent chain hydrocarbon group or a C3 to C20 monovalent alicyclic hydrocarbon group; regarding R¹¹ and R¹², R¹¹ represents a C1 to C10 monovalent chain hydrocarbon group or a C3 to C20 monovalent alicyclic hydrocarbon group, and R¹² represents a C1 to C20 divalent hydrocarbon group, or R¹¹ represents a hydrogen atom, and R¹² represents a C6 to C14 monovalent aromatic ring group, or a C3 to C20 alicyclic structure formed by combining R¹¹ and R¹² together with the carbon atom to which R¹¹ and R¹² are bound; Y¹ represents a single bond or a divalent linking group; “*2” represents a chemical bond to A¹ or A² in the above formula (1); and “*” represents a chemical bond;
in formula (b-2), each of R¹³ and R¹⁴ independently represents a hydrogen atom or a C1 to C20 monovalent hydrocarbon group, or a ring structure formed by combining R¹³ and R¹⁴ together with the carbon atom to which R¹³ is bound and the carbon atom to which R¹⁴ is bound; R^{c} represents an unsaturated alicyclic structure formed with two carbon atoms in the formula (b-2) to which R^{c} is bound and a carbon atom to which R¹³ is bound; Y² represents a single bond or a divalent linking group; “*2” represents a chemical bond to A¹ or A² in the above formula (1); and “*” represents a chemical bond; and
in formula (b-3), each of X¹ and X² independently represents an oxygen atom or a sulfur atom; R¹⁵ represents a single bond or a C1 to C10 alkanediyl group; R¹⁶ represents a C1 to C10 alkanediyl group; each of R¹⁷ and R¹⁸ independently represents a hydrogen atom or a C1 to C10 monovalent hydrocarbon group; Y³ represents a divalent linking group; “*2” represents a chemical bond to A¹ or A² in the above formula (1); and “*” represents a chemical bond.

In the above formula (b-1), specific examples of the C1 to C10 monovalent chain hydrocarbon group, C3 to C20 monovalent alicyclic hydrocarbon group, and C1 to C20 monovalent hydrocarbon group represented by R¹⁰, R¹¹, or R¹² include the same groups as exemplified in relation to the monovalent hydrocarbon group represented by R³, R⁴, or R⁵.

When R¹² is a C6 to C14 monovalent aromatic ring, examples of the monovalent aromatic ring include a phenylene group or a naphthanylene group. The monovalent aromatic ring may have a substituent in a ring moiety. Examples of the substituent include a halogen atom, a hydroxy group, and an alkoxy group.

Examples of the C3 to C20 alicyclic structure formed by combining R¹¹ and R¹² together with the carbon atom to which R¹¹ and R¹² are bound include monocyclic saturated alicyclic structures such as a cyclopropane structure, a cyclobutane structure, a cyclopentane structure, a cyclohexane structure, a cycloheptane structure, and a cyclooctane structure; monocyclic unsaturated alicyclic structures such as a cyclopentene structure and a cyclohexene structure; and polycyclic alicyclic structures such as a norbornane structure, an adamantane structure, a tricyclodecane structure, and a tetracyclododecane structure.

In the above formula (b-2), specific examples of the C1 to C20 monovalent hydrocarbon group in R¹³ or R¹⁴ include the same groups as exemplified in relation to the monovalent hydrocarbon group represented by R³, R⁴, or R⁵.

Examples of the ring structure formed by combining R¹³ and R¹⁴ together with the carbon atom to which R¹³ is bound and the carbon atom to which R¹⁴ is bound include alicyclic hydrocarbon structures such as a cyclobutene structure, a cyclopentene structure, a cyclohexene structure, and a norbornene structure; aliphatic heterocycle structures such as a thiacyclopentane structure, an oxacyclopentane structure, and an azacyclopentane structure; and aromatic heterocycle structures such as a thiophene structure and a furan structure.

The unsaturated alicyclic structure formed with two carbon atoms in the formula (b-2) to which R^{c} is bound and a carbon atom to which R¹³ is bound may be a monocyclic structure or a polycyclic structure. Examples of the unsaturated alicyclic structure include a cyclobutene structure, a cyclopentene structure, a cyclohexene structure, a norbornene structure, and a 1,2,3,4,4a,5,6,7-octahydronaphthalene structure. Also, the ring structure in the above formula (b-2) may have a substituent.

In the above formula (b-3), both of X¹ and X² are preferably an oxygen atom or a sulfur atom, more preferably an oxygen atom.

The C1 to C10 alkanediyl group of R¹⁵ or R¹⁶ may be linear-chain or branched. From the viewpoint of ease of synthesis, the alkanediyl group is preferably a C1 to C3, more preferably a methylene group.

Specific examples of the C1 to C10 monovalent hydrocarbon group of R¹⁷ and R¹⁸ include the same groups as exemplified in relation to the monovalent hydrocarbon group represented by R³, R⁴, or R⁵. R¹⁷ or R¹⁸ is preferably a hydrogen atom or a C1 to C10 alkyl group.

In the above formulas (b-1) to (b-3), examples of the divalent linking group represented by Y¹, Y², or Y³ include an alkanediyl group, a carbonyl group, an ether group, a carbonyloxy group, a sulfide group, a thiocarbonyl group, a sulfonyl group, an amide group, and a group formed from two or more of the above members.

B¹ may have one cleavage site or a plurality (preferably 2 to 4) of cleavage sites. When B¹ has a plurality of cleavage sites, the cleavage sites may be linked by a single bond or by the mediation of a divalent linking group. Examples of the divalent linking group include a group formed by further removing one hydrogen atom from any of the groups exemplified as the monovalent organic group represented by R¹ or R².

Specific examples of the compound (RA) include compounds represented by the following formulas (ra-1) to (ra-16), respectively.

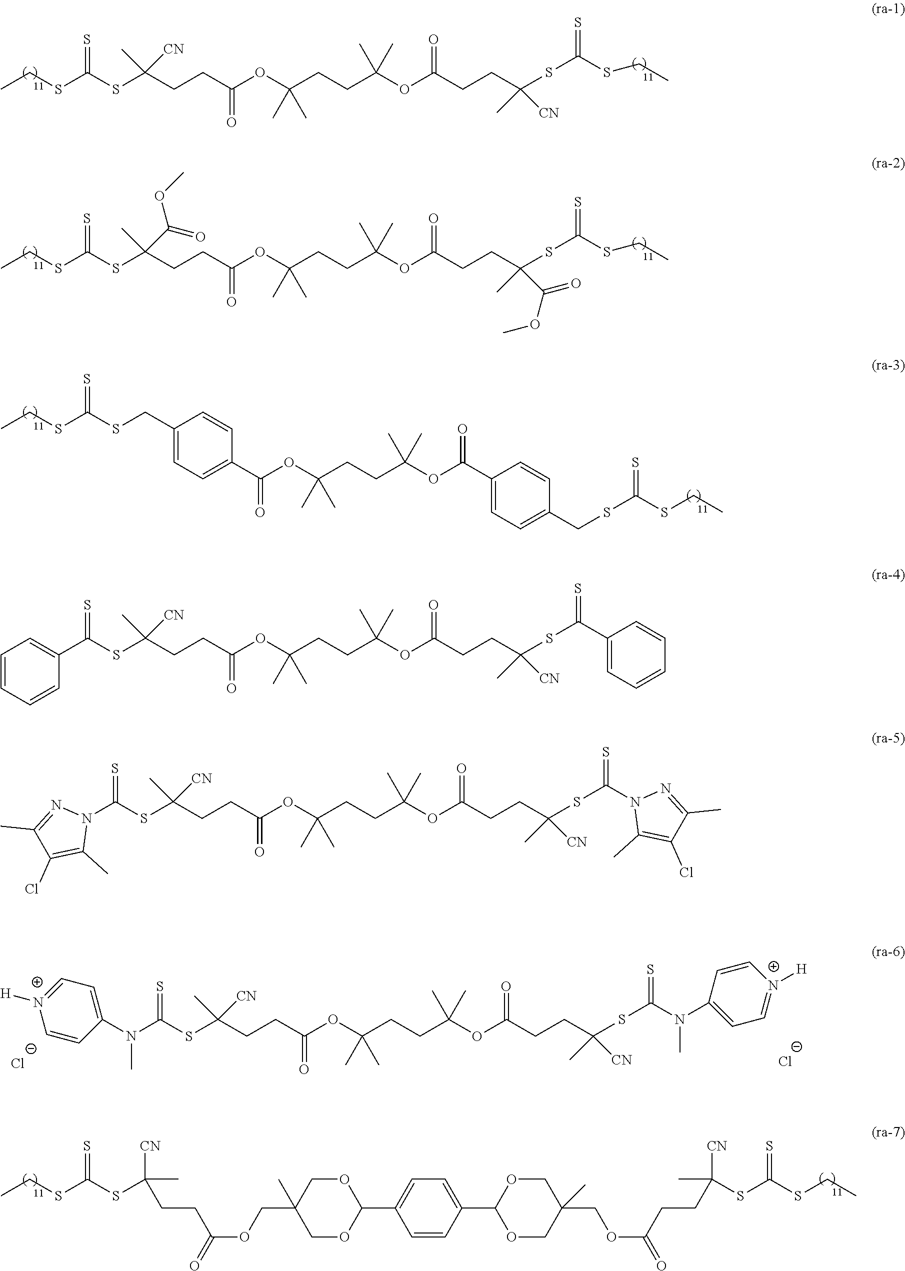

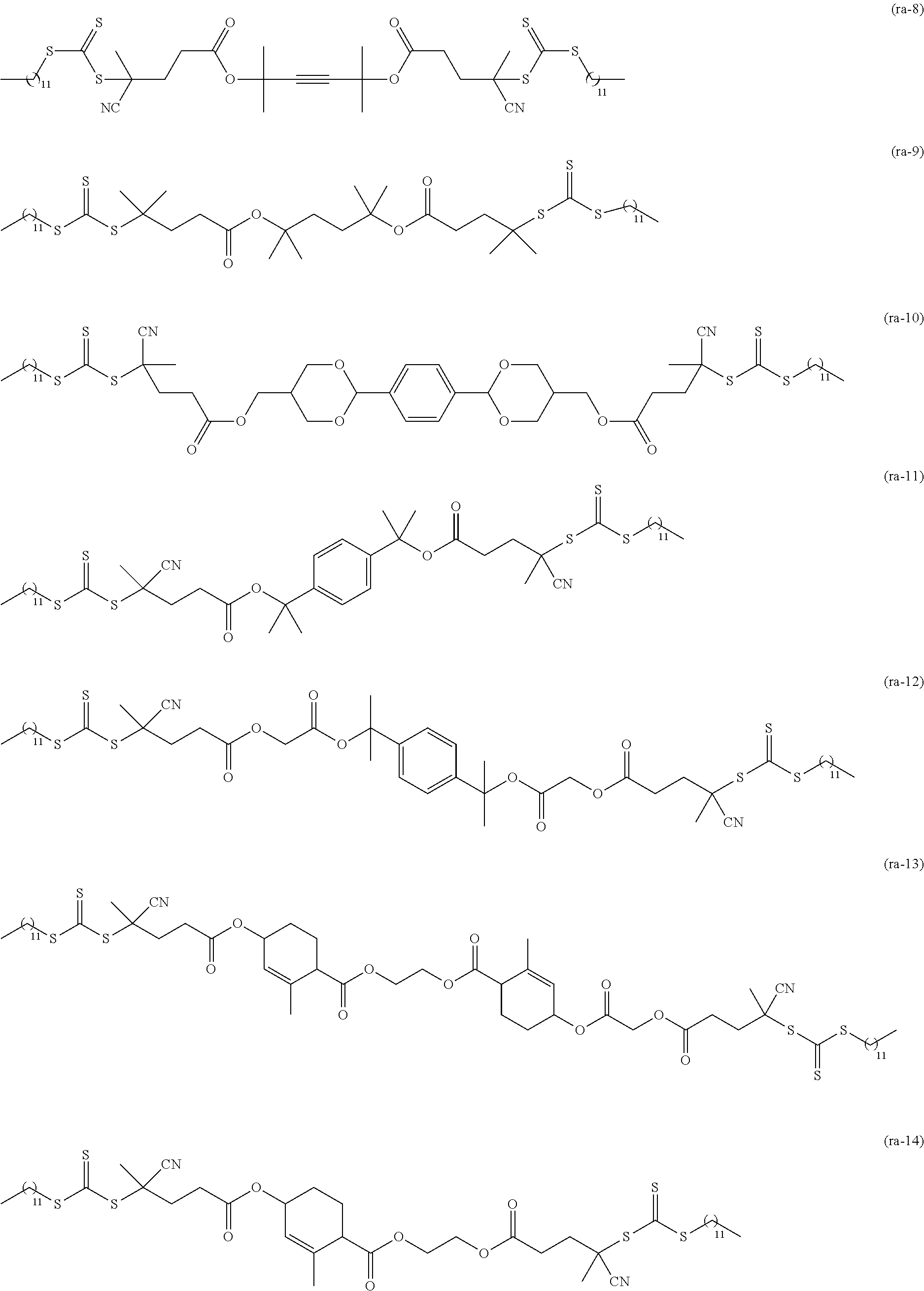

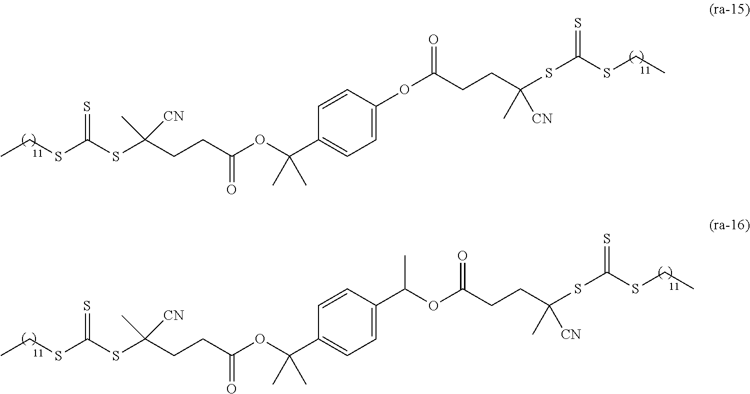

No particular limitation is imposed on the method of synthesizing the compound (RA), and RA can be synthesized through customary methods of organic chemistry in appropriate combinations. Taking a compound represented by the above formula (ra-1) as an example, a specific procedure of the synthesis will be described. A compound RA can be yielded by allowing to react a compound represented by the following formula (D-1) (i.e., a compound that can provide B¹ in the above formula (2)), and a compound represented by the following formula (D-2) (i.e., a compound that can provide “R¹-D¹-C(═S)—S-A¹-” and “R²-D²-C(═S)—S-A²-”) in an appropriate solvent optionally in the presence of a catalyst. Other compounds RA can also be synthesized through appropriate choice of starting materials.

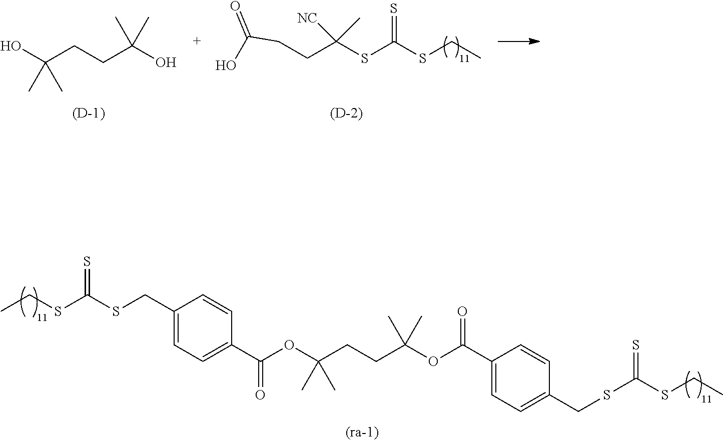

The polymer (A) can be synthesized by use of the compound (RA) serving as a reversible addition-fragmentation chain transfer agent (RAFT agent), specifically by polymerizing a monomer or monomers in an appropriate solvent in the presence of the compound (RA). From the viewpoint of satisfactorily proceeding of living radical polymerization, the amount of the compound (PA) in polymerization is preferably 0.05 mol % or more, with respect to the total amount of the monomer(s) (100 mol %), more preferably 0.1 mol % or more. The amount of the compound (PA) used is preferably 20 mol % or less with respect to the total amount of the monomer(s), more preferably 10 mol % or less.

From the viewpoint of productivity, the polymerization is preferably conducted in the presence of a radical generating agent. As the radical generating agent, there may be used any radical polymerization initiator appropriately selected from conventionally known radical polymerization initiators generally employed radical polymerization. Examples of the radical polymerization initiator include azo-type radical initiators (e.g., azobisisobutyronitrile (AIBN) and 2,2′-azobis(4-methoxy-2,4-dimethylvaleronitrile) and peroxide-type radical initiators (e.g., benzoyl peroxide).

In the case where polymerization is conducted in the presence of a radical generating agent, the amount of the radical generating agent used, with respect to 100 parts by mass of the compound (PA), is preferably 1 part by mass or more, more preferably 10 parts by mass or more. Also, the amount of the compound (PA) used, with respect to 100 parts by mass of the compound (PA), is preferably 1,000 parts by mass or less, more preferably 100 parts by mass or less.

Examples of the solvent used in the polymerization include a linear-chain alkane, a cycloalkane, an aromatic hydrocarbon, a halogenated hydrocarbon, a saturated carboxylate ester, a ketone, an ether, and an alcohol. The reaction temperature in the polymerization is preferably 40 to 150° C., more preferably 50 to 120° C., and the reaction time is preferably 1 to 48 hours, more preferably 2 to 24 hours. The polymer formed through the above polymerization procedure as is may be used for preparing a radiation-sensitive composition. Alternatively, the polymer may be used for preparing a radiation-sensitive composition, after conducting an inactivation treatment which includes removal or transformation of a group derived from the compound (PA) and bound to a polymer end (specifically, a thiocarbonylthio group) (hereinafter may also be referred to as a “end treatment”). End treatment may be conducted through a known method, for example, a method in which a thiol compound and a polymerization initiator are added.

Through the aforementioned polymerization reaction, a polymer represented by the above formula (1) can be yielded. No particular limitation is imposed on the monomer forming the polymer (A) (i.e., the monomers forming P¹ and P² in the above formula (1)). From the viewpoint of successfully forming a fine resist pattern through light exposure, the polymer (A) preferably includes a structural unit having an acid-releasable group (hereinafter may also be referred to as a “first structural unit”). In addition, the polymer (A) may optionally include one or more members selected from among a structural unit having a hydroxy group bound to an aromatic ring (hereinafter may also be referred to as a “second structural unit”); a structural unit having an onium salt structure (hereinafter may also be referred to as a “third structural unit”); a structural unit having a lactone structure, a cyclic carbonate structure, a sultone structure, or a ring structure formed by combining two or more of the above structures (hereinafter may also be referred to as a “fourth structural unit”); and a structural unit having an alcoholic hydroxy group (hereinafter may also be referred to as a “fifth structural unit”).

Notably, each of the first to fifth structural units may be included in one or both of P¹ and P². From the viewpoint of ease of polymerization, in one case where the polymer (A) includes the first structural unit, both P¹ and P² preferably include the first structural unit. The same is applicable to the second to fifth structural units. Hereinafter, the structural units will be described in detail.

### First Structural Unit

The first structural unit is preferably a structural unit which undergoes release of acid-releasable group by the acid generated in the present composition through light exposure, to thereby generate a carboxy group or a hydroxy group. Examples of the first structural unit include the structural units represented by the following formula (i-1) (hereinafter may also be referred to as “structural units (I-1)”), the structural units represented by the following formula (i-2) (hereinafter may also be referred to as “structural units (I-2)”), and the structural units represented by the following formula (i-3) (hereinafter may also be referred to as “structural units (I-3)”).

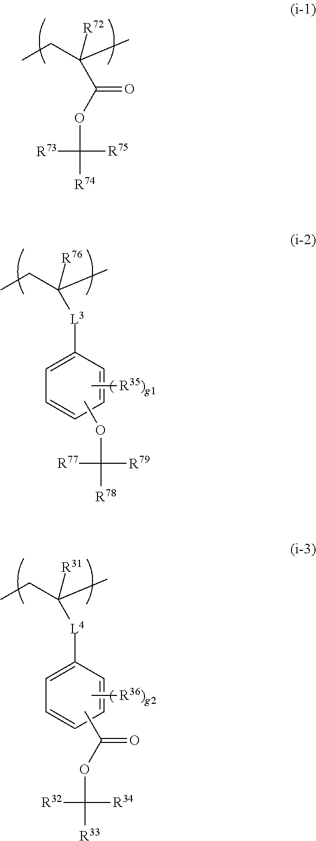

In formula (i-1), R⁷² represents a hydrogen atom, a fluorine atom, a methyl group, or a trifluoromethyl group; R⁷³ represents a hydrogen atom or a C1 to C20 substituted or unsubstituted monovalent hydrocarbon group; each of R⁷⁴ and R⁷⁵ independently represents a C1 to C20 substituted or unsubstituted monovalent hydrocarbon group or aromatic heterocyclic group, or a C3 to C20 alicyclic hydrocarbon structure formed by combining R⁷⁴ and R⁷⁵ together with a carbon atom to which R⁷⁴ and R⁷⁵ are bound; and when R⁷³ is a hydrogen atom, one or both of R⁷⁴ and R⁷⁵ independently represent a substituted or unsubstituted monovalent unsaturated hydrocarbon group, a substituted or unsubstituted aromatic heterocyclic group, or a C3 to C20 unsaturated alicyclic hydrocarbon structure formed by combining R⁷⁴ and R⁷⁵ together with a carbon atom to which R⁷⁴ and R⁷⁵ are bound;
in formula (i-2), R⁷⁶ represents a hydrogen atom, a fluorine atom, a methyl group, or a trifluoromethyl group; L³ is a single bond, —O—, —CO—, *²—COO—, or *²—CONH—; “*2” represents a chemical bond to the main chain; each of R⁷⁷, R⁷⁸, and R⁷⁹ independently represents a hydrogen atom, a C1 to C20 substituted or unsubstituted monovalent hydrocarbon group, or a C1 to C20 substituted or unsubstituted monovalent oxyhydrocarbon group; R³⁵ represents a monovalent substituent; and g1 is an integer of 0 to 4; and
in formula (i-3), R³¹ represents a hydrogen atom, a fluorine atom, a methyl group, or a trifluoromethyl group; L⁴ represents a single bond, —O—, —CO—, *³—COO—, or *³—CONH—; “*3” represents a chemical bond to the main chain; R³² represents a hydrogen atom, a C1 to C20 substituted or unsubstituted monovalent hydrocarbon group or a C1 to C20 substituted or unsubstituted monovalent oxyhydrocarbon group; each of R³³ and R³⁴ independently represents a hydrogen atom, a C1 to C20 substituted or unsubstituted monovalent hydrocarbon group, a C1 to C20 substituted or unsubstituted monovalent oxyhydrocarbon group, or a C3 to C20 alicyclic hydrocarbon structure formed by combining R³³ and R³⁴ together with a carbon atom to which R³³ and R³⁴ are bound; R³⁶ represents a monovalent substituent; and g2 is an integer of 0 to 4.

In the above formula (i-1), from the viewpoint of co-polymerizability of a monomer forming the structural unit (I-1), R⁷² is preferably a hydrogen atom or a methyl group, more preferably a methyl group. In the above formula (i-2), from the viewpoint of co-polymerizability of a monomer forming the structural unit (I-2), R⁷⁶ is preferably a hydrogen atom. Similarly, R³¹ in the above formula (i-3) is preferably a hydrogen atom or a methyl group. L³ in the above formula (i-2) or L⁴ in the above formula (i-3) is preferably a single bond, —COO—, or —CONH—.

Examples of the C1 to C20 monovalent hydrocarbon group represented by any of R⁷³ to R⁷⁵, R⁷⁷ to R⁷⁹, and R³² to R³⁴ include a C1 to C20 monovalent chain hydrocarbon group, a C3 to C20 monovalent alicyclic hydrocarbon group, and a C6 to C20 monovalent aromatic hydrocarbon group. Specific examples thereof include the same groups exemplified as the monovalent hydrocarbon group represented by R³, R⁴, or R⁵ in the above formulas (a-1) to (a-4).

Examples of the monovalent unsaturated hydrocarbon group represented by R⁷⁴ or R⁷⁵ include the aforementioned monocyclic or polycyclic alicyclic unsaturated hydrocarbon group and aromatic hydrocarbon group. Examples of the monovalent aromatic heterocyclic group include a furyl group and a thienyl group.

Examples of the C3 to C20 alicyclic hydrocarbon structure formed by combining R⁷⁴ and R⁷⁵ together with a carbon atom to which R⁷⁴ and R⁷⁵ are bound, and the C3 to C20 alicyclic hydrocarbon structure formed by combining R³³ and R³⁴ together with a carbon atom to which R³³ and R³⁴ are bound include monocyclic saturated alicyclic hydrocarbon structures such as a cyclopropane structure, a cyclobutane structure, a cyclopentane structure, a cyclohexane structure, a cycloheptane structure, a cyclooctane structure; monocyclic unsaturated alicyclic hydrocarbon structures such as a cyclopentene structure and a cyclohexene structure; and polycyclic alicyclic hydrocarbon structures such as a norbornane structure, an adamantane structure, a tricyclodecane structure, and a tetracyclododecane structure.

Examples of the C1 to C20 monovalent oxyhydrocarbon group represented by any of R⁷⁷ to R⁷⁹, or R³² to R³⁴ include groups exemplified as the C1 to C20 monovalent hydrocarbon group of any of the aforementioned R⁷³ to R⁷⁵, R⁷⁷ to R⁷⁹, and R³² to R³⁴, each containing an oxygen atom at the end of the chemical bond side. Among them, the monovalent oxyhydrocarbon group represented by any of R⁷⁷ to R⁷⁹, or R³² to R³⁴ is preferably an alkoxy group, a cycloalkoxy group, or a cycloalkylalkoxy group.

When the group represented by any of the aforementioned R⁷³ to R⁷⁵, R⁷⁷ to R⁷⁹, and R³² to R³⁴ has a substituent, examples of the substituent include a halogen atom (e.g., a fluorine atom, a chlorine atom, a bromine atom, or an iodine atom), a hydroxy group, and a C1 to C3 alkoxy group. In the case where R⁷⁴ and R⁷⁵ are combined together with a carbon atom to which R⁷⁴ and R⁷⁵ are bound to form a C3 to C20 alicyclic hydrocarbon structure, or R³³ and R³⁴ are combined together with a carbon atom to which R³³ and R³⁴ are bound to form a C3 to C20 alicyclic hydrocarbon structure, any of the above-exemplified substituents and alkyl groups may be bound to a ring.

Examples of the monovalent substituent represented by R³⁵ or R³⁶ include a C1 to C3 alkyl group, a C1 to C3 alkoxy group, a halogen atom (e.g., a fluorine atom, a chlorine atom, a bromine atom, or an iodine atom), and a hydroxy group. Each of g1 and g2 is preferably 0 to 2, more preferably 0 or 1.

Specific examples of the structural unit (I-1) include the structural units represented by the following formulas.

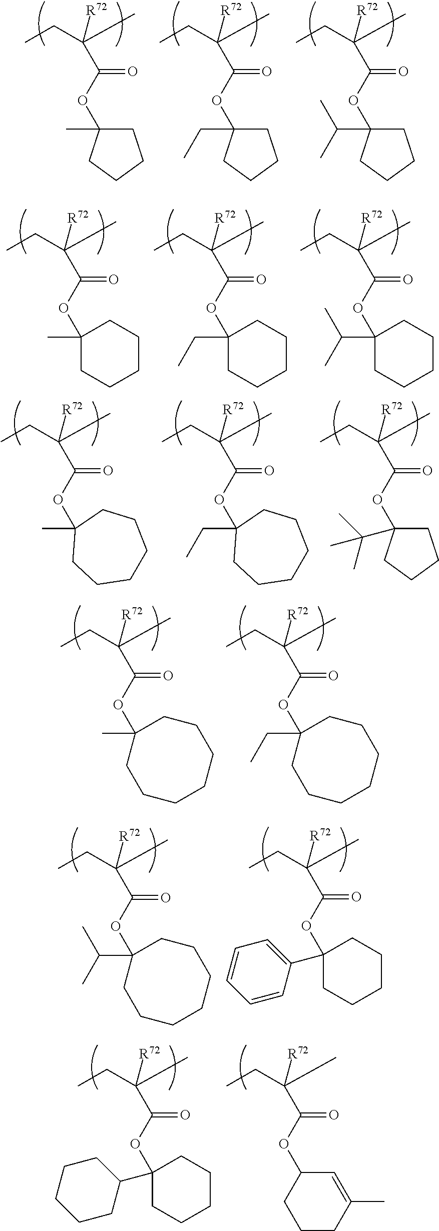

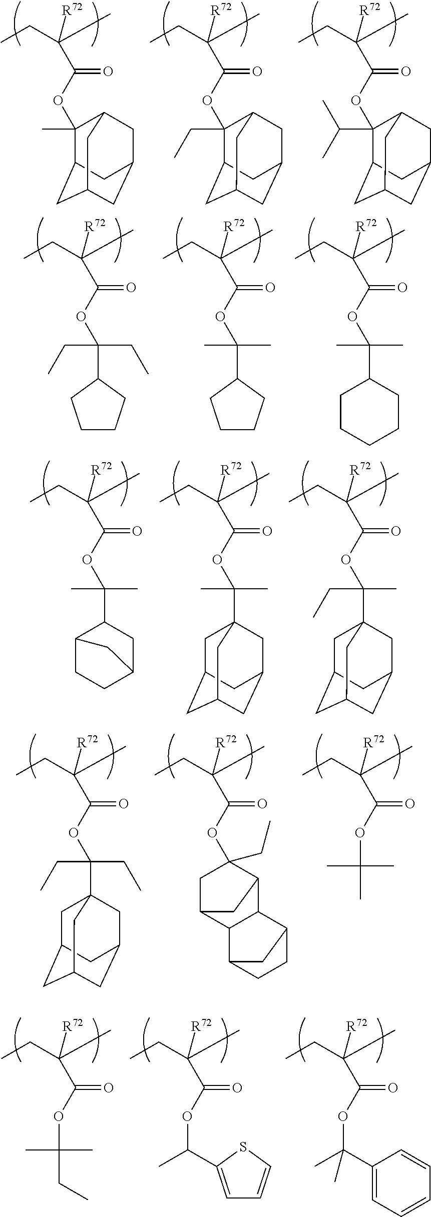

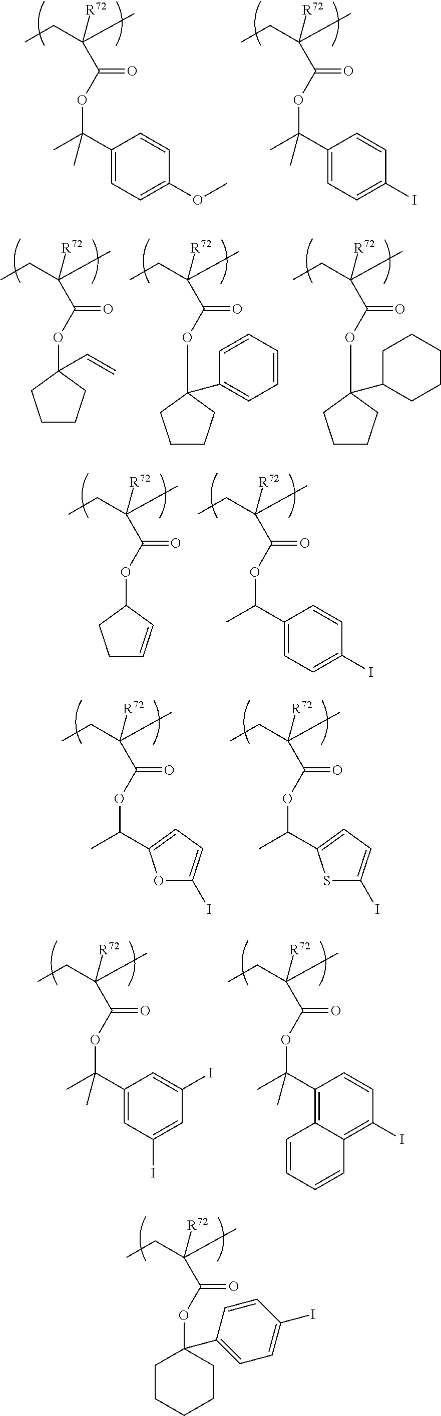

In the formulas, R⁷² represents a hydrogen atom, a fluorine atom, a methyl group, or a trifluoromethyl group.

Specific examples of the structural unit (I-2) include the structural units represented by the following formulas.

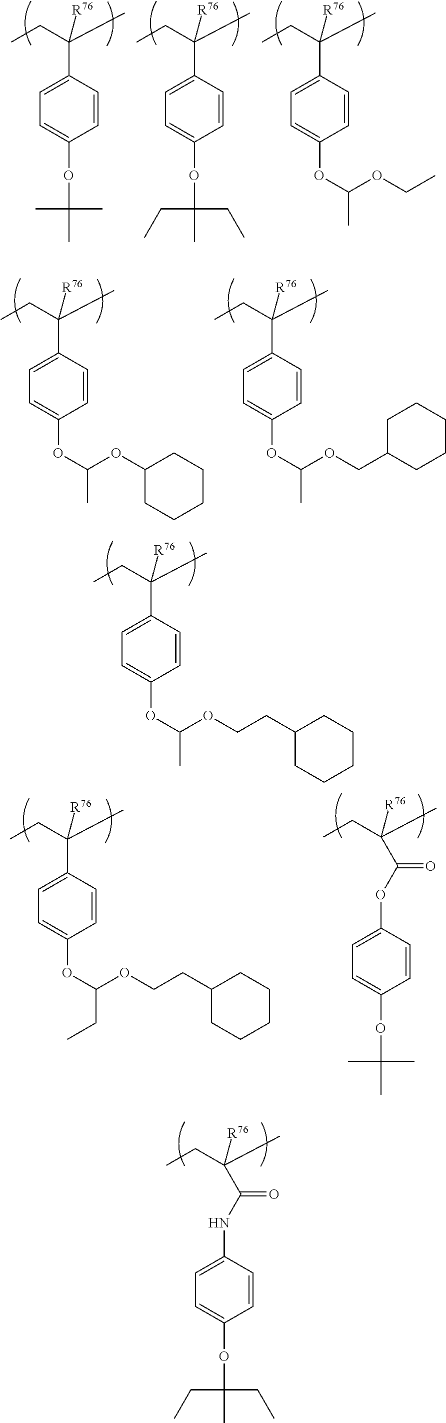

In the formulas, R⁷⁶ represents a hydrogen atom, a fluorine atom, a methyl group, or a trifluoromethyl group.

Specific examples of the structural unit (I-3) include the structural units represented by the following formulas.

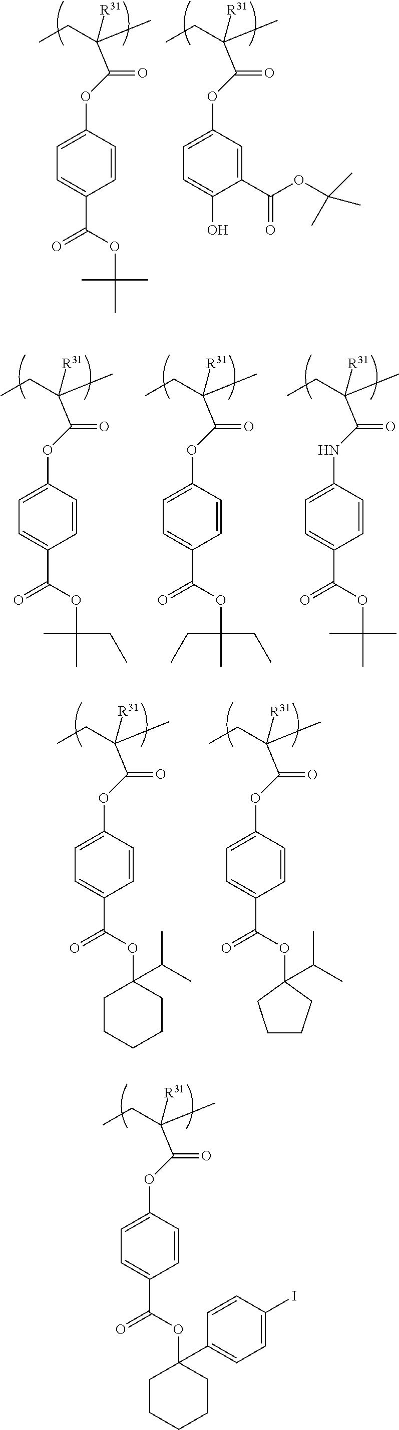

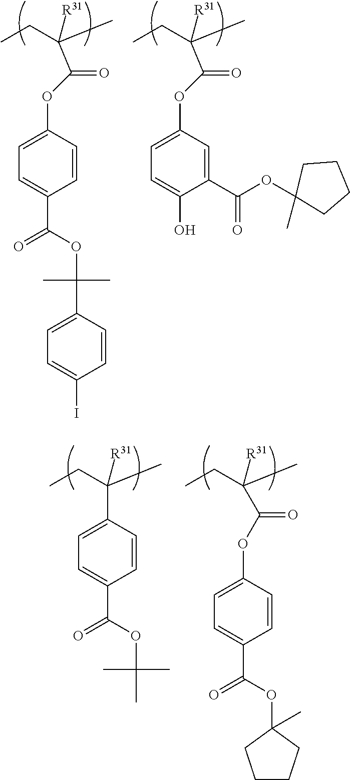

In the formulas, R³¹ represents a hydrogen atom, a fluorine atom, a methyl group, or a trifluoromethyl group.

Examples of the first structural unit further include a structural unit derived from an unsaturated dicarboxylic acid compound in which two carboxy groups thereof are protected (e.g., di(tert-butyl) maleate).

The relative amount of the first structural unit in the polymer (A), with respect to the total amount of the structural units included in the polymer (A), is preferably 20 mol % or more, more preferably 25 mol % or more, still more preferably 30 mol % or more. Also, the relative amount of the first structural unit in the polymer (A), with respect to the total amount of the structural units included in the polymer (A), is preferably 80 mol % or less, more preferably 75 mol % or less, still more preferably 70 mol % or less. By adjusting the first structural unit content to satisfy the above conditions, the difference in dissolution rate with respect to the developer between the light-exposed part and the light-unexposed part increases, while suitable sensitivity of the present composition is maintained. As a result, the pattern form of the resist film can be further enhanced.

Notably, the polymer (A) may further include a structural unit having an acid-releasable group and a hydroxy group bound to an aromatic ring. In the present specification, the structural unit having an acid-releasable group and a hydroxy group bound to an aromatic ring is categorized to the first structural unit.

### Second Structural Unit

The second structural unit is a structural unit having an aromatic ring and a hydroxy group bound to the aromatic ring (excepting the first structural unit). In corporation of the second structural unit into the polymer (A) is preferred, since lithographic performance of the present composition (e.g., LWR performance or CDU (critical dimension uniformity) performance can be further enhanced, and a high effect of suppressing dissolution of the light-unexposed part in the developer is achieved, to thereby sufficiently reduce development failure. Particularly, in pattern formation by employing light exposure by means of a radiation having a wavelength of 50 nm or shorter (e.g., an electron beam or EUV), a polymer having a hydroxy group bound to an aromatic ring is preferably applied.

Examples of the aromatic ring to which a hydroxy group is bound include a benzene ring, a naphthalene ring, an anthracene ring, and a phenanthrene ring. Of these, a benzene ring or a naphthalene ring is preferred, with a benzene ring being more preferred. No particular limitation is imposed on the number of hydroxy groups bound to the aromatic ring. The number of hydroxy groups bound to the aromatic ring is preferably 1 to 3, more preferably 1 or 2. Also, no particular limitation is imposed on the position of the aromatic ring to which a hydroxy group is bound. For example, when the polymer (A) has a hydroxy group bound to a benzene ring, the position of the hydroxy group bound to the benzene ring may be o-, m-, or p-position with respect to the other group.

To the aromatic ring to which a hydroxy group is bound, a substituent differing from a hydroxy group may further be bound. Examples of the substituent include a C1 to C5 alkyl group, a C1 to C5 alkoxy group, and a halogen atom (e.g., a fluorine atom, a chlorine atom, a bromine atom, or an iodine atom).

Specific examples of the second structural unit include the structural units represented by the following formula (ii):

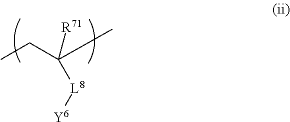

wherein R⁷¹ represents a hydrogen atom, a fluoro group, a methyl group, or a trifluoromethyl group; L² represents a single bond, —O—, —CO—, *⁶—COO—, or *⁶—CONH—; and “*6” represents a chemical bond to the main chain; and Y⁶ represents a monovalent group having a hydroxy group bound to an aromatic ring.

In the above formula (ii), R⁷¹ is preferably a hydrogen atom or a methyl group, from the viewpoint of co-polymerizability of a monomer forming the second structural unit. L² is preferably a single bond or *⁶—COO—, more preferably a single bond, from the viewpoint of further enhancing the sensitivity of the present composition. Y⁶ is preferably a group formed by removing one hydrogen atom from a ring moiety of an aromatic ring to which a hydroxy group is bound (i.e., a monovalent aromatic ring substituted by a hydroxy group). The aromatic ring in Y⁶ may further have a substituent differing from a hydroxy group. Specific examples of the substituent are the same as mentioned above.

Specific examples of the second structural unit further include the structural units represented by the following formulas:

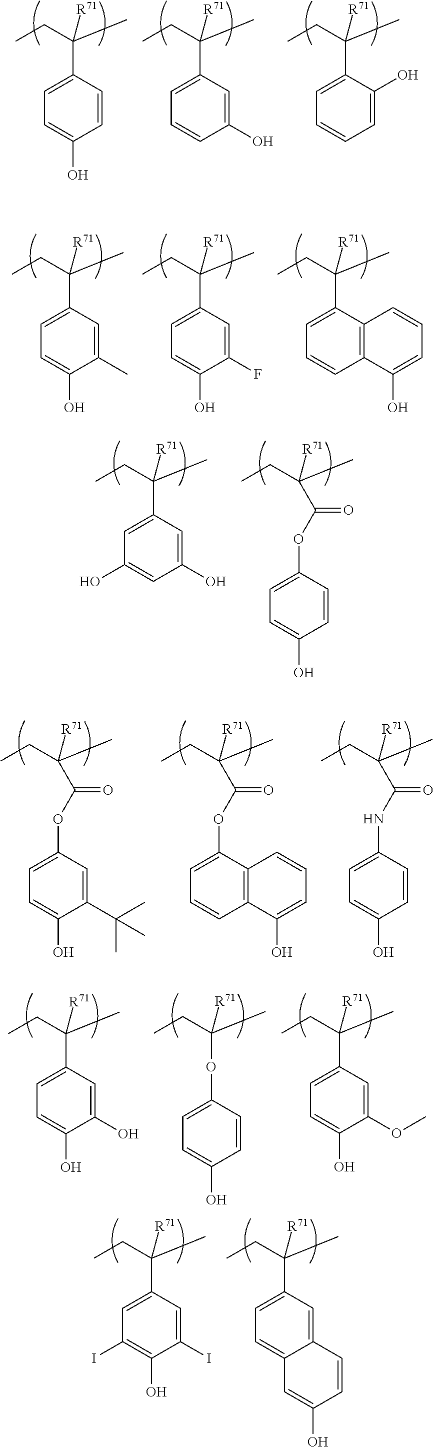

wherein R⁷¹ represents a hydrogen atom, a fluoro group, a methyl group, or a trifluoromethyl group.

The relative amount of the second structural unit in the polymer (A), with respect to the total amount of the structural units included in the polymer (A), is preferably 5 mol % or more, more preferably 10 mol % or more, still more preferably 15 mol % or more, yet more preferably 20 mol % or more. Also, the relative amount of the second structural unit in the polymer (A), with respect to the total amount of the structural units included in the polymer (A), is preferably 80 mol % or less, more preferably 75 mol % or less, still more preferably 70 mol % or less. Adjusting of the second structural unit content to satisfy the above conditions is preferred, since lithographic performance and development failure suppression performance of the present composition can be further enhanced.

In the case where a polymer including the second structural unit is yielded as the polymer (A), the second structural unit may be formed by performing polymerization while the phenolic hydroxy group is protected by a protecting group such as an alkaline-releasable group during polymerization (i.e., by use of a monomer having an aromatic ring to which a protected hydroxy group is bound), and then deprotecting through performing hydrolysis.

Notably, the present composition may contain, separate from a polymer including the first structural unit, a polymer including the second structural unit. From the viewpoint of yielding a radiation-sensitive composition exhibiting excellent lithographic performance (LWR performance or CDU performance) and development failure suppression property, the present composition preferably includes, as the polymer (A), a polymer including the first structural unit and the second structural unit in one molecule.

### Third Structural Unit

The third structural unit is a structural unit having a partial structure derived from a radiation-sensitive acid-generator (excepting the first structural unit or the second structural unit). Incorporation of the third structural unit into the polymer (A) can suppress a drop in resolution concomitant with diffusion of acid, to thereby further enhance lithographic performance. Also, performance as a radiation-sensitive acid-generating agent or an acid diffusion controlling agent can be imparted to the polymer (A), whereby the number of the components contained in the radiation-sensitive composition can be reduced to a maximum degree.

The partial structure derived from a radiation-sensitive acid-generator include in the third structural unit may be a partial structure derived from an ionic radiation-sensitive acid-generator or that derived from a non-ionic radiation-sensitive acid-generator. From the viewpoint of sensitivity, the third structural unit preferably includes a partial structure derived from an ionic radiation-sensitive acid-generator, more specifically, an onium salt structure formed of a radiation-sensitive cation and an organic anion.

For further enhancing the sensitivity of the present composition, the third structural unit may have a partial structure in which an iodo group is bound to an aromatic ring (preferably a benzene ring). In each structural unit, the number of the iodo group(s) bound to the aromatic ring is, for example, 1 to 5. When the third structural unit has an iodo group, the iodo group may be possessed by a radiation-sensitive cation moiety having an onium salt structure, an organic anion moiety, or both moieties.

Specific examples of preferred members of the third structural unit include a structural unit formed of a radiation-sensitive cation and a sulfonate anion, and a structural unit formed of a radiation-sensitive cation and a carboxylate anion. Specific examples of the third structural unit further include the structural units represented by the following formulas (iii-1), (iii-2), and (iii-3):

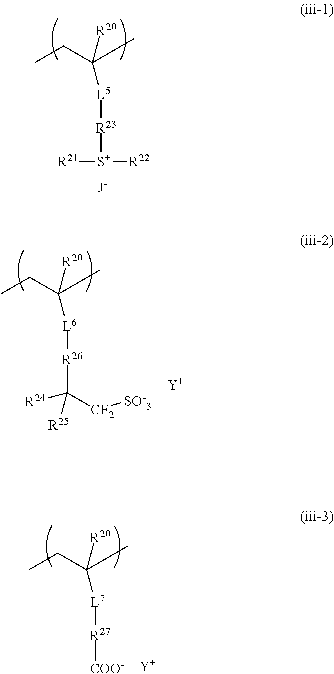

wherein, in formula (iii-1), R²⁰ represents a hydrogen atom, a fluorine atom, a methyl group, or a trifluoromethyl group; L⁵ represents —O—, *—COO—, or a divalent aromatic ring group; “*” represents a chemical bond to a main chain; R²³ represents a C1 to C6 substituted or unsubstituted alkanediyl group, a C2 to C6 substituted or unsubstituted alkenediyl group, or a C6 to C12 substituted or unsubstituted arylene group. Each of R²¹ and R²² independently represents a C1 to C12 substituted or unsubstituted alkyl group, a C2 to C12 substituted or unsubstituted alkenyl group, or a C6 to C20 substituted or unsubstituted aryl group; and J⁻ represents a sulfonate anion or a carboxylate anion;
in formula (iii-2), R²⁰ represents a hydrogen atom, a fluorine atom, a methyl group, or a trifluoromethyl group; L⁶ represents —O—, *—COO—, or a divalent aromatic ring group; “*” represents a chemical bond to a main chain; R²⁶ represents a C1 to C40 divalent organic group; each of R²⁴ and R²⁵ independently represents a hydrogen atom, a fluorine atom, a C1 to C10 alkyl group, or a C1 to C10 fluoroalkyl group; and Y⁺ represents a monovalent radiation-sensitive cation; and
in formula (iii-3), R²⁰ represents a hydrogen atom, a fluorine atom, a methyl group, or a trifluoromethyl group; L⁷ represents —O—, *—COO—, or a divalent aromatic ring group; “*” represents a chemical bond to a main chain; R²⁷ represents a C1 to C40 divalent organic group; and Y⁺ represents a monovalent radiation-sensitive cation.

In the above formulas (iii-1) to (iii-3), when any of L⁵ to L⁷ and R²¹ to R²⁷ has a substituent, examples of the substituent include a fluorine atom, a chlorine atom, a bromine atom, an iodine atom, an alkoxy group, a cycloalkyloxy group, an ester group, an alkylsulfonyl group, a cycloalkylsulfonyl group, a hydroxy group, a carboxy group, a cyano group, a nitro group, an acetyl group, a fluoroacetyl group, an alkoxycarbonyl group, an alkoxycarbonyloxy group, and an oxo group.

In the above formulas (iii-2) and (iii-3), the divalent organic group represented by R²⁶ or R²⁷ may be a group having a chain structure (hereinafter may also be referred to as a “chain organic group”) or a group having a cyclic structure (hereinafter may also be referred to as a “cyclic organic group”).

When the divalent organic group represented by R²⁶ or R²⁷ is a chain organic group, examples of the chain organic group include a C1 to C40 linear-chain or branched saturated hydrocarbon group, a C1 to C40 linear-chain or branched unsaturated hydrocarbon group, a C2 to C40 monovalent group having a (thio)ether group or an ester group between a carbon-carbon bond of a linear-chain or branched hydrocarbon group, and a C1 to C40 monovalent group formed by substituting any hydrogen atom of the above monovalent group or a linear-chain or branched hydrocarbon group.

When the divalent organic group represented by R²⁶ or R²⁷ is a cyclic organic group, examples of the cyclic structure possessed by R²⁶ or R²⁷ include a C3 to C20 alicyclic hydrocarbon structure, a C3 to C20 aliphatic heterocycle structure, and a C6 to C20 aromatic ring structure. These cyclic structures may have a substituent.

Examples of the C3 to C20 alicyclic hydrocarbon structure include a C3 to C20 alicyclic monocyclic hydrocarbon structure and a C6 to C20 alicyclic polycyclic hydrocarbon structure. The C3 to C20 alicyclic monocyclic hydrocarbon structure and the C6 to C20 alicyclic polycyclic hydrocarbon structure may be saturated or unsaturated. Also, the alicyclic polycyclic structure may be any of a bridged structure, a condensed ring structure, and a spiro ring structure.

Examples of the ring possessed by the alicyclic monocyclic hydrocarbon structure include cyclopentane, cyclohexane, cycloheptane, and cyclooctane, cyclopentene, cyclohexene, cycloheptene, cyclooctene, and cyclodecene. The alicyclic polycyclic hydrocarbon structure is preferably a bridged alicyclic saturated hydrocarbon structure or a condensed alicyclic saturated hydrocarbon structure. Examples thereof include a bicyclo[2.2.1]heptane structure, a bicyclo[2.2.2]octane structure, a tricyclo[3.3.1.1^{3,7}]decane structure, and a steroid structure.

Examples of the C3 to C20 aliphatic heterocycle structure include a cyclic ether structure, a lactone structure, a cyclic acetal structure, a cyclic carbonate structure, and a sultone structure. The aliphatic heterocycle structure may be a monocyclic structure or a polycyclic structure. The polycyclic structure may be any of a bridged structure, a condensed ring structure, and a spiro ring structure. Notably, the C3 to C20 aliphatic heterocycle structure represented by R²⁶ or R²⁷ may be a combination of two or more members of the bridged structure, the condensed ring structure, and the spiro ring structure. When the C3 to C20 aliphatic heterocycle structure represented by R²⁶ or R²⁷ has a spiro ring structure, the aforementioned two or more rings forming the spiro ring structure may be an aliphatic heterocycle singly or a combination of an aliphatic heterocycle and an alicyclic hydrocarbon ring.

Examples of the ring possessed by the C6 to C20 aromatic ring structure include a benzene ring, a naphthalene ring, an anthracene ring, an indene ring, and a fluorene ring.

Notably, when the R²⁶ or R²⁷ is a divalent cyclic organic group, R²⁶ or R²⁷ may have a chain structure in addition to the cyclic structure.

In the above formulas (iii-2) and (iii-3), the radiation-sensitive cation (Y⁺) preferably has a triarylsulfonium cation structure or a diaryliodonium cation structure. Specific examples of the radiation-sensitive cation include the same radiation-sensitive cation included in the radiation-sensitive acid-generating agent.

From the viewpoint of achieving higher sensitivity of the present composition, preferably, the radiation-sensitive cation (Y⁺) has a triarylsulfonium cation structure or a diaryliodonium cation structure, and an iodo group, a fluoro group, or a fluoro alkyl group is bound to an aromatic ring in the triarylsulfonium cation structure or the diaryliodonium cation structure (i.e., an aromatic ring to be bound to S⁺ or I⁺). The fluoro alkyl group is preferably a trifluoromethyl group.

Specific examples of the third structural unit further include the structural units represented by the following formulas.

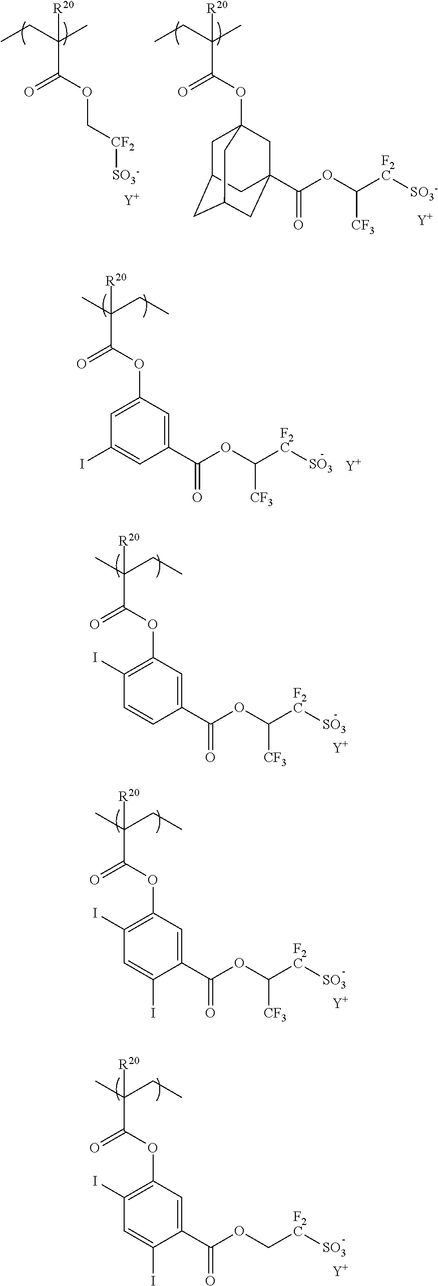

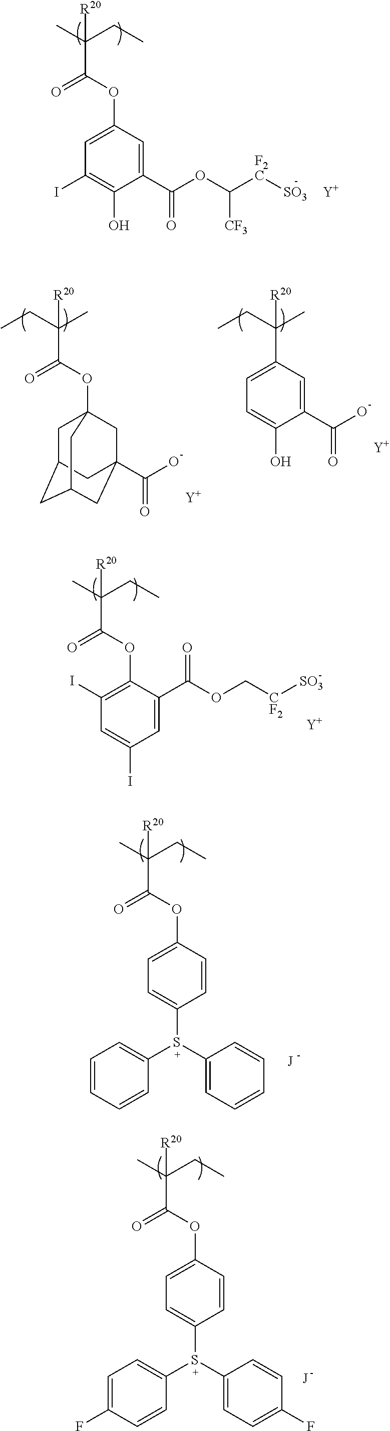

In the formulas, R²⁰ represents a hydrogen atom, a fluorine atom, a methyl group, or a trifluoromethyl group; Y⁺ represents a monovalent radiation-sensitive cation; and J⁻ represents a sulfonate anion or a carbonate anion.

When the polymer (A) includes the third structural unit, the relative amount of the third structural unit, with respect to the total amount of the structural units included in the polymer (A) is preferably 1 mol % or more, more preferably 3 mol % or more. Also, the relative amount of the third structural unit, with respect to the total amount of the structural units included in the polymer (A), is preferably 35 mol % or less, more preferably 30 mol % or less. By adjusting the third structural unit content to satisfy the above conditions, lithographic performance of the present composition can be further enhanced.

### Fourth Structural Unit

The fourth structural unit is a lactone structure, a cyclic carbonate structure, a sultone structure, or a structural unit having a ring structure formed by combining two or more members of the structures (excepting a unit corresponding to the first structural unit, the second structural unit, or the third structural unit).

Specific examples of the fourth structural unit include the structural units represented by the following formulas.

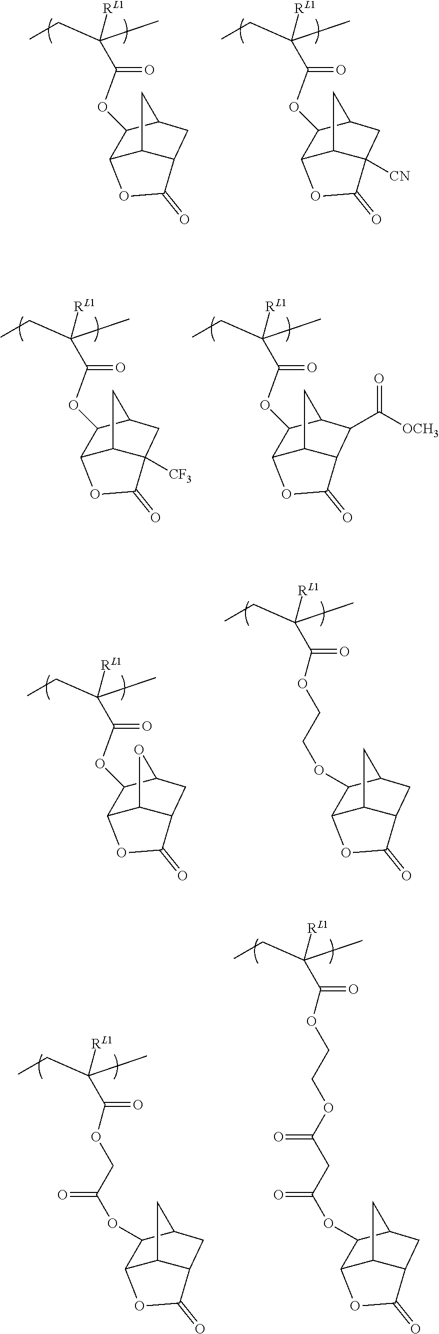

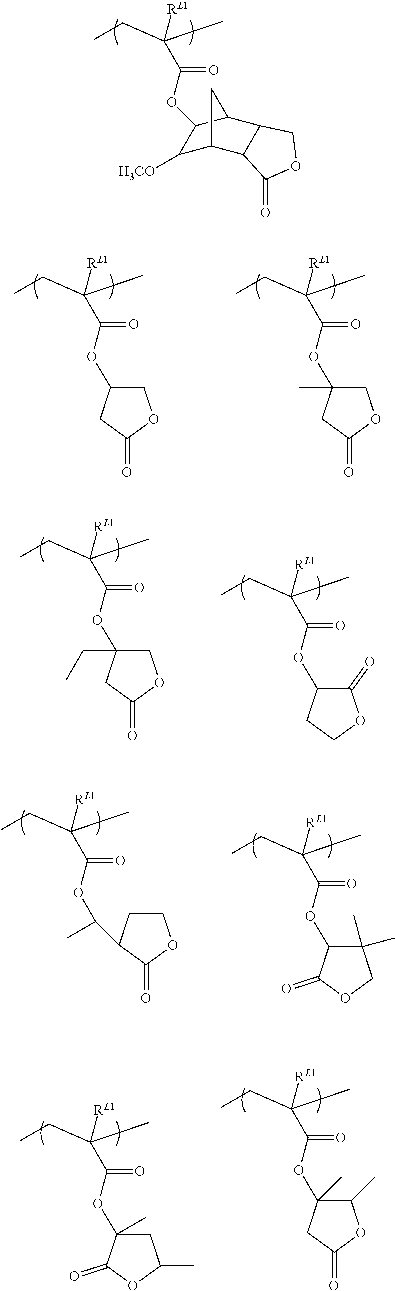

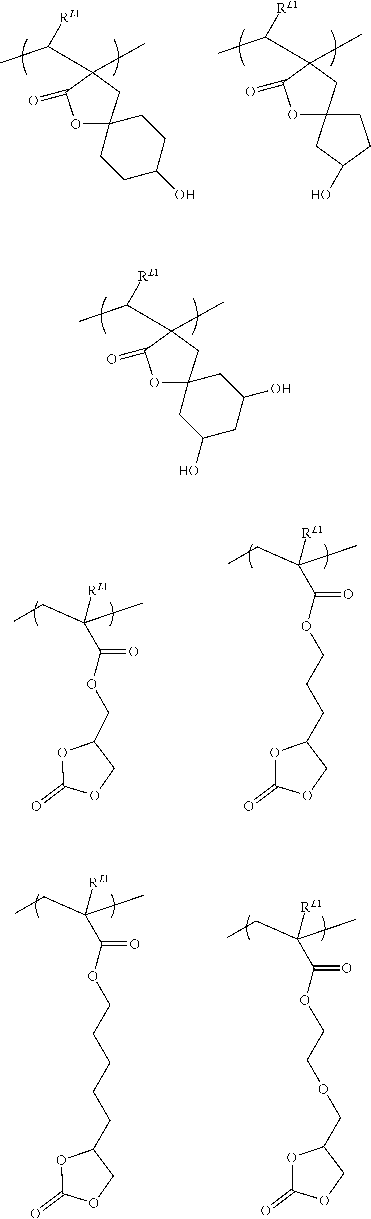

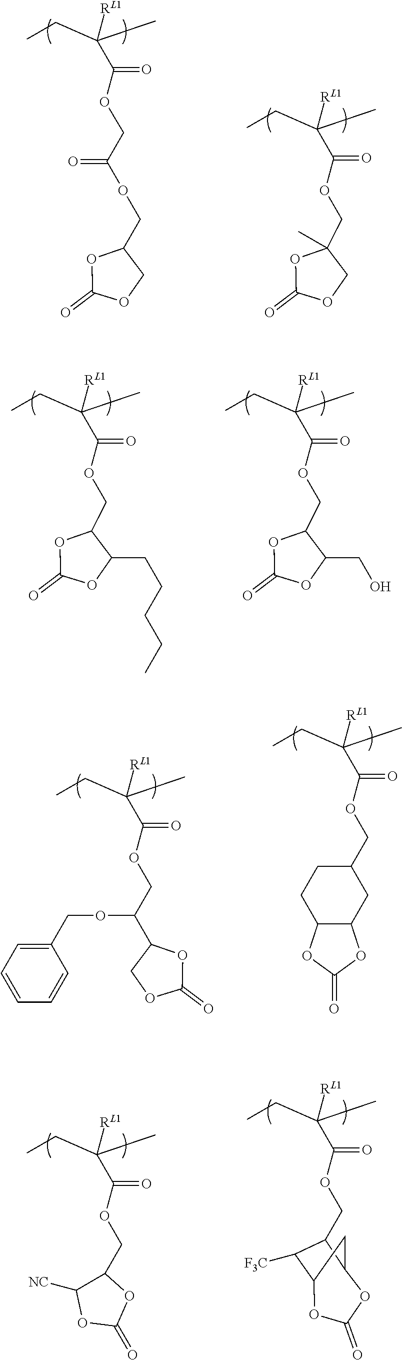

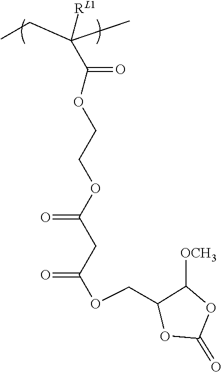

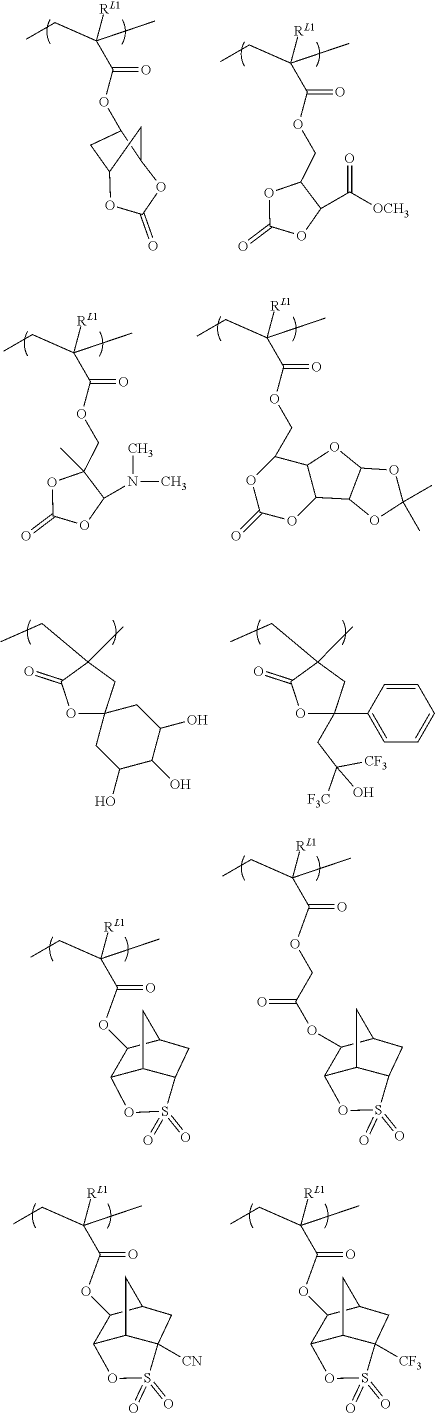

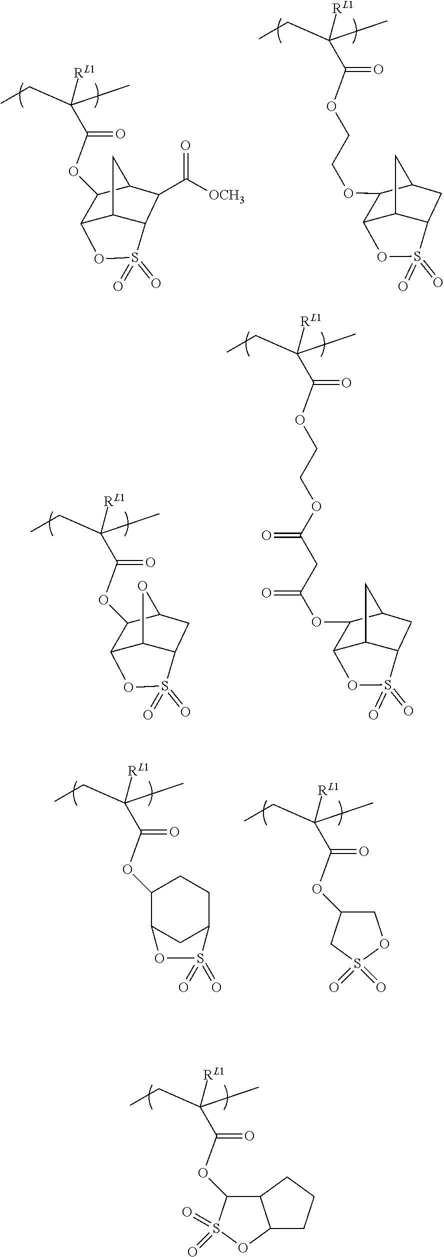

In the formulas, R^{L1} represents a hydrogen atom, a fluorine atom, a methyl group, or a trifluoromethyl group.

When the polymer (A) includes the fourth structural unit, the relative amount of the fourth structural unit, with respect to the total amount of the structural units included in the polymer (A) is preferably 1 mol % or more, more preferably 3 mol % or more. Also, the relative amount of the fourth structural unit, with respect to the total amount of the structural units included in the polymer (A), is preferably 30 mol % or less, more preferably 20 mol % or less, still more preferably 15 mol % or less.

### Fifth Structural Unit

The fifth structural unit is a structural unit having an alcoholic hydroxy group (excepting a unit corresponding to the first structural unit, the second structural unit, the third structural unit, or the fourth structural unit). As used herein, the term “alcoholic hydroxy group” refers to a group having a structure in which a hydroxy group is directly bound to an aliphatic hydrocarbon group. The aliphatic hydrocarbon group may be a chain hydrocarbon group or an alicyclic hydrocarbon group.

The fifth structural unit is preferably a structural unit which has an alcoholic hydroxy group and is derived from an unsaturated monomer. No particular limitation is imposed on the structure of the unsaturated monomer for providing the fifth structural unit. Specific examples of the fifth structural unit include the structural units represented by the following formulas.

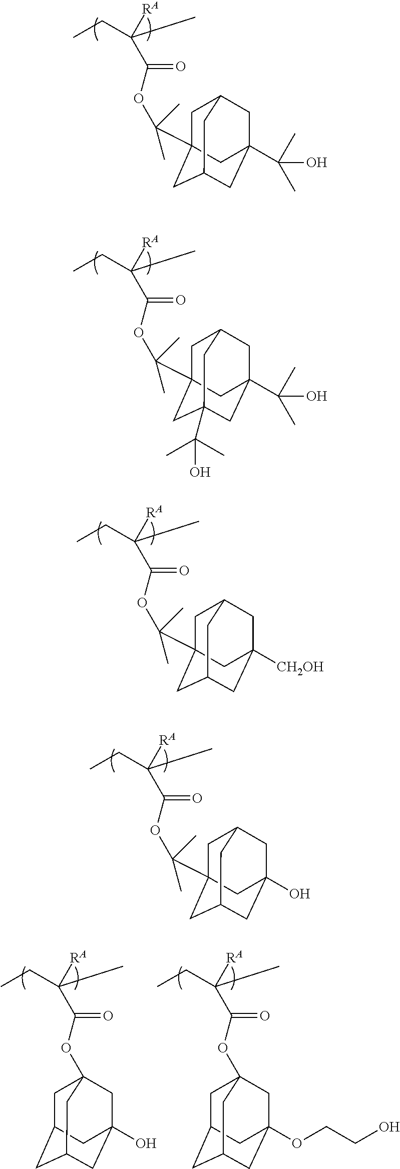

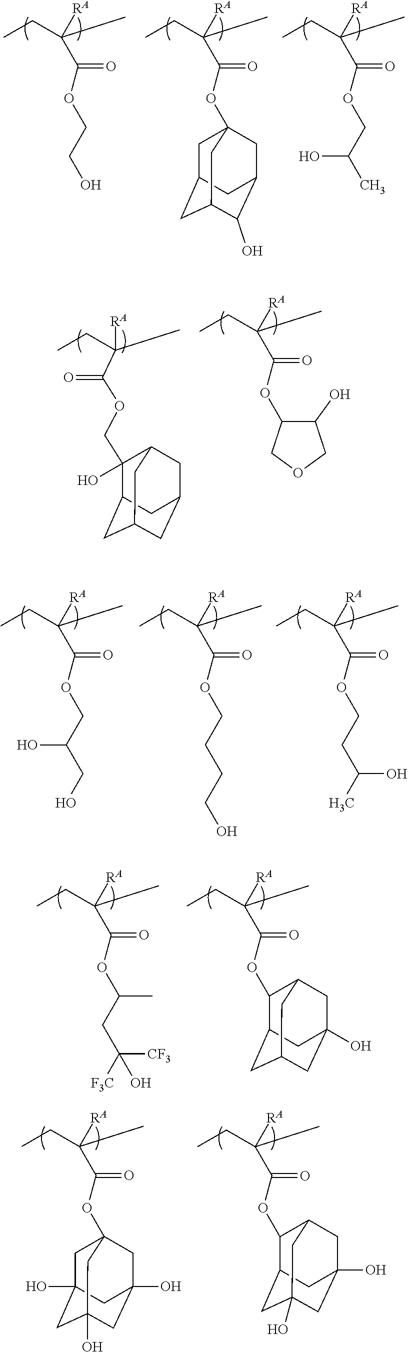

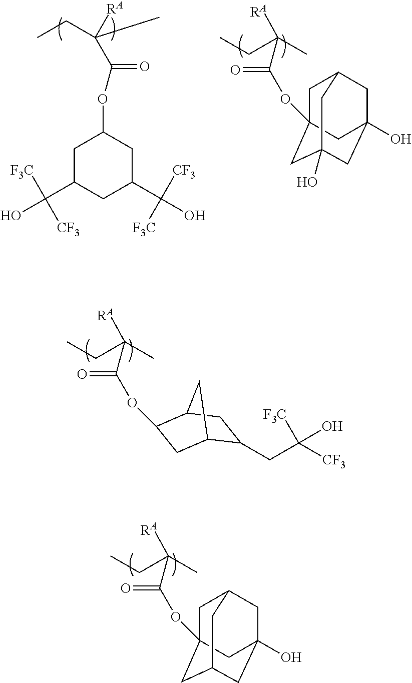

In the formulas, R^{A} represents a hydrogen atom, a fluorine atom, a methyl group, or a trifluoromethyl group.

When the polymer (A) includes the fifth structural unit, the relative amount of the fifth structural unit, with respect to the total amount of the structural units included in the polymer (A), is preferably 1 mol % or more, more preferably 3 mol % or more. Also, the relative amount of the fifth structural unit, with respect to the total amount of the structural units included in the polymer (A), is preferably 30 mol % or less, more preferably 20 mol % or less.

In addition to the aforementioned structural units, examples of the structural unit included in the polymer (A) include a structural unit having a cyano group, a nitro group, or a sulfonamide group (specifically, a structural unit derived from 2-cyanomethyladamantan-2-yl (meth)acrylate or the like); a structural unit having a non-acid-releasable hydrocarbon group (specifically, a structural unit derived from substituted or unsubstituted styrene (e.g., a styrene unit or an iodostyrene unit); a structural unit derived from vinylnaphthalene; a structural unit derived from n-pentyl (meth)acrylate; or the like); and a structural unit derived from a (meth)acrylic acid. The relative amounts of these structural units may be appropriately set individually, so long as the effect of the present disclosure are not impaired.

The weight average molecular weight (Mw) of the polymer (A), which is determined through gel permeation chromatography (GPC) and is reduced to polystyrene, is preferably 1,000 or more, more preferably 2,000 or more, still more preferably 3,000 or more, yet more preferably 4,000 or more. Also, the Mw of the polymer (A) is preferably 50,000 or less, more preferably 30,000 or less, still more preferably 20,000 or less, yet more preferably 15,000 or less. Adjusting the Mw of the polymer (A) so as to satisfy the above conditions is preferred, since coatability of the present composition can be improved, and development failure can be sufficiently suppressed.

The ratio (Mw/Mn, hereinafter may also be referred to as a “molecular weight dispersion”) of Mw to the number average molecular weight (Mn) of the polymer (A), which is determined through GPC and is reduced to polystyrene, is preferably 5.0 or less, more preferably 3.0 or less, still more preferably 2.0 or less. Also, the Mw/Mn of the polymer (A) is generally 1.0 or more.

In the present composition, the polymer (A) content, with respect to the entire solid content of the present composition, is preferably 50 mass % or higher, more preferably 70 mass % or higher, still more preferably 85 mass % or higher. Also, the polymer (A) content, with respect to the entire solid content of the present composition, is preferably 99 mass % or lower, more preferably 98 mass % or lower, still more preferably 95 mass % or lower. Preferably, the polymer (A) serves as a base resin of the present composition. As used herein, the term “base resin” refers to a polymer component in a relative amount of 50 mass % or more, with respect to the entire solid content of the present composition. Notably, when the present composition contains two or more polymers as the polymer (A), the total amount of the two or more polymers is preferably 50 mass % or more the total solid content of the present composition.

### <Additional Components>

The present composition may further contain a component differing from the polymer (A) as an optional component (hereinafter may also be referred to as an “additional component”). Examples of the additional component include a radiation-sensitive acid-generating agent, an acid diffusion control agent, a solvent, and a high-fluorine content polymer.

### (Radiation-Sensitive Acid-Generating Agent)

No particular limitation is imposed on the radiation-sensitive acid-generating agent, and a known radiation-sensitive acid-generating agent employed in resist pattern formation may be appropriately used. The radiation-sensitive acid-generating agent incorporated into the present composition may be an ionic radiation-sensitive acid-generating agent or a nonionic radiation-sensitive acid-generating agent, and is preferably an ionic radiation-sensitive acid-generating agent, for example, an onium salt formed of a radiation-sensitive cation and an organic anion. Typically, the radiation-sensitive acid-generating agent is preferably a compound that can generate an acid having an acidity higher than that of an acid generated by the light-degradable base (preferably, a strong acid such as a sulfonic acid, an imidic acid, or a methic acid) in the composition under general conditions, to thereby evoke release of an acid-releasable group. As used herein, the term “general conditions” refers to conducting post exposure baking (PEB) at 110° C. for 60 seconds.

When an onium salt is used as the radiation-sensitive acid-generating agent, from the viewpoints of achieving high sensitivity of the present composition and forming a resist film exhibiting more excellent lithographic performance, the radiation-sensitive cation in the radiation-sensitive acid-generating agent is preferably a sulfonium cation or an iodonium cation, more preferably a triarylsulfonium cation or a diaryliodonium cation. Specific examples of such cations include the cations represented by the following formula (1B) or (2B):

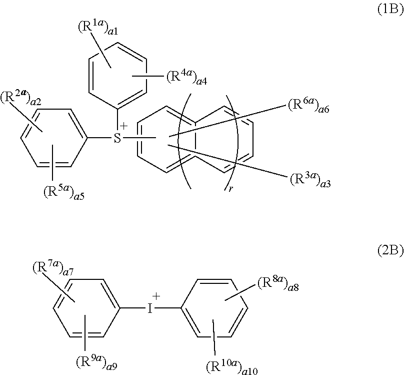

wherein, in formula (1B), each of R^{1a}, R^{2a}, and R^{3a} independently represents an iodo group, a fluoro group, or a fluoro alkyl group; each of R^{4a} and R^{5a} independently represents a monovalent substituent, or a single bond or a divalent group which links a ring structure to which R^{4a} and R^{5a} combined together are bound; R^{6a} represents a monovalent substituent; each of a1, a2, and a3 is independently an integer of 0 to 5; each of a4, a5, and a6 is independently an integer of 0 to 3; r is 0 or 1; and a1+a4≤5, a2+a5≤5, and a3+a6≤2×r+5 are satisfied; and
in formula (2B), each of R^{7a} and R^{8a} independently represents an iodo group, a fluoro group, or a fluoroalkyl group; each of R^{9a} and R^{10a} independently represents a monovalent substituent; each of a7 and a8 independently represents an integer of 0 to 5; each of a9 and a10 independently represents an integer of 0 to 3; and a7+a9≤5 and a8+a10≤5 are satisfied.

Each of R^{1a}, R^{2a}, R^{3a}, R^{7a}, and R^{8a} is preferably an iodo group, a fluoro group, a trifluoromethyl group, a 2,2,2-trifluoroethyl group, or a perfluoroethyl group, more preferably an iodo group, a fluoro group, or a trifluoromethyl group. From the viewpoint of enhancing the radiation sensitivity of the present composition, preferably a1, a2, and a3 satisfy “a1+a2+a3≥1,” and a7 and a8 satisfy “a7+a8≥1.” By using an onium salt having a structure in which an iodo group, a fluoro group, or a trifluoromethyl group is directly bound to an aromatic ring of a triarylsulfonium cation structure or a diaryliodonium cation structure, the sensitivity of the present composition can be further enhanced, and a radiation-sensitive composition exhibiting excellent lithographic performance can be yielded.

In the above formulas (1B) and (2B), the monovalent substituent represented by R^{4a}, R^{5a}, R^{6a}, R^{9a}, and R^{10a} may essentially a group differing from an iodo group, a fluoro group, or a fluoroalkyl group. Specific examples include a chloro group, a bromo group, a substituted or unsubstituted alkyl group (except for a fluoroalkyl group), a substituted or unsubstituted alkoxy group, a substituted or unsubstituted cycloalkyl group, a substituted or unsubstituted cycloalkyloxy group, an ester group, an alkylsulfonyl group, a cycloalkylsulfonyl group, a hydroxy group, a carboxy group, a cyano group, and a nitro group.

Specific examples of the radiation-sensitive cation include the cations respectively represented by the following formulas. However, the radiation-sensitive cation is not limited thereto.

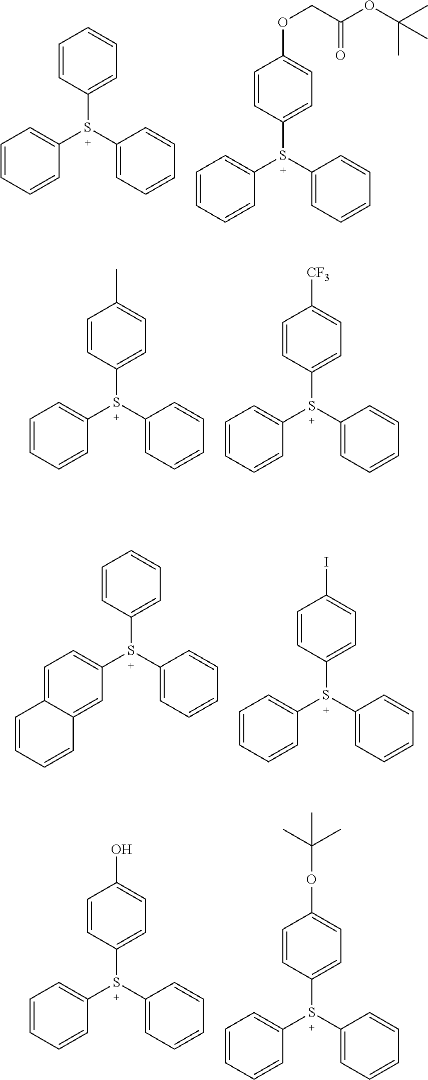

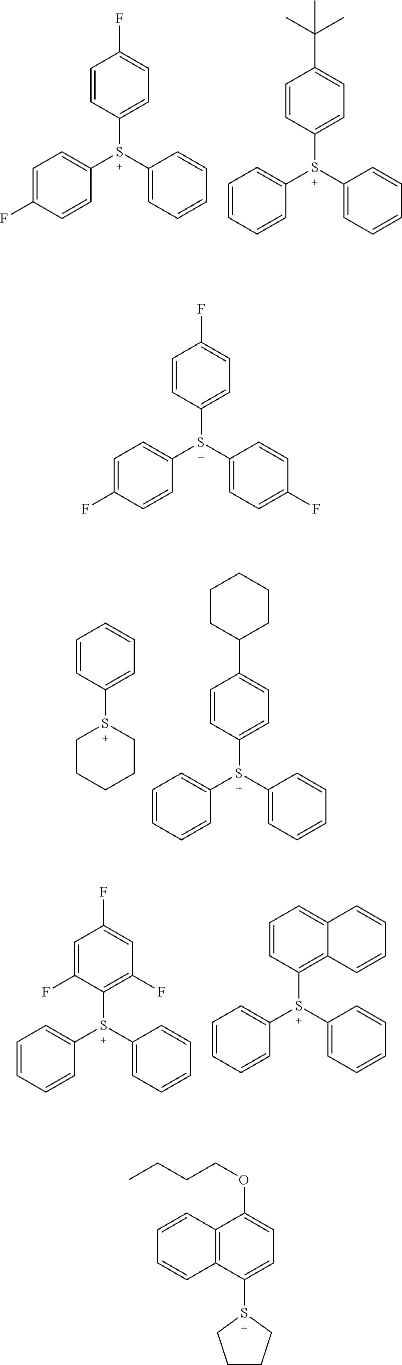

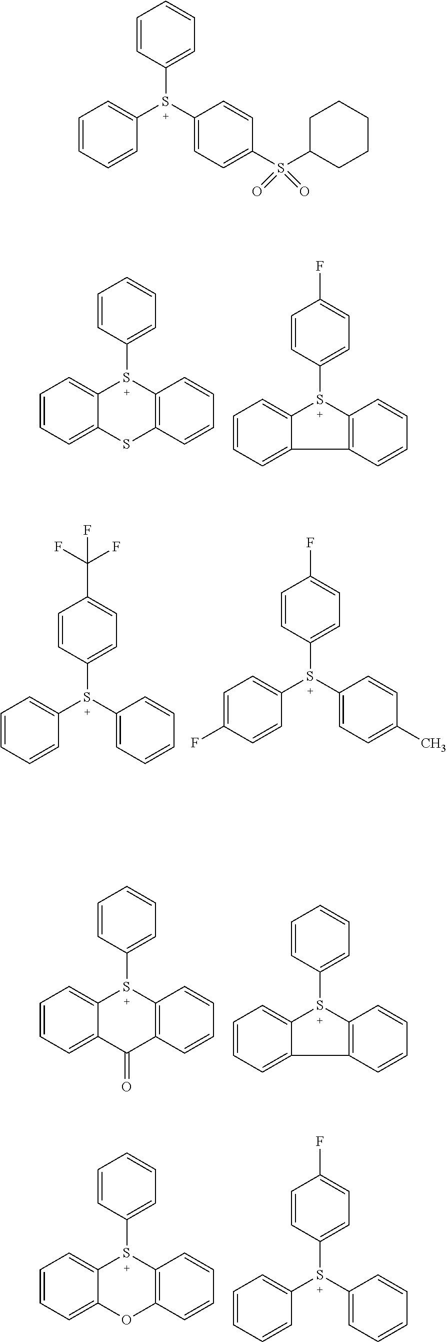

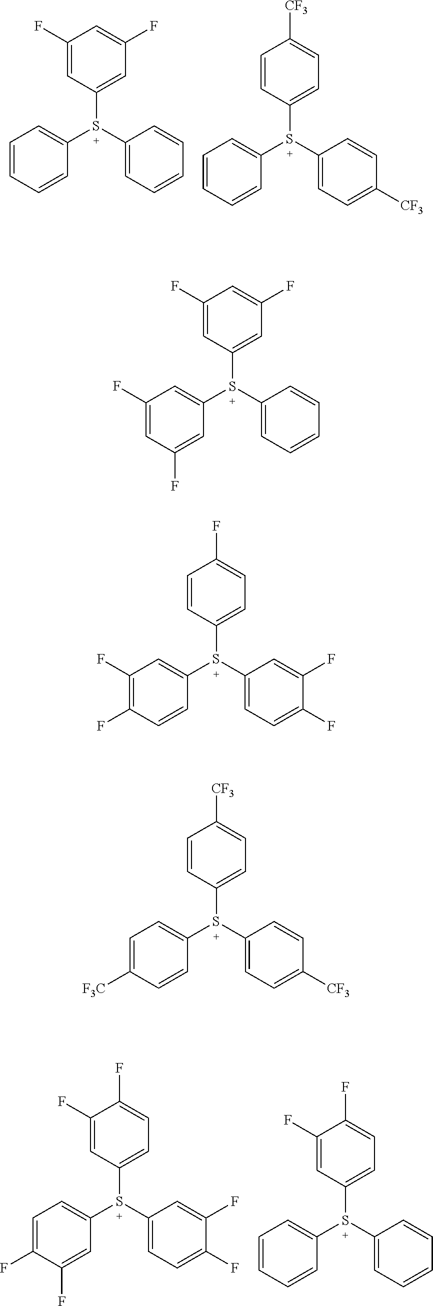

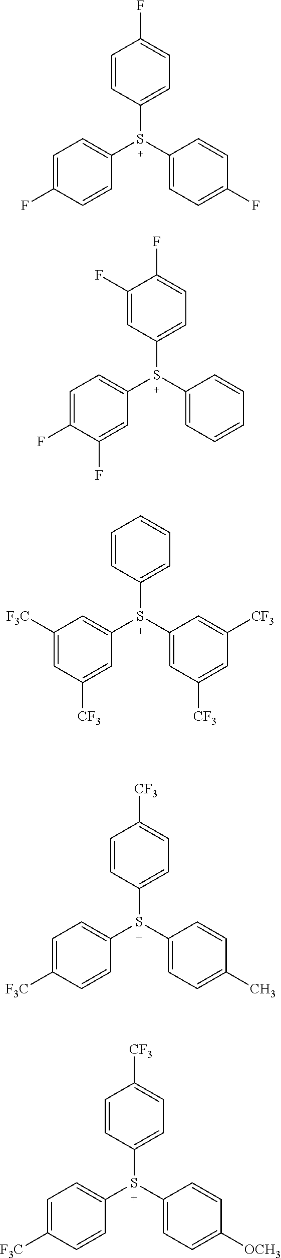

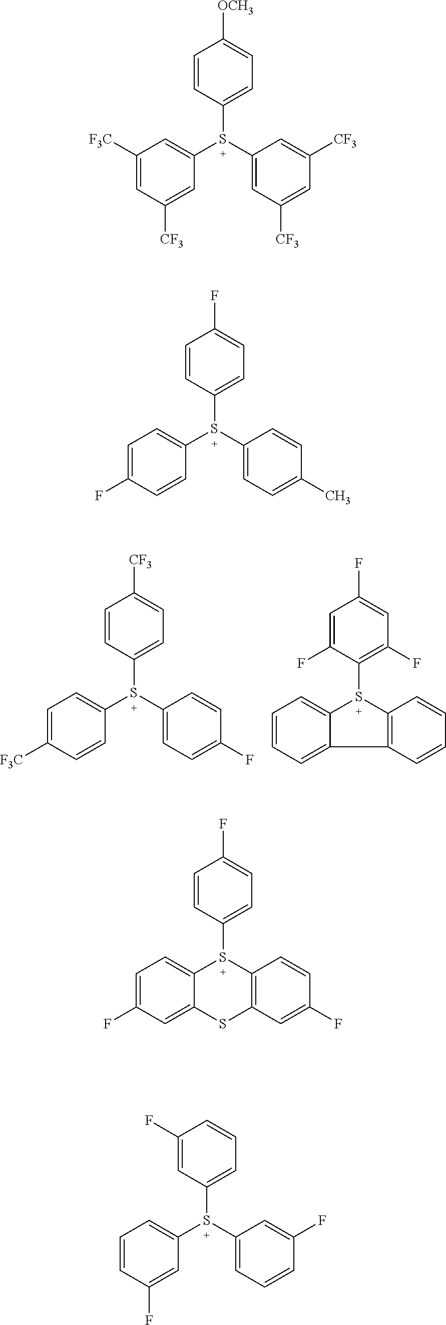

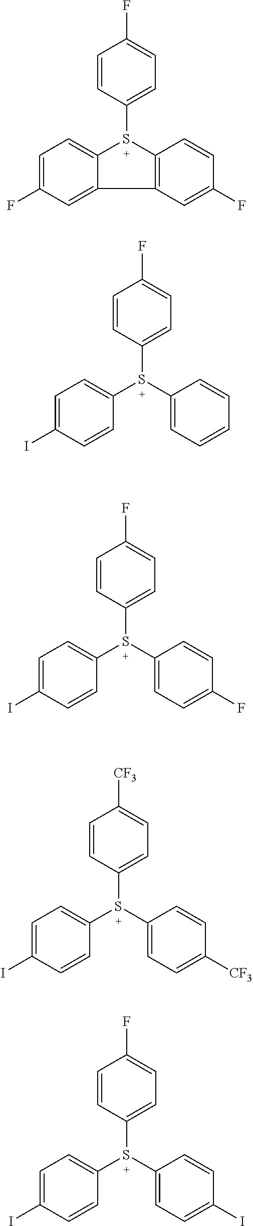

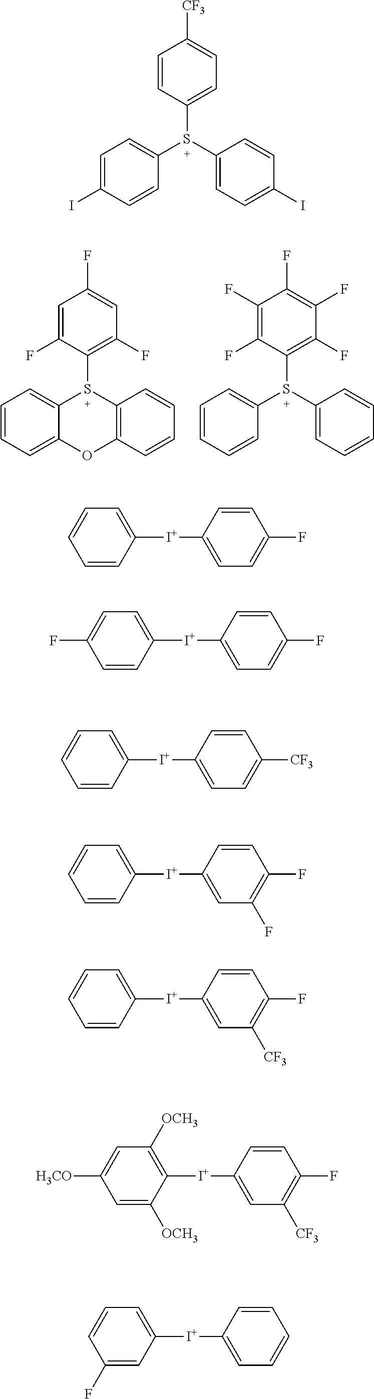

The organic anion included in the radiation-sensitive acid-generating agent is typically an anion formed by removing a proton from an acid residue of the corresponding organic acid. No particular limitation is imposed on the organic anion, so long as the anion is a compound that can generate an acid through exposure of the present composition to light. From the viewpoint of achieving enhanced sensitivity of the present composition, the organic anion included in the radiation-sensitive acid-generating agent is preferably a sulfonate anion, an imide anion, or a methide anion.

Specific examples of the organic anion forming the radiation-sensitive acid-generating agent include the anions and the like represented by the following formulas. However, the organic anion forming the radiation-sensitive acid-generating agent is not limited to the following structures.

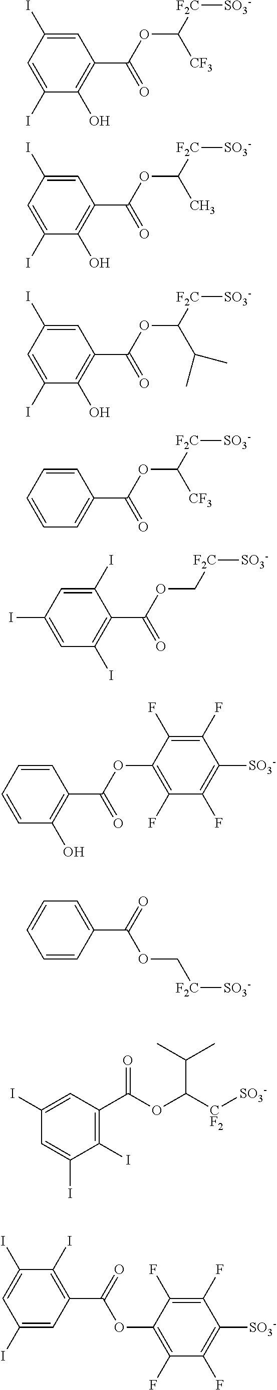

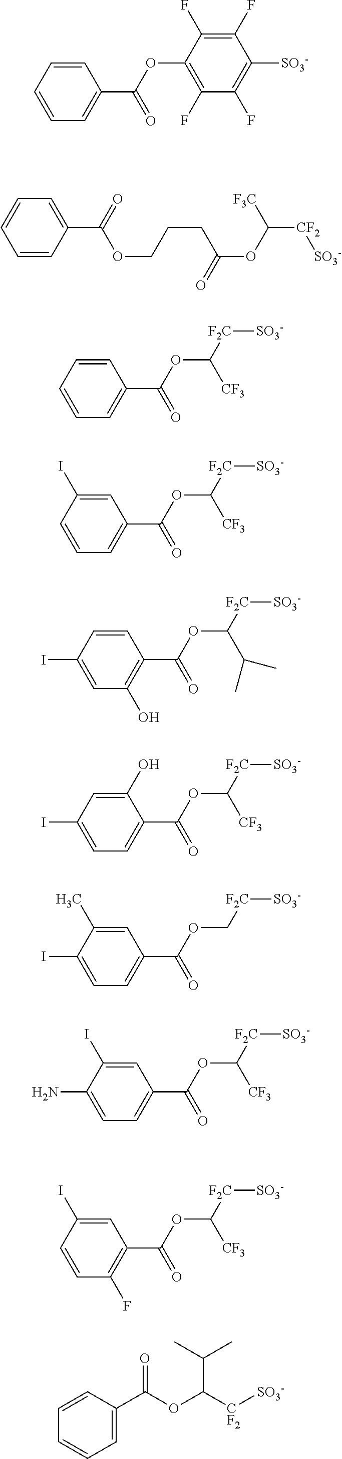

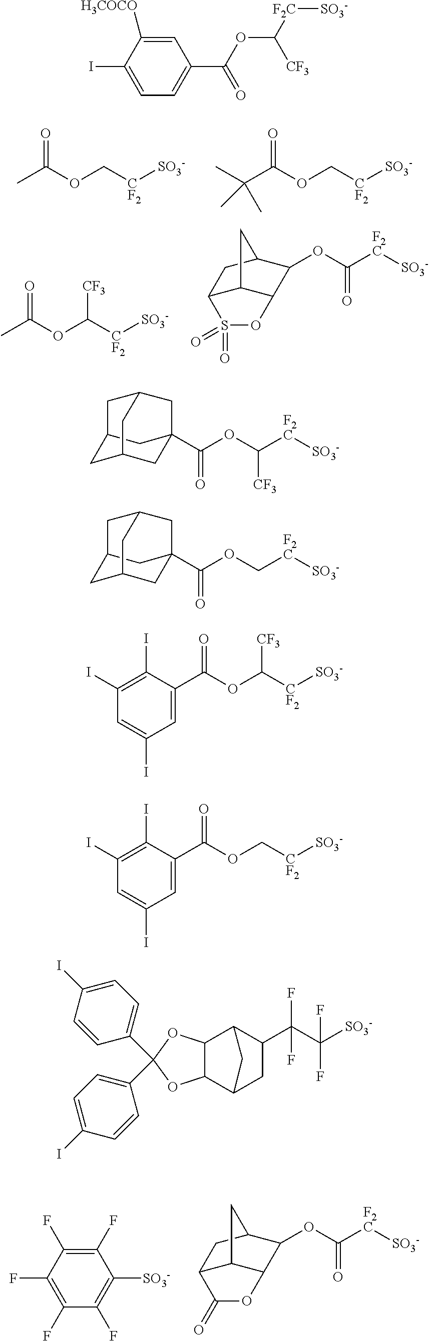

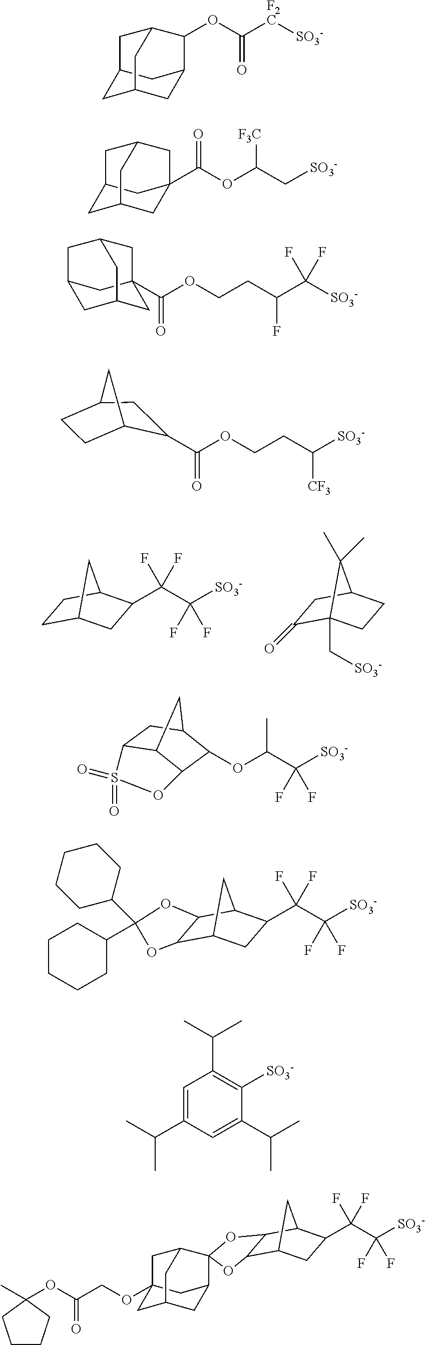

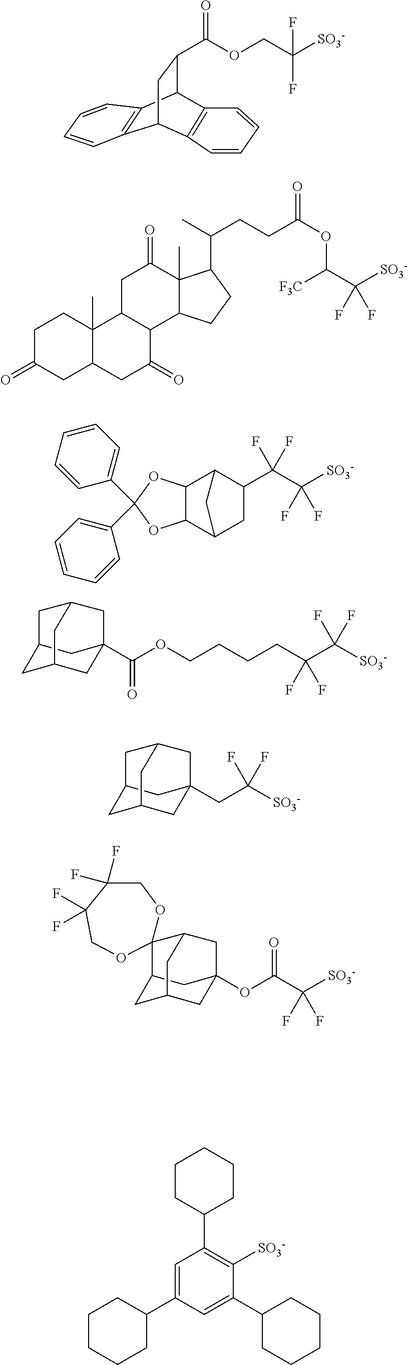

From the viewpoint of further enhancing sensitivity, while resolution and LWR performance of the present composition are maintained, the radiation-sensitive acid-generating agent preferably has an iodo group, more preferably an iodo group bound to an aromatic ring. When an onium salt is used as a radiation-sensitive acid-generating agent, the cation may have an iodo group; the anion may have an iodo group; or both the cation and the anion have an iodo group.

When the radiation-sensitive acid-generating agent is incorporated into the present composition, the relative amount of the radiation-sensitive acid-generating agent, with respect to 100 parts by mass of the polymer (A), is preferably 1 part by mass or more, more preferably 2 parts by mass or more. Also, e relative amount of the radiation-sensitive acid-generating agent, with respect to 100 parts by mass of the polymer (A), is preferably 50 parts by mass or less, more preferably 40 parts by mass or less, still more preferably 35 parts by mass or less. By adjusting the radiation-sensitive acid-generating agent content to satisfy the above conditions, sensitivity and LWR performance of the present composition can be further enhanced,

### (Acid Diffusion Control Agent)

The acid diffusion control agent is a component that can suppress chemical reaction by an acid in the light-unexposed part, with a mechanism of suppressing diffusion of the acid in a resist film, the acid generated in the resist film through exposure of the present composition to light. By incorporating the acid diffusion control agent into the present composition, lithographic characteristics (LWR performance and CDU performance) of the present composition can be enhanced. Furthermore, variation in line width of a resist pattern, which would otherwise be caused by variation in post-exposure time (i.e., duration of time from light exposure to development) can be suppressed, whereby a radiation-sensitive composition having excellent process stability can be obtained. Examples of the acid diffusion control agent include a nitrogen-containing compound and a light-degradable base.

### Nitrogen-Containing Compound

As the nitrogen-containing compound, a known nitrogen-containing compound used for resist pattern formation may be used. Specific examples of the nitrogen-containing compound include an amino group-containing compound (e.g., alkylamine, aromatic amine, or polyamine), an amide group-containing compound, a urea compound, a nitrogen-containing heterocyclic compound (e.g., N-(undecan-1-ylcarbonyloxyethyl)morpholine), and a nitrogen-containing compound having an acid-releasable group (e.g., N-(t-butoxycarbonyl)di-n-octylamine or N-t-butoxycarbonyl-4-hydroxypiperidine).

### Light-Degradable Base

As the light-degradable base, preferably used is a compound which generates, upon light exposure, an acid having an acidity lower than that of the acid generated by a monomer that can provide the third structural unit, in the case where the radiation-sensitive acid-generating agent or the polymer (A) include the third structural unit. Meanwhile, the degree of acidity can be evaluated on the basis of acid dissociation constant (pKa). The acid dissociation constant (pKa) of the acid generated by the acid diffusion control agent is generally −3 or higher, preferably −1 to 7, more preferably 0 to 5. The acid generated by the light-degradable base is typically a weak acid which does not evoke release of an acid-releasable group under the aforementioned general conditions.

As the light-degradable base, preferably used is an onium salt formed of a radiation-sensitive cation and an organic anion. From the viewpoint of enhancing the lithographic characteristics of the present composition, the light-degradable base is preferably an onium salt that can generate a carboxylic acid, a sulfonic acid, or a sulfonamide. Also, from the viewpoint of successfully forming a resist film exhibiting higher LWR performance, an onium salt having a sulfonium cation structure or a iodonium cation structure is preferably used as the light-degradable base. Specific examples of the radiation-sensitive cation included in the light-degradable base include the same cations exemplified as the cations which the radiation-sensitive acid-generating agent may include.

Specific examples of the light-degradable base include the onium salts represented by the following formulas. However, the light-degradable base is not limited to the following structures. Notably, in the formulas, “Q⁺” represents a radiation-sensitive cation.

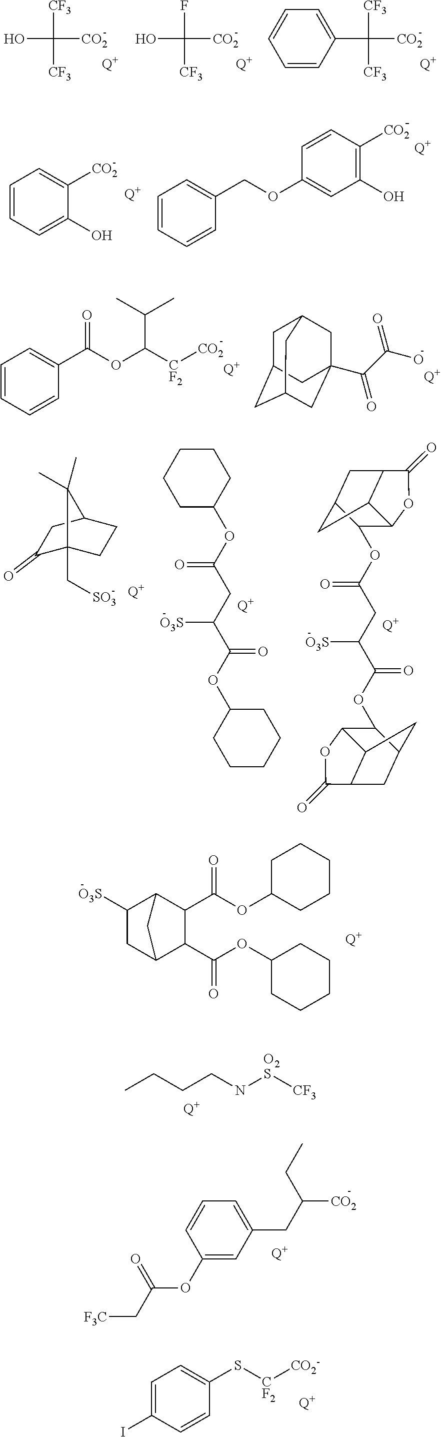

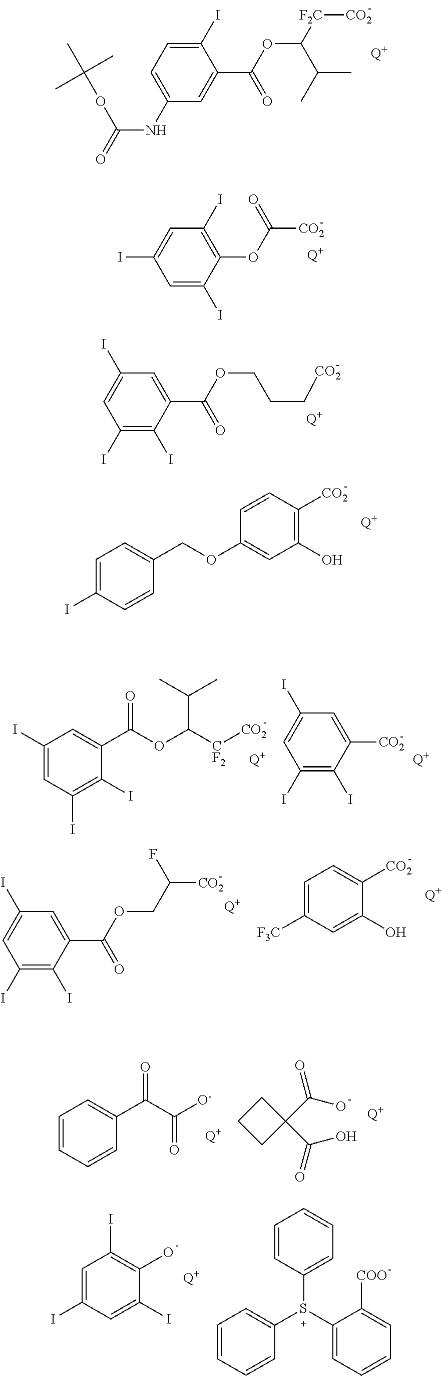

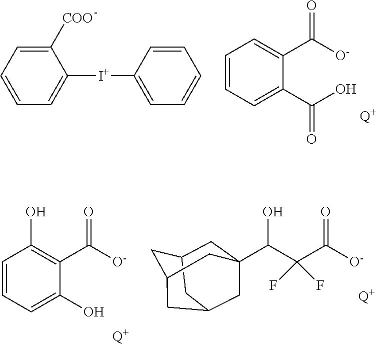

When the light-degradable base is sued as the acid diffusion control agent, from the viewpoint of further enhancing sensitivity, the light-degradable base has an iodo group, more preferably an iodo group bound to an aromatic ring. In this case, the cation forming the light-degradable base may have an iodo group; the anion may have an iodo group; or both the cation and the anion may have an iodo group.

When the acid diffusion control agent is incorporated into the present composition, the relative amount of the acid diffusion control agent in the present composition, with respect to the total amount (as 100 parts by mole) of the monomer(s) providing the third structural unit included in the polymer (A), is preferably 1 part by mole or more, more preferably 2 parts by mole, still more preferably 5 parts by mole. Also, the relative amount of the acid diffusion control agent, with respect to the total amount (as 100 parts by mole) of the monomer(s) providing the third structural unit included in the polymer (A), is preferably 50 parts by mole, more preferably 40 parts by mole, still more preferably 35 parts by mole. By adjusting the acid diffusion control agent content to satisfy the above conditions, LWR performance of the present composition can be further enhanced.

### (Solvent)

No particular limitation is imposed on the solvent, so long as the solvent can dissolve or disperse the components incorporated into the present composition. Examples of the solvent include an alcohol, an ether, a ketone, an amide, an ester, and a hydrocarbon.

Examples of the alcohol include C1 to C18 aliphatic monoalcohols such as 4-methyl-2-pentanol and n-hexanol; C3 to C18 alicyclic monoalcohols such as cyclohexanol; C2 to C18 polyhydric alcohols such as 1,2-propylene glycol; and C3 to C19 polyhydric alcohol partial ethers such as propylene glycol monomethyl ether. Examples of the ether include dialkyl ethers such as diethyl ether, dipropyl ether, dibutyl ether, dipentyl ether, diisoamyl ether, dihexyl ether, and diheptyl ether; cyclic ethers such as tetrahydrofuran and tetrahydropyran; and aromatic ring-containing ethers such as diphenyl ether and anisole.

Examples of the ketone include chain ketones such as acetone, methyl ethyl ketone, methyl n-propyl ketone, methyl n-butyl ketone, diethyl ketone, methyl isobutyl ketone, 2-heptanone, ethyl n-butyl ketone, methyl n-hexyl ketone, diisobutyl ketone, and trimethylnonanone; cyclic ketones such as cyclopentanone, cyclohexanone, cycloheptanone, cyclooctanone, and methylcyclohexanone; and 2,4-pentanedione, acetonylacetone, acetophenone, and diacetone alcohol. Examples of the amide include cyclic amides such as N,N′-dimethylimidazolidinone and N-methylpyrrolidone; and chain amides such as N-methylformamide, N,N-dimethylformamide, N,N-diethylformamide, acetamide, N-methylacetamide, N,N-dimethylacetamide, and N-methylpropionamide.

Examples of the ester include monocarboxylic acid esters such as n-butyl acetate and ethyl lactate; polyhydric alcohol carboxylates such as propylene glycol diacetate; polyhydric alcohol partial ether carboxylates such as propylene glycol monomethyl ether acetate; polybasic carboxylic acid diesters such as diethyl oxalate; carbonates such as dimethyl carbonate and diethyl carbonate; and cyclic esters such as γ-butyrolactone. Examples of the hydrocarbon include C5 to C12 aliphatic hydrocarbons such as n-pentane and n-hexane; and C6 to C16 aromatic hydrocarbons such as toluene and xylene.

The solvent preferably includes at least one member selected from the group consisting of the ester and the ketone, more preferably at least one member selected from the group consisting of polyhydric alcohol partial ether carboxylates and cyclic ketones.

### <High Fluorine-Content Polymer>

The high-fluorine content polymer (hereinafter may also be referred to simply as a “polymer (E)”) is a polymer having a fluorine atom content (by mass) greater than that of the polymer (A). When the present composition contains the polymer (E), the polymer (E) can be localized on the surface of the resist film, with respect to the polymer (A). As a result, water repellency of the surface of the resist film in liquid immersion light exposure, and lithographic performance can be enhanced.

No particular limitation is imposed on the fluorine atom content of the polymer (E), so long as it is greater than the fluorine atom content of the polymer (A). The fluorine atom content of the polymer (E) is preferably 1 mass % or higher, more preferably 2 mass % or higher, still more preferably 4 mass % or higher, yet more preferably 7 mass % or higher. Also, the fluorine atom content of the polymer (E) is preferably 60 mass % or lower, more preferably 40 mass % or lower, still more preferably 30 mass % or lower. The fluorine atom content (mass %) of a polymer can be obtained by determining the structure of the polymer through ¹³C-NMR spectrometry or the like and calculating the content based on the structure determined.

Examples of the fluorine atom-containing structural unit included in the polymer (E) (hereinafter may also be referred to as a “structural unit (F)”) include the structural unit (fa) and structural unit (fb) below. The polymer (E) may include, as the structural unit (F), any of the structural unit (fa) and the structural unit (fb), or both of the structural unit (fa) and the structural unit (fb).

### [Structural Unit (Fa)]

The structural unit (fa) is a structural unit represented by the following formula (8-1). By incorporated the structural unit (fa), the fluorine atom content of the polymer (E) can be controlled:

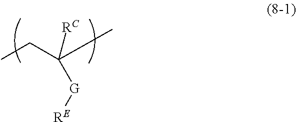

wherein R^{C} represents a hydrogen atom, a fluoro group, a methyl group, or a trifluoromethyl group; G represents a single bond, an oxygen atom, a sulfur atom, —COO—, —SO₂—O—NH—, —CONH—, or —O—CO—NH—. R^{E} represents a C1 to 20 monovalent fluorinated chain hydrocarbon group or a C3 to C20 monovalent fluorinated alicyclic hydrocarbon group.

In the above formula (8-1), R^{C} preferably represents a hydrogen atom or a methyl group, more preferably a methyl group, from the viewpoint of co-polymerizability of the monomer(s) providing the structural unit (fa). Also, from the he viewpoint of co-polymerizability of the monomer(s) providing the structural unit (fa), G is preferably a single bond —COO—, more preferably —COO—.

Examples of the C1 to C20 monovalent fluorinated chain hydrocarbon group represented by R^{E} include a group formed by partially substituting hydrogen atoms of the C1 to C20 linear-chain or branched alkyl group by a fluorine atom. Examples of the C3 to C20 monovalent fluorinated alicyclic hydrocarbon group represented by R^{E} include groups each formed by substituting partially or entire hydrogen atoms contained in the C3 to C20 monocyclic or polycyclic alicyclic hydrocarbon group by a fluorine atom. Among them, R^{E} is preferably a monovalent fluorinated chain hydrocarbon group, more preferably a fluorinated alkyl group, still more preferably a 2,2,2-trifluoroethyl group or a 1,1,1,3,3,3-hexafluoropropyl group or a 5,5,5-trifluoro-1,1-diethylpentyl group.

When the polymer (E) includes the structural unit (fa), the relative amount of the structural unit (fa), with respect to all the structural units forming the polymer (E), is preferably 30 mol % or more, more preferably 40 mol % or more, still more preferably 50 mol % or more. Also, the relative amount of the structural unit (fa), with respect to all the structural units forming the polymer (E), is preferably 95 mol % or less, more preferably 90 mol % or less, still more preferably 85 mol % or less. By adjusting the structural unit (fa) content to satisfy the above conditions, the fluorine atom content of the polymer (E) can be appropriately modified, to thereby promote localization of the polymer (E) in the surface layer of the resist film. As a result, water repellency of the surface of the resist film in liquid immersion light exposure can be enhanced.

### [Structural Unit (Fb)]

The structural unit (fb) is a structural unit represented by the following formula (8-2). By incorporating the structural unit (fb) into the polymer (E), solubility of the polymer (E) in an alkali developer is enhanced, whereby development occurrence of development failure can be further suppressed.

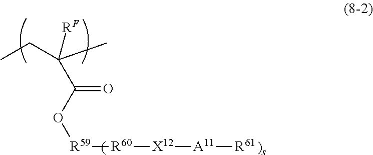

In formula (8-2), R^{F} represents a hydrogen atom, a fluoro group, a methyl group, or a trifluoromethyl group; R⁵⁹ represents a C1 to C20 (s+1)-valent hydrocarbon group or a group formed by bonding an oxygen atom, a sulfur atom, —NR′—, a carbonyl group, —CO—O—, or —CO—NH— to an R⁶⁰ side end of the hydrocarbon group; R¹ represents a hydrogen atom or a monovalent organic group; R⁶⁰ represents a single bond or a C1 to C20 divalent organic group; X¹² represents a single bond or a C1 to C20 divalent hydrocarbon group or a C1 to C20 divalent fluorinated chain hydrocarbon group; A¹¹ represents an oxygen atom, —NR″—, —CO—O—*, or —SO₂—O—*; R″ represents a hydrogen atom or a C1 to C10 monovalent hydrocarbon group; “*” represents a bonding site to R⁶¹; R⁶¹ represents a hydrogen atom or a C1 to C30 monovalent organic group; s is an integer of 1 to 3; and, in the case of s of 2 or 3, a plurality of R⁶⁰, X¹², A¹¹, and R⁶¹ are identical to or different from one another.

The structural unit (fb) is categorized into two cases. That is the unit has an alkali-soluble group, or a group whose solubility in a developer increases through release thereof by the action of alkali (hereinafter may also be referred to simply as a “alkali-releasable group”).

When the structural unit (fb) has an alkali-soluble group, R⁶¹ represents a hydrogen atom; and A¹¹ represents an oxygen atom, —COO—*, or —SO₂O—*. “*” represents a site bound to R⁶¹. X¹² represents a single bond, a C1 to C20 divalent hydrocarbon group or a C1 to C20 divalent fluorinated chain hydrocarbon group. When A¹¹ is an oxygen atom, X¹² represents a fluorinated hydrocarbon group having a fluorine atom or a fluoro alkyl group at a carbon atom to which A¹¹ is bound. R⁶⁰ represents a single bond or a C1 to C20 divalent organic group. When s is 2 or 3, a plurality of R⁶⁰, X¹², A¹¹, and R⁶¹ are respectively identical to or different from one another. By incorporating an alkali-soluble group into the structural unit (fb), affinity to an alkali developer increases, to thereby suppress development failure.

When the structural unit (fb) has an alkali-releasable group, R⁶¹ represents a C1 to C30 monovalent organic group; and A¹¹ represents an oxygen atom, —NR″—, —COO—*, or —SO₂O—*. “*” represents a site bound to R⁶¹. X¹² represents a single bond or a C1 to C20 divalent fluorinated chain hydrocarbon group. R⁶⁰ represents a single bond or a C1 to C20 divalent organic group. When A¹¹ is —COO—* or —SO₂O—*, each of X¹² and R⁶¹ has a fluorine atom at a carbon atom bound to A¹¹ or a carbon atom adjacent thereto. When A¹¹ is an oxygen atom, each of X¹² and R⁶⁰ is a single bond; R⁵⁹ is a structure in which a carbonyl group is bound to the R⁶⁰ side end of the C1 to C20 hydrocarbon group; and R⁶¹ represents an organic group having a fluorine atom. When s is 2 or 3, a plurality of R⁶⁰, X¹², A¹¹, and R⁶¹ are respectively identical to or different from one another. By incorporating an alkali-releasable group into the structural unit (fb), the state of the surface of the resist film is changed from hydrophobic to hydrophilic in the alkali development step. As a result, affinity to an alkali developer increases, to thereby more efficiently suppress development failure. The structural unit (fb) having an alkali-releasable group particularly preferably has a structure in which A¹¹ is —COO—*, and R⁶¹ or X¹² or both have a fluorine atom.

When the polymer (E) includes the structural unit (fb), the relative amount of the structural unit (fb), with respect to all the structural units forming the polymer (E), is preferably 40 mol % or more, more preferably 50 mol % or more, still more preferably 60 mol % or more. Also, the relative amount of the structural unit (fb), with respect to all the structural units forming the polymer (E), is preferably 95 mol % or less, more preferably 90 mol % or less, still more preferably 85 mol % or less. By adjusting the structural unit (fb) content to satisfy the above conditions, water repellency of the surface of the resist film in liquid immersion light exposure can be further enhanced.

In addition to the structural units (fa) and (fb), the polymer (E) may include a structural unit (I) having an acid-releasable group or a structural unit having an alicyclic hydrocarbon structure and represented by the following formula (9) (hereinafter may also be referred to as a “structural unit (G)”).

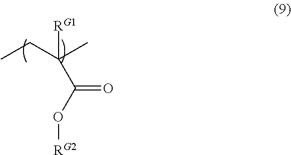

In the above formula (9), R^{G1} represents a hydrogen atom, a fluorine atom, a methyl group, or a trifluoromethyl group; and R^{G2} represents a C3 to C20 monovalent alicyclic hydrocarbon group.)

In the above formula (9), examples of the C3 to C20 monovalent alicyclic hydrocarbon group represented by R^{G2} include the same groups exemplified as the C3 to C20 monovalent alicyclic hydrocarbon group represented by any of R¹³ to R¹⁵ in the above formula (3).

When the polymer (E) includes the structural unit represented by the above formula (9), the relative amount of the structural unit, with respect to all the structural units forming the polymer (E), is preferably 10 mol % or more, more preferably 20 mol % or more, still more preferably 30 mol % or more. Also, the relative amount of the structural unit represented by the above formula (9), with respect to all the structural units forming the polymer (E), is preferably 70 mol % or less, more preferably 60 mol % or less, still more preferably 50 mol % or less.

The Mw of the polymer (E) as determined through GPC is preferably 1,000 or higher, more preferably 3,000 or higher, still more preferably 4,000 or higher. Also, the Mw of the polymer (E) is preferably 50,000 or lower, more preferably 30,000 or lower, still more preferably 20,000 or lower. The molecular weight distribution (Mw/Mn), which is a ratio of Mw to Mn determined through GPC of the polymer (E), is preferably 1 to 5, more preferably 1 to 3.

When the present composition contains the polymer (E), the relative amount of the polymer (E) included in the present composition, with respect to 100 parts by mass of the polymer (A), is preferably 0.1 parts by mass or more, more preferably 0.5 parts by mass or more, still more preferably 1 part by mass or more. Also, the relative amount of the polymer (E) included in the present composition, with respect to 100 parts by mass of the polymer (A), is preferably 10 parts by mass or less, more preferably 7 parts by mass or less, still more preferably 5 parts by mass or less.

### (Additional and Optional Component>

The present composition may further contain a component which differs from the aforementioned polymer (A), the radiation-sensitive acid-generating agent, the acid diffusion control agent, the solvent, and the polymer (E) (hereinafter may also be referred to as an “additional and optional component”). Examples of the additional and optional component include a polymer differing from the polymer (A) and the polymer (E) (e.g., a polymer including the first structural unit and the second structural unit and having a fluorine atom content (by mass) lower than that of the polymer (E)), a surfactant, a compound having an alicyclic skeleton (e.g., 1-adamantanecarboxylic acid, 2-adamantanone, or t-butyl deoxycholate), a sensitizer, and a localization accelerator. The relative amount of the additional and optional component in the present composition may be appropriately modified with respect to the component, so long as the effects of the present disclosure are not impaired.

### <Method of Producing Radiation-Sensitive Composition>

The present composition may be produced through, for example, the following procedure: mixing the polymer (A) with optional components such as a solvent at desired proportions and filtering the resultant mixture preferably by means of a filter (e.g., a filter having a pore size of about 0.2 μm) or the like. The solid content of the present composition is preferably 0.1 mass % or more, more preferably 0.5 mass % or more, still more preferably 1 mass % or more. Also, the solid content of the present composition is preferably 50 mass % or less, more preferably 20 mass % or less, still more preferably 5 mass % or less. Adjusting the solid content of the present composition to satisfy the above conditions is preferred, since coatability of the composition can be enhanced, to thereby obtain a resist pattern having a suitable shape.

The thus-obtained present composition may also be used as a composition for forming a positive pattern, which is employed for pattern formation by use of an alkaline developer. Alternatively, the present composition may be used as a composition for forming a negative pattern by use of a developer containing organic solvent. From the viewpoint of achieving a higher effect of providing excellent pattern rectangularity in development of a light-exposed resist film, while high sensitivity is maintained, the present composition is particularly preferably as a composition for forming a negative pattern by use of an organic solvent-based developer, among the aforementioned types.

### <<Resist Pattern Formation Method>>

The resist pattern formation method of the present disclosure includes a step of applying the present composition on one surface of a substrate (hereinafter may also be referred to as a “application step”), a step of exposing to light a resist film obtained in the application step (hereinafter may also be referred to as a “light-exposure step”), and a step of developing the resist film exposed to light in the light-exposure step (hereinafter may also be referred to as a “development step”). Examples of the pattern obtained through the resist pattern formation method of the present disclosure include a line-and-space pattern and a hole pattern. Since a resist film is formed by use of the present composition in the resist pattern formation method of the present disclosure, a resist pattern which exhibits excellent sensitivity, resolution, and lithographic characteristics can be formed. The steps will next be described in detail.

### [Application Step]

In the application step, the present composition is applied onto one surface of a substrate, to thereby form a resist film on the substrate. A conventionally known substrate can be used as a substrate on which resist film is to be formed. Examples of the substrate include a silicon wafer and a wafer coated with silicon dioxide or aluminum. Alternatively, an organic or inorganic anti-reflection film disclosed in, for example, Japanese Patent Publication (kokoku) No. 1994-12452 and Japanese Patent Application Laid-Open (kokai) No. 1984-93448 may be formed on a substrate to be used. Examples of the method of applying the present composition include spin coating, flow casting, and roller coating. After application, the applied composition may be subjected to pre-baking (PB) so as to evaporate the solvent remaining in the coating film. The temperature of PB is preferably 60° C. or higher, more preferably 80° C. or higher, and preferably 140° C. or lower, more preferably 120° C. or lower. The time of PB is preferably 5 seconds or longer, more preferably 10 seconds or longer, and preferably 600 seconds or shorter, more preferably 300 seconds or shorter. The average thickness of the formed resist film is preferably 10 to 1,000 nm, more preferably 20 to 500 nm.

Particularly, since a resist film exhibiting high transparency while maintaining high sensitivity can be formed from the present composition, a radiation can penetrate the resist film to a sufficient depth in pattern formation by exposing the resist film to light. The present composition having such characteristics exhibits excellent lithographic characteristics (e.g., LWR performance and CDU performance), also when the composition is employed as a composition for forming a thick-film resist. Thus, the present composition is particularly suited for forming a thick-film resist. In the case where a thick-film resist is provided, the average thickness of the resist film is preferably 50 nm or more, more preferably 70 nm or more, and, for example, 1,000 nm or less, preferably 500 nm or less.

When liquid immersion light exposure is conducted in the subsequent light-exposure step, a liquid immersion protective film which is insoluble in an immersion liquid may further be provided on the resist film formed from the present composition in order to prevent direct contact between the immersion liquid and the resist film, regardless of addition of a water-repellent polymer additive such as the polymer (E) to the present composition. As the liquid immersion protective film, there may be employed any of a solvent-removable protective film which is removed by solvent before conducting the development step (see, for example, Japanese Paten Application Laid-Open (kokai) No. 2006-227632), and a developer-removable protective film which is removed simultaneously with the development step (see, for example, WO 2005/069076 and WO 2006/035790). From the viewpoint of through-put, a developer-removable immersion liquid protective film is preferably employed.

### [Light-Exposure Step]

In the light-exposure step, the resist film formed through the above application step is exposed to light. In the light exposure, the resist film is irradiated with radiation by the mediation of a photomask or, in some cases, a liquid immersion medium such as water. The radiation is selected in accordance with the line width of a target pattern, and examples thereof include electromagnetic waves such as visible light, a UV ray, a far-UV ray, an extreme UV (EUV) ray, an X-ray, and a γ-ray; and charged particle rays such as an electron beam and an α-ray. Among them, the radiation applied to the resist film formed from the present composition is preferably a far-UV ray, an EUV ray, or an electron beam, more preferably ArF excimer laser light (wavelength: 193 nm), KrF excimer laser light (wavelength: 248 nm), an EUV ray, or an electron beam, still more preferably ArF excimer laser light, an EUV ray, or an electron beam.

After completion of the above light exposure, post exposure baking (PEB) is preferably performed, whereby release of the acid-releasable group, caused by the acid generated by a radiation-sensitive acid-generating agent through exposure to light in the light-exposed part of the resist film, is accelerated. Through PEB, the difference in dissolution performance with respect to a developer between the light-exposed part and the light-unexposed part can be increased. The temperature at PEB is preferably 50° C. or higher, more preferably 80° C. or higher, and preferably 180° C. or lower, more preferably 130° C. or lower. The time of PEB is preferably 5 seconds or longer, more preferably 10 seconds or longer, and preferably 600 seconds or shorter, more preferably 300 seconds or shorter.

### [Development Step]

In the development step, the resist film which has been exposed to light in the above step is developed by a developer, whereby a resist pattern of interest can be formed. The developer may be an alkaline developer or an organic solvent developer. The developer may be appropriately chosen in accordance with a pattern of interest (i.e., a positive pattern or a negative pattern).

Examples of the developer employed in the alkali development include aqueous alkaline solutions in which at least one species from among alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo[5.4.0]-7-undecene, 1,5-diazabicyclo[4.3.0]-5-nonene, and the like is dissolved. Among such alkaline solutions, an aqueous TMAH solution is preferred, with a 2.38 mass % aqueous TMAH solution being more preferred.

Examples of the developer employed in development with an organic solvent include organic solvents such as hydrocarbons, ethers, esters, ketones, and alcohols, and a solvent containing any of the organic solvents. Examples of the organic solvent include one or more members of the solvents exemplified as the solvents which may be incorporated into the present composition. Among them, an ether, an ester, and a ketone are preferred. The ether is preferably a glycol ether, more preferably ethylene glycol monomethyl ether or propylene glycol monomethyl ether. The ester is preferably an acetate ester, more preferably n-butyl acetate or amyl acetate. The ketone is preferably a chain ketone, more preferably 2-heptanone. The organic solvent content of the developer is preferably 80 mass % or higher, more preferably 90 mass % or higher, still more preferably 95 mass % or higher, particularly preferably 99 mass % or higher. Examples of developer components other than the organic solvent include water and silicone oil.

Examples of the development method include a dipping method (i.e., dipping a substrate in a bath filled with a developer for a specific time); a paddle method (i.e., putting a developer on a substrate to form a drop by surface tension and allowing the substrate to stand for a specific time); a spray method (i.e., spraying a developer onto a substrate); and a dynamic dispense method (i.e., continuously jetting a developer at a specific speed to a substrate rotating at a specific speed through a developer jetting nozzle with scanning). After completion of development, washing with a rinse liquid (e.g., water or alcohol) and drying are generally conducted.

Notably, when a resist film is formed by use of a radiation-sensitive composition containing the polymer (A), the following phenomenon is conceivably evoked. That is, when the resist film is irradiated in the light-exposure step, degradation occurs in the light-exposed part of a main chain of the polymer (A) (more specifically, at a cleavage site included in B¹), to thereby reduce the molecular weight of the polymer (A). Thus, solubility of the polymer (A) in the developer increases. As a result, incomplete dissolution of the polymer (A) in the light-exposed part of the resist film in the subsequent development step can be suppressed, whereby a radiation-sensitive composition exhibiting excellent resolution while high sensitivity is maintained can be yielded. Notably, the above mechanism is merely an assumption, which should not be construed as limiting the present disclosure.

As described hereinabove, the present composition containing the polymer (A) exhibits high sensitivity and high resolution in formation of a resist pattern and provides excellent LWR performance. Thus, the present composition can be suitably used in a semiconductor device process in which further process shrinkage will proceed, and the like.

### EXAMPLES

The present disclosure will next be described in detail by way of examples, which should not be construed as limiting the invention thereto.

### 1. Synthesis of RAFT Agent

### [Example 1] Synthesis of RAFT Agent (R-1)

The RAFT agent (R-1) was synthesized through the following scheme.

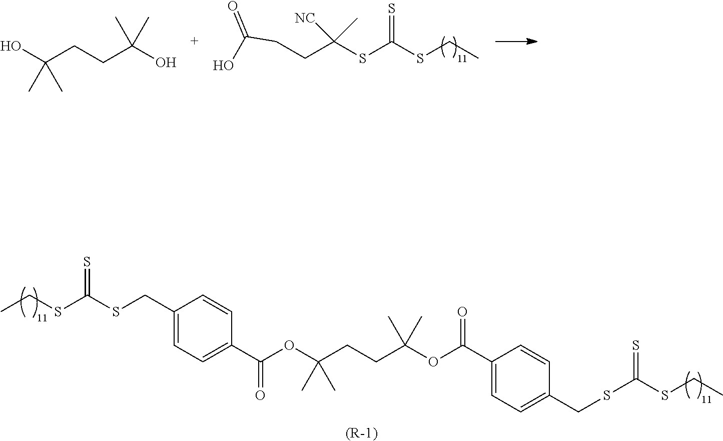

To a reaction vessel, 2,4-dimethyl-2,4-pantanediol (10 mmol), 4-cyano-4-[(dodecylsulfanylthiocarbonyl)sulfanyl]pentanoic acid (20 mmol), and dehydrated dichloromethane (40 mL) were added, and the contents were cooled to 0° C. 4-Dimethylaminopyridine (6 mmol) was added thereto under sufficient stirring. Thereafter, 1-ethyl-3-(-3-dimethylaminopropyl)carbodiimide hydrochloride salt (30 mmol) was gradually added under stirring at room temperature for 10 hours. Subsequently, the reaction was quenched by 1M aqueous HCl (45 mL), extracted twice with dichloromethane (20 mL), and washed twice with saturated aqueous sodium hydrogen carbonate (20 mL) and once with saturated aqueous sodium chloride (20 mL). The obtained organic layer was dried over sodium sulfate, and then filtered and concentrated, followed by purification through silica gel chromatography, to thereby yield a RAFT agent (R-1).

### [Examples 2 to 15] Synthesis of RAFT Agents (R-2) to (R-15)

The technique of Example 1 was repeatedly employed, with a suitable substrate being chosen, to thereby yield RAFT agents (R-2) to (R-15).

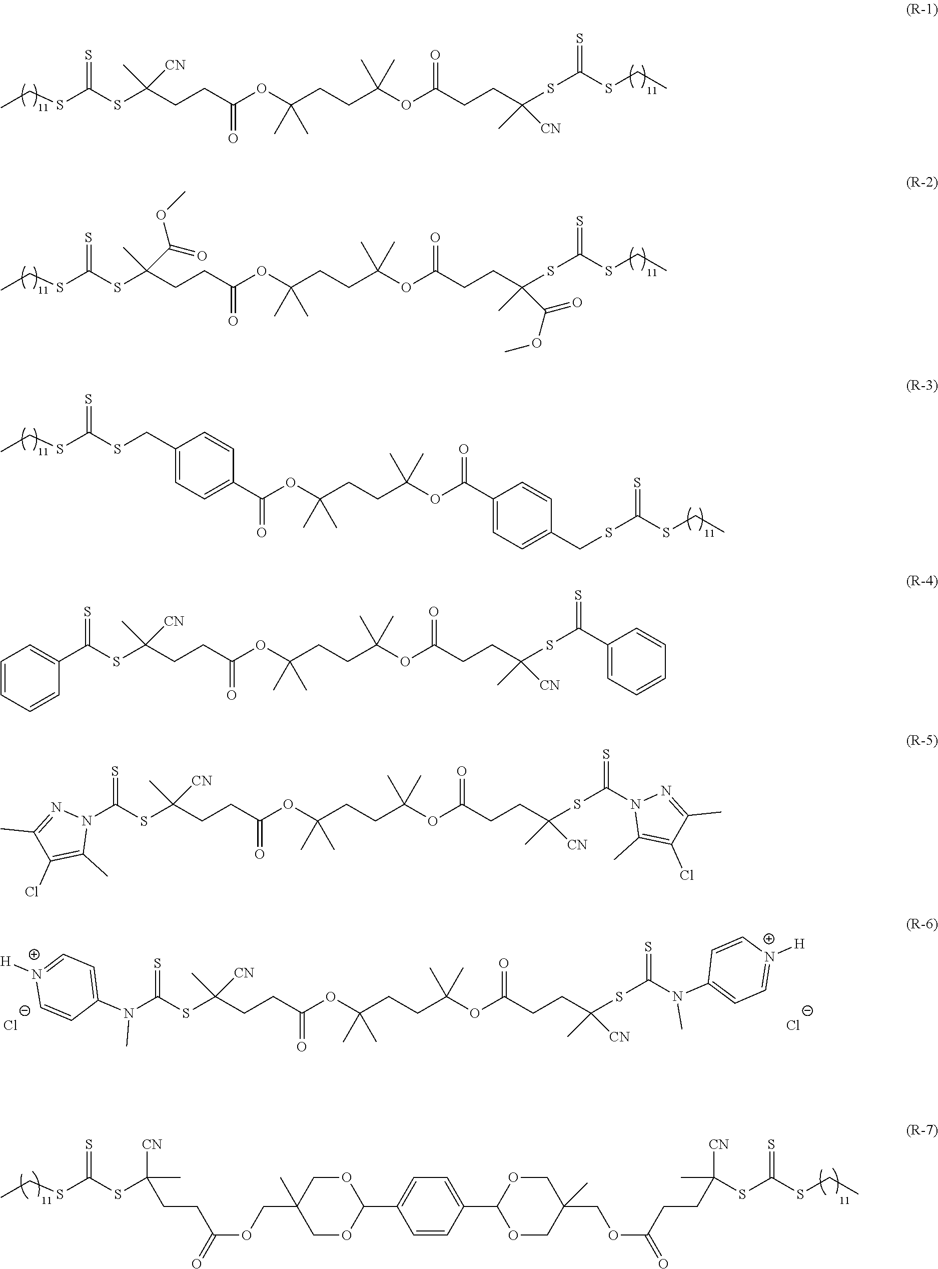

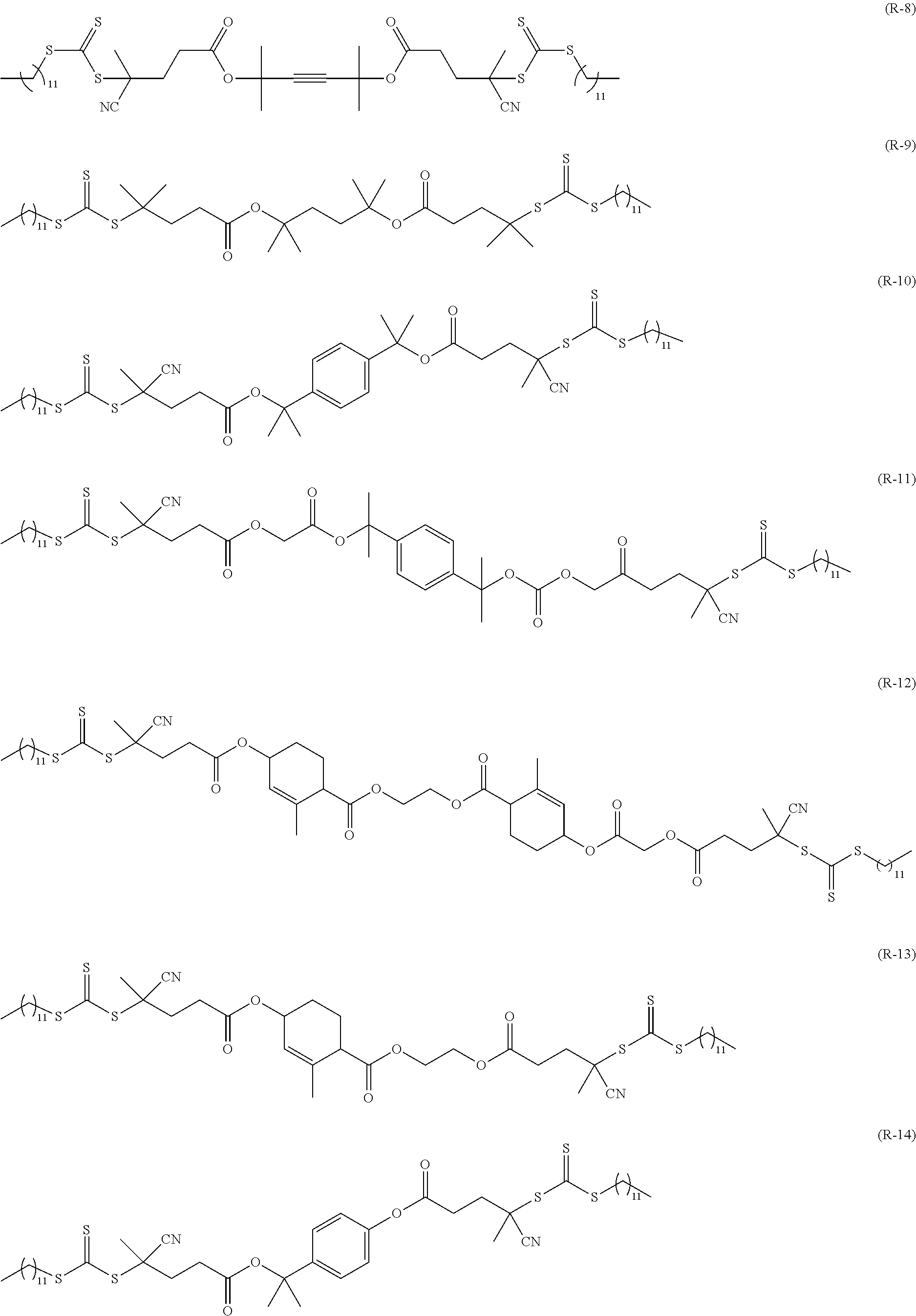

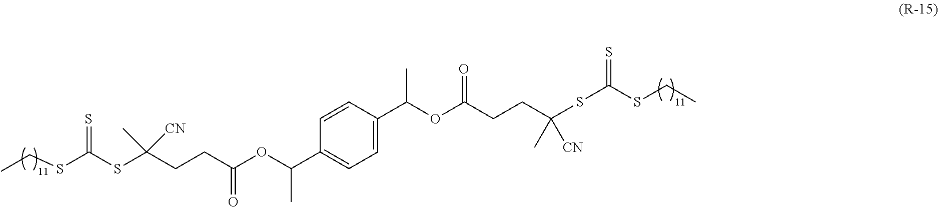

### 2. Synthesis of Base Resin

### [Synthesis Examples 1 to 50] Synthesis of Base Resins (A-1) to (A-50)

Monomers were appropriately used in combination at compositional proportions shown in the following Tables 1 and 2, and copolymerization was performed in a tetrahydrofuran (THF) solvent in the presence of any of the RAFT agents shown in Tables 1 and 2. The amount of the RAFT agent used was adjusted to 3 mol % with respect to the total amount of the monomers (as 100 mol %). After completion of polymerization, an end treatment was performed by use of 2,2′-azobis(isobutyronitrile) and 1-dodecylmercaptan. Thereafter, the formed polymer was crystallized in methanol and then repeatedly washed with hexane, followed by isolation and drying, to thereby yield polymers (A-1) to (A-50) as base resins. Notably, in Tables 1 and 2, the amount of each monomer used corresponds to that with respect to the total amount of the monomers used in polymerization.

### [Synthesis Examples 51 to 86] Synthesis of Base Resins (cA-1) to (cA-36)

The technique of Synthesis Examples 1 to 50 was repeatedly employed, except that no RAFT agent was added, and no end treatment was conducted. Monomers were combined at compositional proportions shown in the following Tables 3 and 4, and polymerization was performed, to thereby yield polymers (cA-1) to (cA-36) as base resins.

The weight average molecular weight (Mw) and the molecular weight distribution (Mw/Mn) of each base resin were determined, and the results are shown in Tables 1 to 4. The Mw/Mn of a resin was determined through gel permeation chromatography (GPC) with GPC columns (G2000HXL×2, G3000HXL×1, and G4000HXL×1) (products of Tosoh Corp.) under the following conditions.
Eluent: tetrahydrofuran (product of Wako Pure Chemical Corporation)
Flow rate: 1.0 mL/min
Sample concentration: 1.0 mass %
Sample injection: 100 μL
Column temperature: 40° C.
Detector: differential refractometer
Standard: monodispersed polystyrene

TABLE 1

| | | Monomer forming first | | | | Monomer forming second | | | | Monomer forming third | | | | | | |
|---|---|---|---|---|---|---|---|---|---|---|---|---|---|---|---|---|
| | | structural unit | | | | structural unit | | | | structural unit | | | | | | |
| Synthesis | | | Amount | | Amount | | Amount | | Amount | | Amount | | Amount | | | |
| Example | | | used | | used | | used | | used | | used | | used | RAFT | | Mw/ |
| No. | Polymer | Type | (mol %) | Type | (mol %) | Type | (mol %) | Type | (mol %) | Type | (mol %) | Type | (mol %) | agent | Mw | Mn |
| 1 | A-1 | M-4 | 50 | — | — | M-1 | 50 | — | — | — | — | — | — | R-1 | 6500 | 1.2 |
| 2 | A-2 | M-5 | 50 | — | — | M-1 | 50 | — | — | — | — | — | — | R-1 | 6600 | 1.2 |
| 3 | A-3 | M-6 | 50 | — | — | M-1 | 50 | — | — | — | — | — | — | R-1 | 6300 | 1.2 |
| 4 | A-4 | M-7 | 50 | — | — | M-1 | 50 | — | — | — | — | — | — | R-1 | 6400 | 1.2 |
| 5 | A-5 | M-8 | 50 | — | — | M-1 | 50 | — | — | — | — | — | — | R-1 | 6400 | 1.3 |
| 6 | A-6 | M-9 | 50 | — | — | M-1 | 50 | — | — | — | — | — | — | R-1 | 6500 | 1.2 |
| 7 | A-7 | M-10 | 50 | — | — | M-1 | 50 | — | — | — | — | — | — | R-1 | 6500 | 1.3 |
| 8 | A-8 | M-11 | 50 | — | — | M-1 | 50 | — | — | — | — | — | — | R-1 | 6600 | 1.3 |
| 9 | A-9 | M-12 | 50 | — | — | M-1 | 50 | — | — | — | — | — | — | R-1 | 6200 | 1.3 |
| 10 | A-10 | M-13 | 50 | — | — | M-1 | 50 | — | — | — | — | — | — | R-1 | 6300 | 1.3 |
| 11 | A-11 | M-29 | 50 | — | — | M-1 | 50 | — | — | — | — | — | — | R-1 | 6600 | 1.2 |
| 12 | A-12 | M-9 | 30 | M-12 | 20 | M-1 | 50 | — | — | — | — | — | — | R-1 | 6500 | 1.2 |
| 13 | A-13 | M-10 | 30 | M-13 | 20 | M-1 | 50 | — | — | — | — | — | — | R-1 | 6500 | 1.3 |
| 14 | A-14 | M-11 | 30 | M-12 | 20 | M-1 | 50 | — | — | — | — | — | — | R-1 | 6800 | 1.3 |
| 15 | A-15 | M-4 | 50 | — | — | M-2 | 50 | — | — | — | — | — | — | R-1 | 6500 | 1.3 |
| 16 | A-16 | M-8 | 50 | — | — | M-2 | 50 | — | — | — | — | — | — | R-1 | 6300 | 1.2 |
| 17 | A-17 | M-9 | 50 | — | — | M-2 | 50 | — | — | — | — | — | — | R-1 | 6700 | 1.2 |
| 18 | A-18 | M-4 | 50 | — | — | M-3 | 50 | — | — | — | — | — | — | R-1 | 6400 | 1.3 |
| 19 | A-19 | M-4 | 50 | — | — | M-1 | 25 | M-2 | 25 | — | — | — | — | R-1 | 6500 | 1.2 |
| 20 | A-20 | M-9 | 50 | — | — | M-1 | 25 | M-2 | 25 | — | — | — | — | R-1 | 6400 | 1.3 |
| 21 | A-21 | M-4 | 50 | — | — | M-1 | 30 | — | — | M-15 | 20 | — | — | R-1 | 12200 | 1.2 |
| 22 | A-22 | M-4 | 50 | — | — | M-1 | 30 | — | — | M-16 | 20 | — | — | R-1 | 12100 | 1.2 |
| 23 | A-23 | M-9 | 50 | — | — | M-1 | 30 | — | — | M-15 | 20 | — | — | R-1 | 12100 | 1.2 |
| 24 | A-24 | M-4 | 50 | — | — | M-1 | 15 | M-2 | 15 | M-15 | 20 | — | — | R-1 | 12000 | 1.3 |
| 25 | A-25 | M-4 | 50 | — | — | M-1 | 15 | M-2 | 15 | M-15 | 20 | — | — | R-1 | 12200 | 1.2 |

TABLE 2

| | | Monomer forming first | | | | Monomer forming second | | | | Monomer forming third | | | | | | |
|---|---|---|---|---|---|---|---|---|---|---|---|---|---|---|---|---|
| | | structural unit | | | | structural unit | | | | structural unit | | | | | | |
| Synthesis | | | Amount | | Amount | | Amount | | Amount | | Amount | | Amount | | | |
| Example | | | used | | used | | used | | used | | used | | used | RAFT | | Mw/ |
| No. | Polymer | Type | (mol %) | Type | (mol %) | Type | (mol %) | Type | (mol %) | Type | (mol %) | Type | (mol %) | agent | Mw | Mn |
| 26 | A-26 | M-4 | 25 | M-9 | 25 | M-1 | 30 | — | — | M-15 | 20 | — | — | R-1 | 12000 | 1.3 |
| 27 | A-27 | M-4 | 25 | M-13 | 25 | M-1 | 30 | — | — | M-15 | 20 | — | — | R-1 | 12100 | 1.2 |
| 28 | A-28 | M-4 | 50 | — | — | M-1 | 45 | — | — | — | — | M-17 | 5 | R-1 | 7300 | 1.2 |
| 29 | A-29 | M-4 | 50 | — | — | M-1 | 45 | — | — | — | — | M-18 | 5 | R-1 | 7200 | 1.3 |
| 30 | A-30 | M-4 | 50 | — | — | M-1 | 45 | — | — | — | — | M-19 | 5 | R-1 | 7300 | 1.2 |
| 31 | A-31 | M-4 | 25 | M-9 | 25 | M-1 | 45 | — | — | — | — | M-17 | 5 | R-1 | 7100 | 1.3 |
| 32 | A-32 | M-4 | 25 | M-13 | 25 | M-1 | 45 | — | — | — | — | M-17 | 5 | R-1 | 7200 | 1.3 |
| 33 | A-33 | M-4 | 50 | — | — | M-2 | 25 | — | — | M-15 | 20 | M-17 | 5 | R-1 | 13300 | 1.3 |
| 34 | A-34 | M-4 | 50 | — | — | M-3 | 25 | — | — | M-16 | 20 | M-17 | 5 | R-1 | 13500 | 1.3 |
| 35 | A-35 | M-4 | 25 | M-9 | 25 | M-3 | 25 | — | — | M-16 | 20 | M-17 | 5 | R-1 | 13300 | 1.3 |
| 36 | A-36 | M-4 | 25 | M-13 | 25 | M-3 | 25 | — | — | M-16 | 20 | M-17 | 5 | R-1 | 13200 | 1.2 |
| 37 | A-37 | M-4 | 50 | — | — | M-1 | 50 | — | — | — | — | — | — | R-2 | 6500 | 1.2 |
| 38 | A-38 | M-12 | 50 | — | — | M-1 | 50 | — | — | — | — | — | — | R-3 | 6300 | 1.2 |
| 39 | A-39 | M-4 | 50 | — | — | M-1 | 50 | — | — | — | — | — | — | R-4 | 6500 | 1.2 |
| 40 | A-40 | M-4 | 50 | — | — | M-1 | 50 | — | — | — | — | — | — | R-5 | 6600 | 1.2 |
| 41 | A-41 | M-4 | 50 | — | — | M-1 | 50 | — | — | — | — | — | — | R-6 | 6600 | 1.3 |
| 42 | A-42 | M-4 | 50 | — | — | M-1 | 50 | — | — | — | — | — | — | R-7 | 6500 | 1.2 |
| 43 | A-43 | M-4 | 50 | — | — | M-1 | 50 | — | — | — | — | — | — | R-8 | 6300 | 1.3 |
| 44 | A-44 | M-4 | 50 | — | — | M-1 | 50 | — | — | — | — | — | — | R-9 | 6500 | 1.3 |
| 45 | A-45 | M-4 | 50 | — | — | M-1 | 50 | — | — | — | — | — | — | R-10 | 6300 | 1.2 |
| 46 | A-46 | M-4 | 50 | — | — | M-1 | 50 | — | — | — | — | — | — | R-11 | 6600 | 1.2 |
| 47 | A-47 | M-4 | 50 | — | — | M-1 | 50 | — | — | — | — | — | — | R-12 | 6600 | 1.3 |
| 48 | A-48 | M-4 | 50 | — | — | M-1 | 50 | — | — | — | — | — | — | R-13 | 6500 | 1.3 |
| 49 | A-49 | M-4 | 50 | — | — | M-1 | 50 | — | — | — | — | — | — | R-14 | 6200 | 1.3 |
| 50 | A-50 | M-4 | 50 | — | — | M-1 | 50 | — | — | — | — | — | — | R-15 | 6500 | 1.3 |

TABLE 3

| | | Monomer forming first | | | | Monomer forming second | | | | Monomer forming third | | | | | |
|---|---|---|---|---|---|---|---|---|---|---|---|---|---|---|---|
| | | structural unit | | | | structural unit | | | | structural unit | | | | | |
| Synthesis | | | Amount | | Amount | | Amount | | Amount | | Amount | | Amount | | |
| Example | | | used | | used | | used | | used | | used | | used | | Mw/ |
| No. | Polymer | Type | (mol %) | Type | (mol %) | Type | (mol %) | Type | (mol %) | Type | (mol %) | Type | (mol %) | Mw | Mn |
| 51 | cA-1 | M-4 | 50 | — | — | M-1 | 50 | — | — | — | — | — | — | 6500 | 1.5 |
| 52 | cA-2 | M-5 | 50 | — | — | M-1 | 50 | — | — | — | — | — | — | 6800 | 1.4 |
| 53 | cA-3 | M-6 | 50 | — | — | M-1 | 50 | — | — | — | — | — | — | 6600 | 1.5 |
| 54 | cA-4 | M-7 | 50 | — | — | M-1 | 50 | — | — | — | — | — | — | 6300 | 1.5 |
| 55 | cA-5 | M-8 | 50 | — | — | M-1 | 50 | — | — | — | — | — | — | 6300 | 1.5 |
| 56 | cA-6 | M-9 | 50 | — | — | M-1 | 50 | — | — | — | — | — | — | 6200 | 1.5 |
| 57 | cA-7 | M-10 | 50 | — | — | M-1 | 50 | — | — | — | — | — | — | 6400 | 1.4 |
| 58 | cA-8 | M-11 | 50 | — | — | M-1 | 50 | — | — | — | — | — | — | 6800 | 1.5 |
| 59 | cA-9 | M-12 | 50 | — | — | M-1 | 50 | — | — | — | — | — | — | 6200 | 1.5 |
| 60 | cA-10 | M-13 | 50 | — | — | M-1 | 50 | — | — | — | — | — | — | 6600 | 1.5 |
| 61 | cA-11 | M-29 | 50 | — | — | M-1 | 50 | — | — | — | — | — | — | 6800 | 1.5 |
| 62 | cA-12 | M-9 | 30 | M-12 | 20 | M-1 | 50 | — | — | — | — | — | — | 6500 | 1.5 |
| 63 | cA-13 | M-10 | 30 | M-13 | 20 | M-1 | 50 | — | — | — | — | — | — | 6600 | 1.4 |
| 64 | cA-14 | M-11 | 30 | M-12 | 20 | M-1 | 50 | — | — | — | — | — | — | 6500 | 1.5 |
| 65 | cA-15 | M-4 | 50 | — | — | M-2 | 50 | — | — | — | — | — | — | 6300 | 1.5 |
| 66 | cA-16 | M-8 | 50 | — | — | M-2 | 50 | — | — | — | — | — | — | 6800 | 1.4 |
| 67 | cA-17 | M-9 | 50 | — | — | M-2 | 50 | — | — | — | — | — | — | 6600 | 1.4 |
| 68 | cA-18 | M-4 | 50 | — | — | M-3 | 50 | — | — | — | — | — | — | 6700 | 1.5 |
| 69 | cA-19 | M-4 | 50 | — | — | M-1 | 25 | M-2 | 25 | — | — | — | — | 6700 | 1.5 |
| 70 | cA-20 | M-9 | 50 | — | — | M-1 | 25 | M-2 | 25 | — | — | — | — | 6500 | 1.5 |
| 71 | cA-21 | M-4 | 50 | — | — | M-1 | 30 | — | — | M-15 | 20 | — | — | 12300 | 1.5 |
| 72 | cA-22 | M-4 | 50 | — | — | M-1 | 30 | — | — | M-16 | 20 | — | — | 12100 | 1.4 |
| 73 | cA-23 | M-9 | 50 | — | — | M-1 | 30 | — | — | M-15 | 20 | — | — | 12500 | 1.5 |
| 74 | cA-24 | M-4 | 50 | — | — | M-1 | 15 | M-2 | 15 | M-15 | 20 | — | — | 12100 | 1.5 |
| 75 | cA-25 | M-4 | 50 | — | — | M-1 | 15 | M-2 | 15 | M-15 | 20 | — | — | 12300 | 1.4 |

TABLE 4

| | | Monomer forming first | | | | Monomer forming second | | | | Monomer forming third | | | | | |
|---|---|---|---|---|---|---|---|---|---|---|---|---|---|---|---|
| | | structural unit | | | | structural unit | | | | structural unit | | | | | |
| Synthesis | | | Amount | | Amount | | Amount | | Amount | | Amount | | Amount | | |
| Example | | | used | | used | | used | | used | | used | | used | | Mw/ |
| No. | Polymer | Type | (mol %) | Type | (mol %) | Type | (mol %) | Type | (mol %) | Type | (mol %) | Type | (mol %) | Mw | Mn |
| 76 | cA-26 | M-4 | 25 | M-9 | 25 | M-1 | 30 | — | — | M-15 | 20 | — | — | 12200 | 1.5 |
| 77 | cA-27 | M-4 | 25 | M-13 | 25 | M-1 | 30 | — | — | M-15 | 20 | — | — | 12100 | 1.5 |
| 78 | cA-28 | M-4 | 50 | — | — | M-1 | 45 | — | — | — | — | M-17 | 5 | 7500 | 1.5 |
| 79 | cA-29 | M-4 | 50 | — | — | M-1 | 45 | — | — | — | — | M-18 | 5 | 7100 | 1.5 |
| 80 | cA-30 | M-4 | 50 | — | — | M-1 | 45 | — | — | — | — | M-19 | 5 | 7200 | 1.4 |
| 81 | cA-31 | M-4 | 25 | M-9 | 25 | M-1 | 45 | — | — | — | — | M-17 | 5 | 7100 | 1.4 |
| 82 | cA-32 | M-4 | 25 | M-13 | 25 | M-1 | 45 | — | — | — | — | M-17 | 5 | 7300 | 1.4 |
| 83 | cA-33 | M-4 | 50 | — | — | M-2 | 25 | — | — | M-15 | 20 | M-16 | 5 | 13000 | 1.5 |
| 84 | cA-34 | M-4 | 50 | — | — | M-3 | 25 | — | — | M-16 | 20 | M-17 | 5 | 13300 | 1.4 |
| 85 | cA-35 | M-4 | 25 | M-9 | 25 | M-3 | 25 | — | — | M-16 | 20 | M-17 | 5 | 13500 | 1.4 |
| 86 | cA-36 | M-4 | 25 | M-13 | 25 | M-3 | 25 | — | — | M-16 | 20 | M-17 | 5 | 13100 | 1.5 |

The monomers employed in polymerization are as follows.

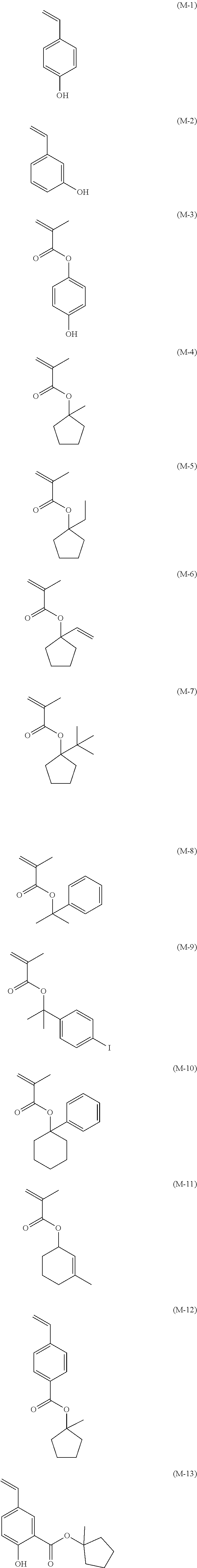

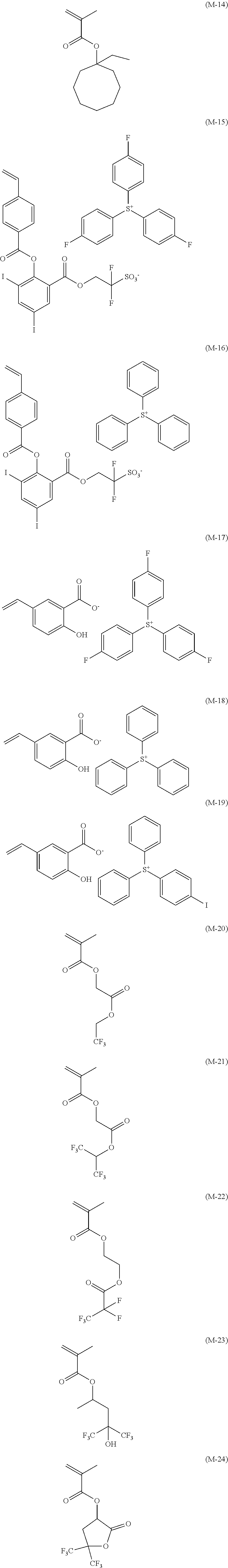

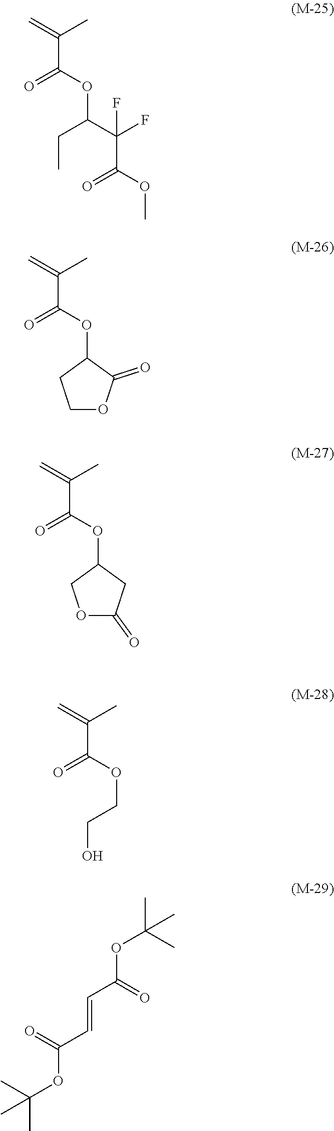

### 3. Synthesis of High-Fluorine Content Resin

### [Synthesis Examples 87 to 91] Synthesis of High-Fluorine Content Resins

Monomers were combined at compositional proportions shown in the following Table 5, and copolymerization was performed in a tetrahydrofuran (THF) solvent. After completion of polymerization, the solvent was changed to acetonitrile, and the polymer was washed with hexane. Thereafter, the solvent was changed to propylene glycol monomethyl ether acetate, to thereby yield polymers (F-1) to (F-5) as high-fluorine content resins.

TABLE 5

| | | Monomer 1 | | Monomer 2 | | Monomer 3 | | | |
|---|---|---|---|---|---|---|---|---|---|
| Synthesis | | | Amount | | Amount | | Amount | | |
| Example | | | used | | used | | used | | Mw/ |
| No. | Polymer | Type | (mol %) | Type | (mol %) | Type | (mol %) | Mw | Mn |
| 87 | F-1 | M-14 | 30 | M-20 | 50 | — | — | 20000 | 1.5 |
| 88 | F-2 | M-1 | 30 | M-21 | 50 | M-26 | 20 | 22000 | 1.5 |
| 89 | F-3 | M-1 | 30 | M-22 | 50 | M-27 | 20 | 19000 | 1.5 |
| 90 | F-4 | — | — | M-23 | 50 | M-24 | 50 | 20000 | 1.5 |
| 91 | F-5 | M-1 | 30 | M-25 | 50 | M-28 | 20 | 21000 | 1.5 |

### 4. Preparation of Radiation-Sensitive Composition

The above-synthesized base resins and high-fluorine content resins, and the radiation-sensitive acid-generating agents, the acid diffusion control agents, and the organic solvents were selected and mixed, to thereby prepare radiation-sensitive compositions. The radiation-sensitive acid-generating agents, the acid diffusion control agents, and the organic solvents employed in preparation of the radiation-sensitive compositions are as follows.

### <Radiation-Sensitive Acid-Generating Agent>

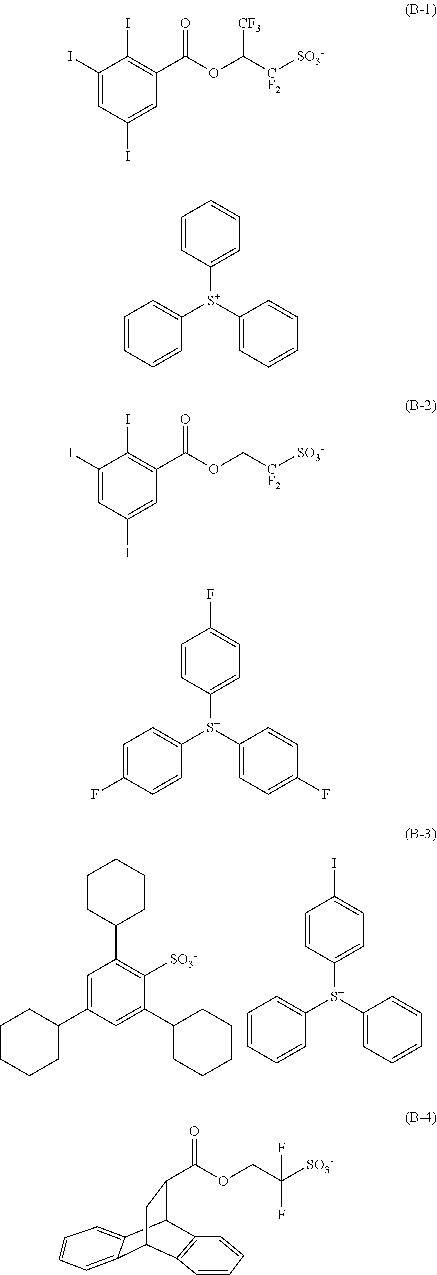

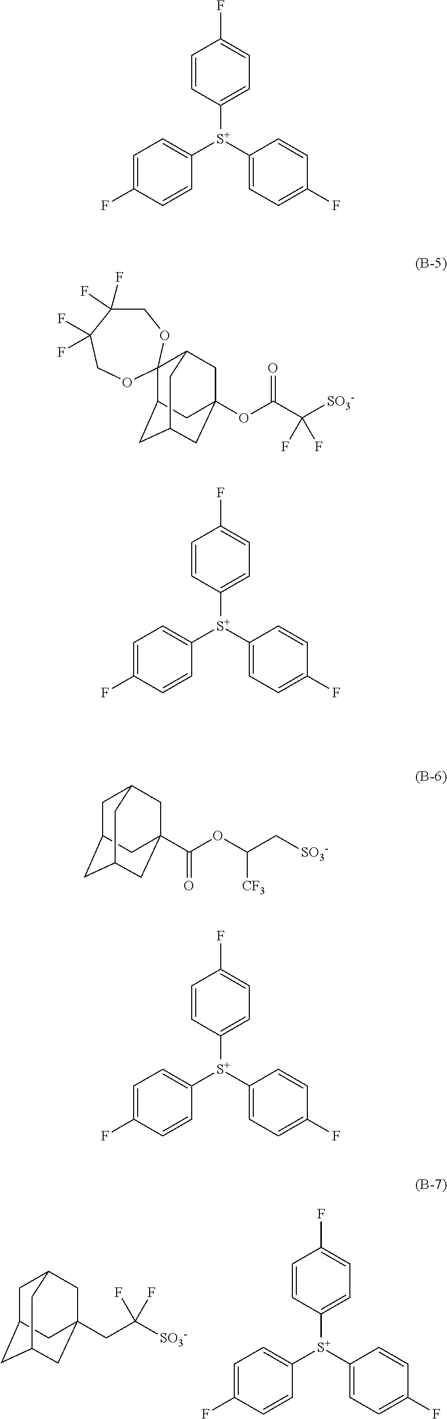

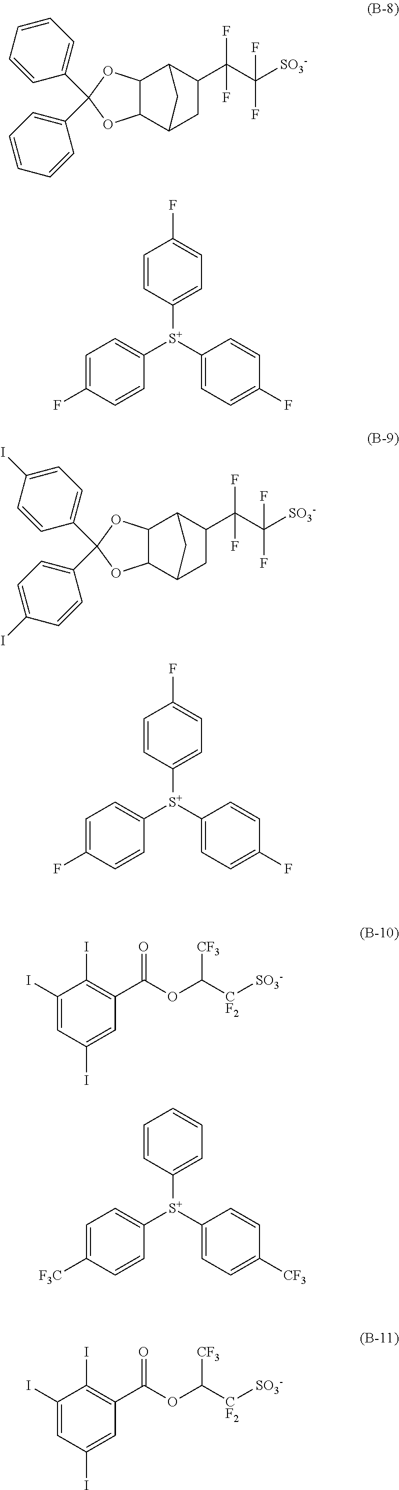

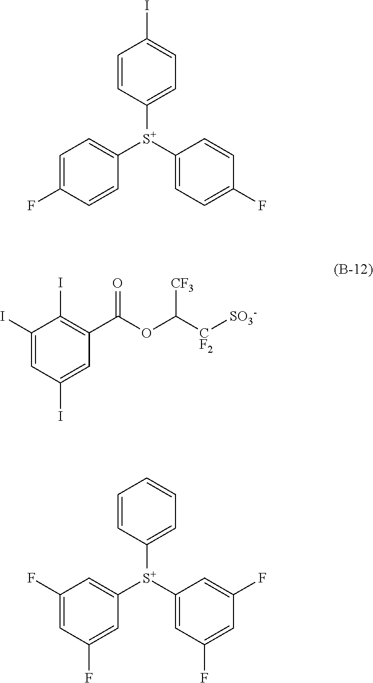

### <Acid Diffusion Control Agent>

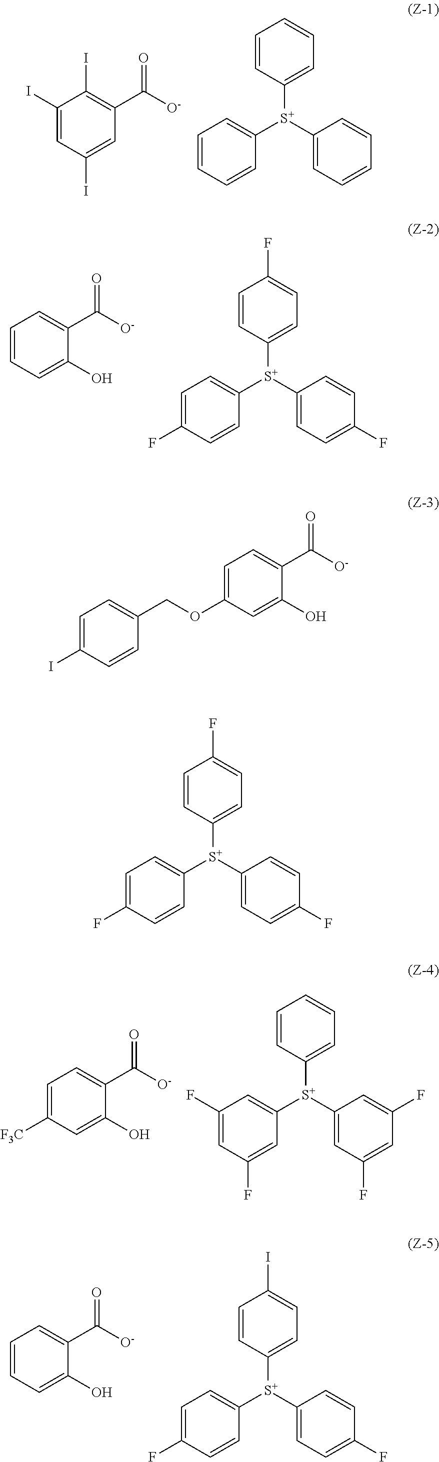

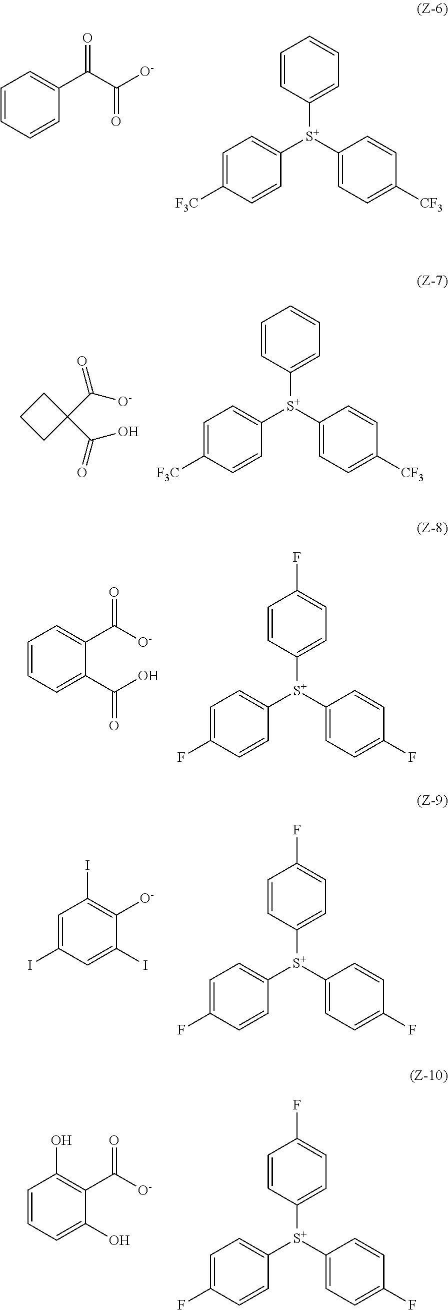

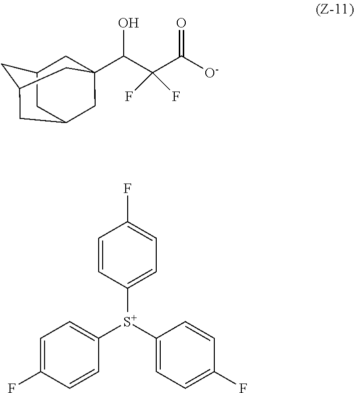 [SMILES: O=C([O-])C(F)(F)C(O)C12CC3CC(CC(C3)C1)C2 ; Fc1ccc([S+](c2ccc(F)cc2)c2ccc(F)cc2)cc1]

### <Organic Solvent>

D-1: propylene glycol monomethyl ether acetate
D-2: propylene glycol 1-monomethyl ether

### Example 1

The polymer (A-1) serving as a base resin (100 parts by mass), a compound (B-1) serving as a radiation-sensitive acid-generating agent (20 parts by mass), a compound (Z-1) serving as an acid diffusion control agent (25 mol %, with respect to the total amount with the radiation-sensitive acid-generating agent (compound (B-1)), a compound (D-1) serving as the organic solvent [D](2,000 parts by mass), and a compound (D-2) serving as the organic solvent [D](4,800 parts by mass) were mixed together, to thereby prepare a radiation-sensitive composition (R-1).

### Examples 2 to 79 and Comparative Examples 1 to 65

The procedure of Example 1 was repeated, except that the type and amounts of the components shown in the Tables 6 to 11 below were employed, to thereby prepare radiation-sensitive compositions (R-2) to (R-79), and (cR-1) to (cR-65).

TABLE 6

| | | | | Radiation- | | | | | | | |
|---|---|---|---|---|---|---|---|---|---|---|---|
| | | | | sensitive acid- | | | | | | | |
| | | | | generating | | | | High-fluorine | | | |
| | | Base resin | | agent | | Acid diffusion | | content resin | | Organic solvent | |
| | Radiation- | | Amount | | Amount | control agent | | | Amount | | Amount |
| Example | sensitive | | (part by | | (part by | | Amount | | (part by | | (part by |
| No. | composition | Type | mass) | Type | mass) | Type | (mol %) | Type | mass) | Type | mass) |
| 1 | R-1 | A-1 | 100 | B-1 | 20 | Z-1 | 25 | F-1 | 2 | D-1/ | 2000/ |
| | | | | | | | | | | D-2 | 4800 |
| 2 | R-2 | A-2 | 100 | B-1 | 20 | Z-1 | 25 | F-1 | 2 | D-1/ | 2000/ |
| | | | | | | | | | | D-2 | 4800 |
| 3 | R-3 | A-3 | 100 | B-1 | 20 | Z-1 | 25 | F-1 | 2 | D-1/ | 2000/ |
| | | | | | | | | | | D-2 | 4800 |
| 4 | R-4 | A-4 | 100 | B-1 | 20 | Z-1 | 25 | F-1 | 2 | D-1/ | 2000/ |
| | | | | | | | | | | D-2 | 4800 |
| 5 | R-5 | A-5 | 100 | B-1 | 20 | Z-1 | 25 | F-1 | 2 | D-1/ | 2000/ |
| | | | | | | | | | | D-2 | 4800 |
| 6 | R-6 | A-6 | 100 | B-1 | 20 | Z-1 | 25 | F-1 | 2 | D-1/ | 2000/ |
| | | | | | | | | | | D-2 | 4800 |
| 7 | R-7 | A-7 | 100 | B-1 | 20 | Z-1 | 25 | F-1 | 2 | D-1/ | 2000/ |
| | | | | | | | | | | D-2 | 4800 |
| 8 | R-8 | A-8 | 100 | B-1 | 20 | Z-1 | 25 | F-1 | 2 | D-1/ | 2000/ |
| | | | | | | | | | | D-2 | 4800 |
| 9 | R-9 | A-9 | 100 | B-1 | 20 | Z-1 | 25 | F-1 | 2 | D-1/ | 2000/ |
| | | | | | | | | | | D-2 | 4800 |
| 10 | R-10 | A-10 | 100 | B-1 | 20 | Z-1 | 25 | F-1 | 2 | D-1/ | 2000/ |
| | | | | | | | | | | D-2 | 4800 |
| 11 | R-11 | A-11 | 100 | B-1 | 20 | Z-1 | 25 | F-2 | 2 | D-1/ | 2000/ |
| | | | | | | | | | | D-2 | 4800 |
| 12 | R-12 | A-12 | 100 | B-1 | 20 | Z-1 | 25 | F-1 | 2 | D-1/ | 2000/ |
| | | | | | | | | | | D-2 | 4800 |
| 13 | R-13 | A-13 | 100 | B-1 | 20 | Z-1 | 25 | F-3 | 2 | D-1/ | 2000/ |
| | | | | | | | | | | D-2 | 4800 |
| 14 | R-14 | A-14 | 100 | B-1 | 20 | Z-1 | 25 | F-1 | 2 | D-1/ | 2000/ |
| | | | | | | | | | | D-2 | 4800 |
| 15 | R-15 | A-15 | 100 | B-1 | 20 | Z-1 | 25 | F-1 | 2 | D-1/ | 2000/ |
| | | | | | | | | | | D-2 | 4800 |
| 16 | R-16 | A-16 | 100 | B-1 | 20 | Z-1 | 25 | F-1 | 2 | D-1/ | 2000/ |
| | | | | | | | | | | D-2 | 4800 |
| 17 | R-17 | A-17 | 100 | B-1 | 20 | Z-1 | 25 | F-1 | 2 | D-1/ | 2000/ |
| | | | | | | | | | | D-2 | 4800 |
| 18 | R-18 | A-18 | 100 | B-1 | 20 | Z-1 | 25 | F-1 | 2 | D-1/ | 2000/ |
| | | | | | | | | | | D-2 | 4800 |
| 19 | R-19 | A-19 | 100 | B-1 | 20 | Z-1 | 25 | F-1 | 2 | D-1/ | 2000/ |
| | | | | | | | | | | D-2 | 4800 |
| 20 | R-20 | A-20 | 100 | B-1 | 20 | Z-1 | 25 | F-1 | 2 | D-1/ | 2000/ |
| | | | | | | | | | | D-2 | 4800 |
| 21 | R-21 | A-21 | 100 | — | — | Z-1 | 25 | F-1 | 2 | D-1/ | 2000/ |
| | | | | | | | | | | D-2 | 4800 |
| 22 | R-22 | A-22 | 100 | — | — | Z-1 | 25 | F-2 | 2 | D-1/ | 2000/ |
| | | | | | | | | | | D-2 | 4800 |
| 23 | R-23 | A-23 | 100 | — | — | Z-1 | 25 | F-1 | 2 | D-1/ | 2000/ |
| | | | | | | | | | | D-2 | 4800 |
| 24 | R-24 | A-24 | 100 | — | — | Z-1 | 25 | F-1 | 2 | D-1/ | 2000/ |
| | | | | | | | | | | D-2 | 4800 |
| 25 | R-25 | A-25 | 100 | — | — | Z-1 | 25 | F-1 | 2 | D-1/ | 2000/ |
| | | | | | | | | | | D-2 | 4800 |
| 26 | R-26 | A-26 | 100 | — | — | Z-1 | 25 | F-1 | 2 | D-1/ | 2000/ |
| | | | | | | | | | | D-2 | 4800 |
| 27 | R-27 | A-27 | 100 | — | — | Z-1 | 25 | F-1 | 2 | D-1/ | 2000/ |
| | | | | | | | | | | D-2 | 4800 |
| 28 | R-28 | A-28 | 100 | B-1 | 20 | — | — | F-1 | 2 | D-1/ | 2000/ |
| | | | | | | | | | | D-2 | 4800 |
| 29 | R-29 | A-29 | 100 | B-1 | 20 | — | — | F-1 | 2 | D-1/ | 2000/ |
| | | | | | | | | | | D-2 | 4800 |
| 30 | R-30 | A-30 | 100 | B-1 | 20 | — | — | F-1 | 2 | D-1/ | 2000/ |
| | | | | | | | | | | D-2 | 4800 |

TABLE 7

| | | | | Radiation- | | | | | | | |
|---|---|---|---|---|---|---|---|---|---|---|---|
| | | | | sensitive acid- | | | | | | | |
| | | | | generating | | | | High-fluorine | | | |
| | | Base resin | | agent | | Acid diffusion | | content resin | | Organic solvent | |
| | Radiation- | | Amount | | Amount | control agent | | | Amount | | Amount |
| Example | sensitive | | (part by | | (part by | | Amount | | (part by | | (part by |
| No. | composition | Type | mass) | Type | mass) | Type | (mol %) | Type | mass) | Type | mass) |
| 31 | R-31 | A-31 | 100 | B-1 | 20 | — | — | F-4 | 2 | D-1/ | 2000/ |
| | | | | | | | | | | D-2 | 4800 |
| 32 | R-32 | A-32 | 100 | B-1 | 20 | — | — | F-1 | 2 | D-1/ | 2000/ |
| | | | | | | | | | | D-2 | 4800 |
| 33 | R-33 | A-33 | 100 | — | — | — | — | F-1 | 2 | D-1/ | 2000/ |
| | | | | | | | | | | D-2 | 4800 |
| 34 | R-34 | A-34 | 100 | — | — | — | — | F-5 | 2 | D-1/ | 2000/ |
| | | | | | | | | | | D-2 | 4800 |
| 35 | R-35 | A-35 | 100 | — | — | — | — | F-2 | 2 | D-1/ | 2000/ |
| | | | | | | | | | | D-2 | 4800 |
| 36 | R-36 | A-36 | 100 | — | — | — | — | F-1 | 2 | D-1/ | 2000/ |
| | | | | | | | | | | D-2 | 4800 |
| 37 | R-37 | A-37 | 100 | B-1 | 20 | Z-1 | 25 | F-1 | 2 | D-1/ | 2000/ |
| | | | | | | | | | | D-2 | 4800 |
| 38 | R-38 | A-38 | 100 | B-1 | 20 | Z-1 | 25 | F-1 | 2 | D-1/ | 2000/ |
| | | | | | | | | | | D-2 | 4800 |
| 39 | R-39 | A-39 | 100 | B-1 | 20 | Z-1 | 25 | F-1 | 2 | D-1/ | 2000/ |
| | | | | | | | | | | D-2 | 4800 |
| 40 | R-40 | A-40 | 100 | B-1 | 20 | Z-1 | 25 | F-1 | 2 | D-1/ | 2000/ |
| | | | | | | | | | | D-2 | 4800 |
| 41 | R-41 | A-41 | 100 | B-1 | 20 | Z-1 | 25 | F-1 | 2 | D-1/ | 2000/ |
| | | | | | | | | | | D-2 | 4800 |
| 42 | R-42 | A-42 | 100 | B-1 | 20 | Z-1 | 25 | F-1 | 2 | D-1/ | 2000/ |
| | | | | | | | | | | D-2 | 4800 |
| 43 | R-43 | A-43 | 100 | B-1 | 20 | Z-1 | 25 | F-1 | 2 | D-1/ | 2000/ |
| | | | | | | | | | | D-2 | 4800 |
| 44 | R-44 | A-44 | 100 | B-1 | 20 | Z-1 | 25 | F-1 | 2 | D-1/ | 2000/ |
| | | | | | | | | | | D-2 | 4800 |
| 45 | R-45 | A-45 | 100 | B-1 | 20 | Z-1 | 25 | F-1 | 2 | D-1/ | 2000/ |
| | | | | | | | | | | D-2 | 4800 |
| 46 | R-46 | A-46 | 100 | B-1 | 20 | Z-1 | 25 | F-1 | 2 | D-1/ | 2000/ |
| | | | | | | | | | | D-2 | 4800 |
| 47 | R-47 | A-47 | 100 | B-1 | 20 | Z-1 | 25 | F-1 | 2 | D-1/ | 2000/ |
| | | | | | | | | | | D-2 | 4800 |
| 48 | R-48 | A-48 | 100 | B-1 | 20 | Z-1 | 25 | F-1 | 2 | D-1/ | 2000/ |
| | | | | | | | | | | D-2 | 4800 |
| 49 | R-49 | A-49 | 100 | B-1 | 20 | Z-1 | 25 | F-1 | 2 | D-1/ | 2000/ |
| | | | | | | | | | | D-2 | 4800 |
| 50 | R-50 | A-50 | 100 | B-1 | 20 | Z-1 | 25 | F-1 | 2 | D-1/ | 2000/ |
| | | | | | | | | | | D-2 | 4800 |
| 51 | R-51 | A-1 | 100 | B-2 | 20 | Z-1 | 25 | F-1 | 2 | D-1/ | 2000/ |
| | | | | | | | | | | D-2 | 4800 |
| 52 | R-52 | A-1 | 100 | B-3 | 20 | Z-1 | 25 | F-1 | 2 | D-1/ | 2000/ |
| | | | | | | | | | | D-2 | 4800 |
| 53 | R-53 | A-1 | 100 | B-4 | 20 | Z-1 | 25 | F-1 | 2 | D-1/ | 2000/ |
| | | | | | | | | | | D-2 | 4800 |
| 54 | R-54 | A-1 | 100 | B-5 | 20 | Z-1 | 25 | F-1 | 2 | D-1/ | 2000/ |
| | | | | | | | | | | D-2 | 4800 |
| 55 | R-55 | A-1 | 100 | B-6 | 20 | Z-1 | 25 | F-1 | 2 | D-1/ | 2000/ |
| | | | | | | | | | | D-2 | 4800 |
| 56 | R-56 | A-1 | 100 | B-7 | 20 | Z-1 | 25 | F-1 | 2 | D-1/ | 2000/ |
| | | | | | | | | | | D-2 | 4800 |
| 57 | R-57 | A-1 | 100 | B-8 | 20 | Z-1 | 25 | F-1 | 2 | D-1/ | 2000/ |
| | | | | | | | | | | D-2 | 4800 |
| 58 | R-58 | A-1 | 100 | B-9 | 20 | Z-1 | 25 | F-1 | 2 | D-1/ | 2000/ |
| | | | | | | | | | | D-2 | 4800 |
| 59 | R-59 | A-1 | 100 | B-10 | 20 | Z-1 | 25 | F-1 | 2 | D-1/ | 2000/ |
| | | | | | | | | | | D-2 | 4800 |
| 60 | R-60 | A-1 | 100 | B-11 | 20 | Z-1 | 25 | F-1 | 2 | D-1/ | 2000/ |
| | | | | | | | | | | D-2 | 4800 |

TABLE 8

| | | | | Radiation- | | | | | | | |
|---|---|---|---|---|---|---|---|---|---|---|---|
| | | | | sensitive acid- | | | | | | | |
| | | | | generating | | | | High-fluorine | | | |
| | | Base resin | | agent | | Acid diffusion | | content resin | | Organic solvent | |
| | Radiation- | | Amount | | Amount | control agent | | | Amount | | Amount |
| Example | sensitive | | (part by | | (part by | | Amount | | (part by | | (part by |
| No. | composition | Type | mass) | Type | mass) | Type | (mol %) | Type | mass) | Type | mass) |
| 61 | R-61 | A-1 | 100 | B-12 | 20 | Z-1 | 25 | F-1 | 2 | D-1/D-2 | 2000/4800 |
| 62 | R-62 | A-1 | 100 | B-1 | 20 | Z-2 | 25 | F-1 | 2 | D-1/D-2 | 2000/4800 |
| 63 | R-63 | A-1 | 100 | B-1 | 20 | Z-3 | 25 | F-1 | 2 | D-1/D-2 | 2000/4800 |
| 64 | R-64 | A-1 | 100 | B-1 | 20 | Z-4 | 25 | F-1 | 2 | D-1/D-2 | 2000/4800 |
| 65 | R-65 | A-1 | 100 | B-1 | 20 | Z-5 | 25 | F-1 | 2 | D-1/D-2 | 2000/4800 |
| 66 | R-66 | A-1 | 100 | B-1 | 20 | Z-6 | 25 | F-1 | 2 | D-1/D-2 | 2000/4800 |
| 67 | R-67 | A-1 | 100 | B-1 | 20 | Z-7 | 25 | F-1 | 2 | D-1/D-2 | 2000/4800 |
| 68 | R-68 | A-1 | 100 | B-1 | 20 | Z-8 | 25 | F-1 | 2 | D-1/D-2 | 2000/4800 |
| 69 | R-69 | A-1 | 100 | B-1 | 20 | Z-9 | 25 | F-1 | 2 | D-1/D-2 | 2000/4800 |
| 70 | R-70 | A-1 | 100 | B-1 | 20 | Z-10 | 25 | F-1 | 2 | D-1/D-2 | 2000/4800 |
| 71 | R-71 | A-1 | 100 | B-1 | 20 | Z-11 | 25 | F-1 | 2 | D-1/D-2 | 2000/4800 |
| 72 | R-72 | A-26 | 100 | B-1 | 10 | Z-1 | 25 | F-1 | 2 | D-1/D-2 | 2000/4800 |
| 73 | R-73 | A-27 | 100 | B-1 | 10 | Z-1 | 25 | F-1 | 2 | D-1/D-2 | 2000/4800 |
| 74 | R-74 | A-26 | 100 | B-4 | 10 | Z-1 | 25 | F-1 | 2 | D-1/D-2 | 2000/4800 |
| 75 | R-75 | A-26 | 100 | B-12 | 10 | Z-1 | 25 | F-1 | 2 | D-1/D-2 | 2000/4800 |
| 76 | R-76 | A-28 | 100 | B-1 | 10 | Z-1 | 12.5 | F-1 | 2 | D-1/D-2 | 2000/4800 |
| 77 | R-77 | A-28 | 100 | B-1 | 10 | Z-1 | 12.5 | F-1 | 2 | D-1/D-2 | 2000/4800 |
| 78 | R-78 | A-34 | 100 | B-1 | 10 | Z-1 | 12.5 | F-1 | 2 | D-1/D-2 | 2000/4800 |
| 79 | R-79 | A-35 | 100 | B-1 | 10 | Z-1 | 12.5 | F-1 | 2 | D-1/D-2 | 2000/4800 |

TABLE 9

| | | | | Radiation- | | | | | | | |
|---|---|---|---|---|---|---|---|---|---|---|---|
| | | | | sensitive acid- | | | | | | | |
| | | | | generating | | | | High-fluorine | | | |
| | | Base resin | | agent | | Acid diffusion | | content resin | | Organic solvent | |
| Comparative | Radiation- | | Amount | | Amount | control agent | | | Amount | | Amount |
| Example | sensitive | | (part by | | (part by | | Amount | | (part by | | (part by |
| No. | composition | Type | mass) | Type | mass) | Type | (mol %) | Type | mass) | Type | mass) |
| 1 | cR-1 | cA-1 | 100 | B-1 | 20 | Z-1 | 25 | F-1 | 2 | D-1/ | 2000/ |
| | | | | | | | | | | D-2 | 4800 |
| 2 | cR-2 | cA-2 | 100 | B-1 | 20 | Z-1 | 25 | F-1 | 2 | D-1/ | 2000/ |
| | | | | | | | | | | D-2 | 4800 |
| 3 | cR-3 | cA-3 | 100 | B-1 | 20 | Z-1 | 25 | F-1 | 2 | D-1/ | 2000/ |
| | | | | | | | | | | D-2 | 4800 |
| 4 | cR-4 | cA-4 | 100 | B-1 | 20 | Z-1 | 25 | F-1 | 2 | D-1/ | 2000/ |
| | | | | | | | | | | D-2 | 4800 |
| 5 | cR-5 | cA-5 | 100 | B-1 | 20 | Z-1 | 25 | F-1 | 2 | D-1/ | 2000/ |
| | | | | | | | | | | D-2 | 4800 |
| 6 | cR-6 | cA-6 | 100 | B-1 | 20 | Z-1 | 25 | F-1 | 2 | D-1/ | 2000/ |
| | | | | | | | | | | D-2 | 4800 |
| 7 | cR-7 | cA-7 | 100 | B-1 | 20 | Z-1 | 25 | F-1 | 2 | D-1/ | 2000/ |
| | | | | | | | | | | D-2 | 4800 |
| 8 | cR-8 | cA-8 | 100 | B-1 | 20 | Z-1 | 25 | F-1 | 2 | D-1/ | 2000/ |
| | | | | | | | | | | D-2 | 4800 |
| 9 | cR-9 | cA-9 | 100 | B-1 | 20 | Z-1 | 25 | F-1 | 2 | D-1/ | 2000/ |
| | | | | | | | | | | D-2 | 4800 |
| 10 | cR-10 | cA-10 | 100 | B-1 | 20 | Z-1 | 25 | F-1 | 2 | D-1/ | 2000/ |
| | | | | | | | | | | D-2 | 4800 |
| 11 | cR-11 | cA-11 | 100 | B-1 | 20 | Z-1 | 25 | F-2 | 2 | D-1/ | 2000/ |
| | | | | | | | | | | D-2 | 4800 |
| 12 | cR-12 | cA-12 | 100 | B-1 | 20 | Z-1 | 25 | F-1 | 2 | D-1/ | 2000/ |
| | | | | | | | | | | D-2 | 4800 |
| 13 | cR-13 | cA-13 | 100 | B-1 | 20 | Z-1 | 25 | F-3 | 2 | D-1/ | 2000/ |
| | | | | | | | | | | D-2 | 4800 |
| 14 | cR-14 | cA-14 | 100 | B-1 | 20 | Z-1 | 25 | F-1 | 2 | D-1/ | 2000/ |
| | | | | | | | | | | D-2 | 4800 |
| 15 | cR-15 | cA-15 | 100 | B-1 | 20 | Z-1 | 25 | F-1 | 2 | D-1/ | 2000/ |
| | | | | | | | | | | D-2 | 4800 |
| 16 | cR-16 | cA-16 | 100 | B-1 | 20 | Z-1 | 25 | F-1 | 2 | D-1/ | 2000/ |
| | | | | | | | | | | D-2 | 4800 |
| 17 | cR-17 | cA-17 | 100 | B-1 | 20 | Z-1 | 25 | F-1 | 2 | D-1/ | 2000/ |
| | | | | | | | | | | D-2 | 4800 |
| 18 | cR-18 | cA-18 | 100 | B-1 | 20 | Z-1 | 25 | F-1 | 2 | D-1/ | 2000/ |
| | | | | | | | | | | D-2 | 4800 |
| 19 | cR-19 | cA-19 | 100 | B-1 | 20 | Z-1 | 25 | F-1 | 2 | D-1/ | 2000/ |
| | | | | | | | | | | D-2 | 4800 |
| 20 | cR-20 | cA-20 | 100 | B-1 | 20 | Z-1 | 25 | F-1 | 2 | D-1/ | 2000/ |
| | | | | | | | | | | D-2 | 4800 |
| 21 | cR-21 | cA-21 | 100 | — | — | Z-1 | 25 | F-1 | 2 | D-1/ | 2000/ |
| | | | | | | | | | | D-2 | 4800 |
| 22 | cR-22 | cA-22 | 100 | — | — | Z-1 | 25 | F-2 | 2 | D-1/ | 2000/ |
| | | | | | | | | | | D-2 | 4800 |
| 23 | cR-23 | cA-23 | 100 | — | — | Z-1 | 25 | F-1 | 2 | D-1/ | 2000/ |
| | | | | | | | | | | D-2 | 4800 |
| 24 | cR-24 | cA-24 | 100 | — | — | Z-1 | 25 | F-1 | 2 | D-1/ | 2000/ |
| | | | | | | | | | | D-2 | 4800 |
| 25 | cR-25 | cA-25 | 100 | — | — | Z-1 | 25 | F-1 | 2 | D-1/ | 2000/ |
| | | | | | | | | | | D-2 | 4800 |

TABLE 10

| | | | | Radiation- | | | | | | | |
|---|---|---|---|---|---|---|---|---|---|---|---|
| | | | | sensitive acid- | | | | | | | |
| | | | | generating | | | | High-fluorine | | | |
| | | Base resin | | agent | | Acid diffusion | | content resin | | Organic solvent | |
| Comparative | Radiation- | | Amount | | Amount | control agent | | | Amount | | Amount |
| Example | sensitive | | (part by | | (part by | | Amount | | (part by | | (part by |
| No. | composition | Type | mass) | Type | mass) | Type | (mol %) | Type | mass) | Type | mass) |
| 26 | cR-26 | cA-26 | 100 | — | — | Z-1 | 25 | F-1 | 2 | D-1/ | 2000/ |
| | | | | | | | | | | D-2 | 4800 |
| 27 | cR-27 | cA-27 | 100 | — | — | Z-1 | 25 | F-1 | 2 | D-1/ | 2000/ |
| | | | | | | | | | | D-2 | 4800 |
| 28 | cR-28 | cA-28 | 100 | B-1 | 20 | — | — | F-1 | 2 | D-1/ | 2000/ |
| | | | | | | | | | | D-2 | 4800 |
| 29 | cR-29 | cA-29 | 100 | B-1 | 20 | — | — | F-1 | 2 | D-1/ | 2000/ |
| | | | | | | | | | | D-2 | 4800 |
| 30 | cR-30 | cA-30 | 100 | B-1 | 20 | — | — | F-1 | 2 | D-1/ | 2000/ |
| | | | | | | | | | | D-2 | 4800 |
| 31 | cR-31 | cA-31 | 100 | B-1 | 20 | — | — | F-4 | 2 | D-1/ | 2000/ |
| | | | | | | | | | | D-2 | 4800 |
| 32 | cR-32 | cA-32 | 100 | B-1 | 20 | — | — | F-1 | 2 | D-1/ | 2000/ |
| | | | | | | | | | | D-2 | 4800 |
| 33 | cR-33 | cA-33 | 100 | — | — | — | — | F-1 | 2 | D-1/ | 2000/ |
| | | | | | | | | | | D-2 | 4800 |
| 34 | cR-34 | cA-34 | 100 | — | — | — | — | F-5 | 2 | D-1/ | 2000/ |
| | | | | | | | | | | D-2 | 4800 |
| 35 | cR-35 | cA-35 | 100 | — | — | — | — | F-2 | 2 | D-1/ | 2000/ |
| | | | | | | | | | | D-2 | 4800 |
| 36 | cR-36 | cA-36 | 100 | — | — | — | — | F-1 | 2 | D-1/ | 2000/ |
| | | | | | | | | | | D-2 | 4800 |
| 37 | cR-37 | cA-1 | 100 | B-2 | 20 | Z-1 | 25 | F-1 | 2 | D-1/ | 2000/ |
| | | | | | | | | | | D-2 | 4800 |
| 38 | cR-38 | cA-1 | 100 | B-3 | 20 | Z-1 | 25 | F-1 | 2 | D-1/ | 2000/ |
| | | | | | | | | | | D-2 | 4800 |
| 39 | cR-39 | cA-1 | 100 | B-4 | 20 | Z-1 | 25 | F-1 | 2 | D-1/ | 2000/ |
| | | | | | | | | | | D-2 | 4800 |
| 40 | cR-40 | cA-1 | 100 | B-5 | 20 | Z-1 | 25 | F-1 | 2 | D-1/ | 2000/ |
| | | | | | | | | | | D-2 | 4800 |
| 41 | cR-41 | cA-1 | 100 | B-6 | 20 | Z-1 | 25 | F-1 | 2 | D-1/ | 2000/ |
| | | | | | | | | | | D-2 | 4800 |
| 42 | cR-42 | cA-1 | 100 | B-7 | 20 | Z-1 | 25 | F-1 | 2 | D-1/ | 2000/ |
| | | | | | | | | | | D-2 | 4800 |
| 43 | cR-43 | cA-1 | 100 | B-8 | 20 | Z-1 | 25 | F-1 | 2 | D-1/ | 2000/ |
| | | | | | | | | | | D-2 | 4800 |
| 44 | cR-44 | cA-1 | 100 | B-9 | 20 | Z-1 | 25 | F-1 | 2 | D-1/ | 2000/ |
| | | | | | | | | | | D-2 | 4800 |
| 45 | cR-45 | cA-1 | 100 | B-10 | 20 | Z-1 | 25 | F-1 | 2 | D-1/ | 2000/ |
| | | | | | | | | | | D-2 | 4800 |
| 46 | cR-46 | cA-1 | 100 | B-11 | 20 | Z-1 | 25 | F-1 | 2 | D-1/ | 2000/ |
| | | | | | | | | | | D-2 | 4800 |
| 47 | cR-47 | cA-1 | 100 | B-12 | 20 | Z-1 | 25 | F-1 | 2 | D-1/ | 2000/ |
| | | | | | | | | | | D-2 | 4800 |
| 48 | cR-48 | cA-1 | 100 | B-1 | 20 | Z-2 | 25 | F-1 | 2 | D-1/ | 2000/ |
| | | | | | | | | | | D-2 | 4800 |
| 49 | cR-49 | cA-1 | 100 | B-1 | 20 | Z-3 | 25 | F-1 | 2 | D-1/ | 2000/ |
| | | | | | | | | | | D-2 | 4800 |
| 50 | cR-50 | cA-1 | 100 | B-1 | 20 | Z-4 | 25 | F-1 | 2 | D-1/ | 2000/ |
| | | | | | | | | | | D-2 | 4800 |

TABLE 11

| | | | | Radiation- | | | | | | | |
|---|---|---|---|---|---|---|---|---|---|---|---|
| | | | | sensitive acid- | | | | | | | |
| | | | | generating | | | | High-fluorine | | | |
| | | Base resin | | agent | | Acid diffusion | | content resin | | Organic solvent | |
| Comparative | Radiation- | | Amount | | Amount | control agent | | | Amount | | Amount |
| Example | sensitive | | (part by | | (part by | | Amount | | (part by | | (part by |
| No. | composition | Type | mass) | Type | mass) | Type | (mol %) | Type | mass) | Type | mass) |
| 51 | cR-51 | cA-1 | 100 | B-1 | 20 | Z-5 | 25 | F-1 | 2 | D-1/ | 2000/ |
| | | | | | | | | | | D-2 | 4800 |
| 52 | cR-52 | cA-1 | 100 | B-1 | 20 | Z-6 | 25 | F-1 | 2 | D-1/ | 2000/ |
| | | | | | | | | | | D-2 | 4800 |
| 53 | cR-53 | cA-1 | 100 | B-1 | 20 | Z-7 | 25 | F-1 | 2 | D-1/ | 2000/ |
| | | | | | | | | | | D-2 | 4800 |
| 54 | cR-54 | cA-1 | 100 | B-1 | 20 | Z-8 | 25 | F-1 | 2 | D-1/ | 2000/ |
| | | | | | | | | | | D-2 | 4800 |
| 55 | cR-55 | cA-1 | 100 | B-1 | 20 | Z-9 | 25 | F-1 | 2 | D-1/ | 2000/ |
| | | | | | | | | | | D-2 | 4800 |
| 56 | cR-56 | cA-1 | 100 | B-1 | 20 | Z-10 | 25 | F-1 | 2 | D-1/ | 2000/ |
| | | | | | | | | | | D-2 | 4800 |
| 57 | cR-57 | cA-1 | 100 | B-1 | 20 | Z-11 | 25 | F-1 | 2 | D-1/ | 2000/ |
| | | | | | | | | | | D-2 | 4800 |
| 58 | cR-58 | cA-26 | 100 | B-1 | 10 | Z-1 | 25 | F-1 | 2 | D-1/ | 2000/ |
| | | | | | | | | | | D-2 | 4800 |
| 59 | cR-59 | cA-27 | 100 | B-1 | 10 | Z-1 | 25 | F-1 | 2 | D-1/ | 2000/ |
| | | | | | | | | | | D-2 | 4800 |
| 60 | cR-60 | cA-26 | 100 | B-4 | 10 | Z-1 | 25 | F-1 | 2 | D-1/ | 2000/ |
| | | | | | | | | | | D-2 | 4800 |
| 61 | cR-61 | cA-26 | 100 | B-12 | 10 | Z-1 | 25 | F-1 | 2 | D-1/ | 2000/ |
| | | | | | | | | | | D-2 | 4800 |
| 62 | cR-62 | cA-28 | 100 | B-1 | 10 | Z-1 | 12.5 | F-1 | 2 | D-1/ | 2000/ |
| | | | | | | | | | | D-2 | 4800 |
| 63 | cR-63 | cA-28 | 100 | B-1 | 10 | Z-1 | 12.5 | F-1 | 2 | D-1/ | 2000/ |
| | | | | | | | | | | D-2 | 4800 |
| 64 | cR-64 | cA-34 | 100 | B-1 | 10 | Z-1 | 12.5 | F-1 | 2 | D-1/ | 2000/ |
| | | | | | | | | | | D-2 | 4800 |
| 65 | cR-65 | cA-35 | 100 | B-1 | 10 | Z-1 | 12.5 | F-1 | 2 | D-1/ | 2000/ |
| | | | | | | | | | | D-2 | 4800 |

### 5. Formation of Resist Pattern (EUV Light Exposure and Alkali Development)

By use of each of the above-prepared radiation-sensitive compositions, a resist pattern was formed through the following procedure.

### <Formation of Resist Pattern>

A 12-inch silicon wafer having an under-layer film having a thickness of 20 nm (AL-412, product of Brewer Science, Inc.) was used. Onto the surface of the wafer, each of the above-prepared radiation-sensitive compositions was applied by means of a spin coater (CLEANl TRACK ACT12, product of Tokyo Electron Ltd.). The wafer was subjected to SB at 130° C. for 60 seconds and then cooled at 23° C. for 30 seconds, to thereby form a resist film having a thickness of 50 nm. Subsequently, the resist film was irradiated with EUV light by means of an EUV exposure device (NXE3400, product of ASML, NA=0.33, lighting condition: Conventional s=0.89). After completion of exposure to EUV light, the resist film was subjected to PEB at 110° C. for 60 seconds. Then, development was performed by use of 2.38 wt % aqueous TMAH at 23° C. for 30 seconds, to thereby form a positive-type line-and-space pattern (32 nm).

### 6. Evaluation

Each of the formed resist patterns was evaluated in terms of sensitivity, LWR performance, and minimum CD (i.e., resolution) of each radiation-sensitive composition, through the below-mentioned measurement procedures. Notably, dimensions of the resist pattern were measured under a scanning electron microscope (CG-5000, product of Hitachi High Technology Co., Ltd.). Tables 12 to 15 show the results of evaluation.

### [Sensitivity]

In the resist pattern formation, a dose which can form a line-and-space pattern having a width of 32 nm was employed as an optimum dose, and the sensitivity was evaluated by the optimum dose (unit: mJ/cm²). The case in which the sensitivity was lower than 30 mJ/cm² was evaluated as “A”; the case in which the sensitivity was 30 m J/cm² or higher and lower than 33 mJ/cm² was evaluated as “B”; and the case in which the sensitivity was 33 mJ/cm² or higher was evaluated as “C.”

### [LWR Performance]

The resist pattern formed through exposure to EUV light was observed from above under the aforementioned scanning electron microscope. The line width was measured at 50 points selected at random, and the 36 value was determined from the distribution of the measurements. The 36 value was employed as an LWR (unit: nm). Regarding LWR performance, the case in which LWR was less than 2.8 nm was evaluated as “A”; the case in which LWR was 2.8 nm or more and less than 3.0 nm was evaluated as “B”; and the case in which LWR was 3.0 nm or more was evaluated as “C.”

### [Minimum CD]

In a resist pattern formed by exposure to EUV light, the minimum space pattern width achieving resolution which does not cause bridge failure or residual failure was employed as minimum CD (nm). The case of the minimum CD less than 13 nm was evaluated as “A”; the case of the minimum CD of 13 nm or more and less than 15 nm was evaluated as “B”; and the case of the minimum CD of 15 nm or more was evaluated as “C.”

TABLE 12

| | Radiation- | | | |
|---|---|---|---|---|
| Example | sensitive | Eop | LWR | Minimum |
| No. | composition | (mJ/cm²) | (nm) | CD(nm) |
| 1 | R-1 | B | B | B |
| 2 | R-2 | B | B | B |
| 3 | R-3 | B | B | B |
| 4 | R-4 | B | B | B |
| 5 | R-5 | B | B | B |
| 6 | R-6 | A | B | B |
| 7 | R-7 | B | B | B |
| 8 | R-8 | B | B | B |
| 9 | R-9 | B | B | B |
| 10 | R-10 | B | B | B |
| 11 | R-11 | B | B | B |
| 12 | R-12 | A | B | B |
| 13 | R-13 | B | B | B |
| 14 | R-14 | B | B | B |
| 15 | R-15 | B | B | B |
| 16 | R-16 | B | B | B |
| 17 | R-17 | B | B | B |
| 18 | R-18 | B | B | B |
| 19 | R-19 | B | B | B |
| 20 | R-20 | B | B | B |
| 21 | R-21 | B | B | A |
| 22 | R-22 | B | B | A |
| 23 | R-23 | B | B | A |
| 24 | R-24 | B | B | A |
| 25 | R-25 | B | B | A |
| 26 | R-26 | B | B | A |
| 27 | R-27 | B | B | A |
| 28 | R-28 | B | B | A |
| 29 | R-29 | B | B | A |
| 30 | R-30 | B | B | B |
| 31 | R-31 | B | B | B |
| 32 | R-32 | B | B | B |
| 33 | R-33 | B | A | A |
| 34 | R-34 | B | A | A |
| 35 | R-35 | B | A | A |
| 36 | R-36 | B | A | A |
| 37 | R-37 | B | B | B |
| 38 | R-38 | B | B | B |
| 39 | R-39 | B | B | B |
| 40 | R-40 | B | B | B |
| 41 | R-41 | B | B | B |
| 42 | R-42 | B | B | B |
| 43 | R-43 | B | B | B |
| 44 | R-44 | B | B | B |
| 45 | R-45 | B | B | B |
| 46 | R-46 | B | B | B |
| 47 | R-47 | B | B | B |
| 48 | R-48 | B | B | B |
| 49 | R-49 | B | B | B |
| 50 | R-50 | B | B | B |

TABLE 13

| | Radiation- | | | |
|---|---|---|---|---|
| Example | sensitive | Eop | LWR | Minimum |
| No. | composition | (mJ/cm²) | (nm) | CD(nm) |
| 51 | R-51 | B | B | B |
| 52 | R-52 | B | B | B |
| 53 | R-53 | C | B | B |
| 54 | R-54 | C | B | B |
| 55 | R-55 | C | B | B |
| 56 | R-56 | C | B | B |
| 57 | R-57 | C | B | B |
| 58 | R-58 | B | B | B |
| 59 | R-59 | B | B | B |
| 60 | R-60 | B | B | B |
| 61 | R-61 | B | B | B |
| 62 | R-62 | B | B | B |
| 63 | R-63 | A | B | B |
| 64 | R-64 | B | B | B |
| 65 | R-65 | B | B | B |
| 66 | R-66 | B | B | B |
| 67 | R-67 | B | B | B |
| 68 | R-68 | B | B | B |
| 69 | R-69 | A | B | B |
| 70 | R-70 | B | A | A |
| 71 | R-71 | B | A | A |
| 72 | R-72 | B | A | A |
| 73 | R-73 | B | A | A |
| 74 | R-74 | B | A | A |
| 75 | R-75 | B | A | A |
| 76 | R-76 | B | A | A |
| 77 | R-77 | B | A | A |
| 78 | R-78 | B | A | A |
| 79 | R-79 | B | A | A |

TABLE 14

| | Radiation- | | | |
|---|---|---|---|---|
| Comparative | sensitive | Eop | LWR | Minimum |
| Example No. | composition | (mJ/cm²) | (nm) | CD(nm) |
| 1 | cR-1 | C | C | C |
| 2 | cR-2 | C | C | C |
| 3 | cR-3 | C | C | C |
| 4 | cR-4 | C | C | C |
| 5 | cR-5 | C | C | C |
| 6 | cR-6 | B | C | C |
| 7 | cR-7 | C | C | C |
| 8 | cR-8 | C | C | C |
| 9 | cR-9 | C | C | C |
| 10 | cR-10 | C | C | C |
| 11 | cR-11 | C | C | C |
| 12 | cR-12 | B | C | C |
| 13 | cR-13 | C | C | C |
| 14 | cR-14 | C | C | C |
| 15 | cR-15 | C | C | C |

TABLE 15

| | Radiation- | | | |
|---|---|---|---|---|
| Comparative | sensitive | Eop | LWR | Minimum |
| Example No. | composition | (mJ/cm²) | (nm) | CD(nm) |
| 16 | cR-16 | C | C | C |
| 17 | cR-17 | C | C | C |
| 18 | cR-18 | C | C | C |
| 19 | cR-19 | C | C | C |
| 20 | cR-20 | C | C | C |
| 21 | cR-21 | C | C | B |
| 22 | cR-22 | C | C | B |
| 23 | cR-23 | C | C | B |
| 24 | cR-24 | C | C | B |
| 25 | cR-25 | C | C | B |
| 26 | cR-26 | C | C | B |
| 27 | cR-27 | C | C | B |
| 28 | cR-28 | C | C | B |
| 29 | cR-29 | C | C | B |
| 30 | cR-30 | C | B | B |
| 31 | cR-31 | C | B | B |
| 32 | cR-32 | C | B | B |
| 33 | cR-33 | C | B | B |
| 34 | cR-34 | C | B | B |
| 35 | cR-35 | C | B | B |
| 36 | cR-36 | C | B | B |
| 37 | cR-37 | C | C | C |
| 38 | cR-38 | C | C | C |
| 39 | cR-39 | C | C | C |
| 40 | cR-40 | C | C | C |
| 41 | cR-41 | C | C | C |
| 42 | cR-42 | C | C | C |
| 43 | cR-43 | C | C | C |
| 44 | cR-44 | C | C | C |
| 45 | cR-45 | C | C | C |
| 46 | cR-46 | C | C | C |
| 47 | cR-47 | C | C | C |
| 48 | cR-48 | C | C | C |
| 49 | cR-49 | B | C | C |
| 50 | cR-50 | C | C | C |
| 51 | cR-51 | C | C | C |
| 52 | cR-52 | C | C | C |
| 53 | cR-53 | C | C | C |
| 54 | cR-54 | C | C | C |
| 55 | cR-55 | B | C | C |
| 56 | cR-56 | C | B | B |
| 57 | cR-57 | C | B | B |
| 58 | cR-58 | C | B | B |
| 59 | cR-59 | C | B | B |
| 60 | cR-60 | C | B | B |
| 61 | cR-61 | C | B | B |
| 62 | cR-62 | C | B | B |
| 63 | cR-63 | C | B | B |
| 64 | cR-64 | C | B | B |
| 65 | cR-65 | C | B | B |

As is clear from Tables 12 to 15, the radiation-sensitive compositions of Examples 1 to 79 were found to be evaluated by the score A or B in terms of sensitivity, LWR, and minimum CD, or by only one score C. Thus, sensitivity, LWR performance, and resolution were found to be improved in a well-balanced manner. Particularly, all of the radiation-sensitive compositions of Examples 1 to 79 were evaluated by A or B in terms of LWR and minimum CD, which were superior to those of the radiation-sensitive compositions of Comparative Examples 1 to 65.

According to the aforementioned radiation-sensitive composition and resist pattern formation method, there can be formed a resist composition which has suitable sensitivity to exposure light and a resist pattern having excellent LWR performance and high resolution. Thus, the present composition and formation method can be suitably employed in a semiconductor device process or the like in which further process shrinkage will proceed.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising a polymer represented by formula (1): 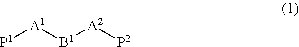
wherein each of A¹ and A² independently represents a group represented by formula (a-1), (a-2), (a-3), or (a-4): 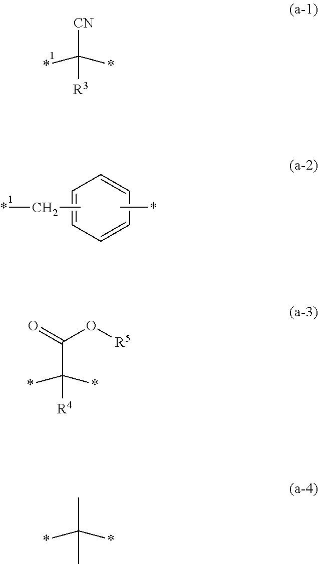
wherein each of R³, R⁴, and R⁵ independently represents a monovalent hydrocarbon group; *1 represents a chemical bond to P¹ or P²; and * represents a chemical bond;
B¹ represents a divalent group comprising a partial structure that can cleave the bond between A¹ and A² via B¹ by an action of acid; and
each of P¹ and P² independently represents a molecular chain.

2. The radiation-sensitive composition according to claim 1, wherein at least one of P¹ and P² in the formula (1) comprises a structural unit comprising an acid-releasable group.

3. The radiation-sensitive composition according to claim 1, wherein at least one of P¹ and P² in the formula (1) comprises a structural unit comprising an aromatic ring and a hydroxy group bound to the aromatic ring.

4. The radiation-sensitive composition according to claim 1, wherein at least one of P¹ and P² in the formula (1) comprises a structural unit comprising a partial structure derived from a radiation-sensitive acid-generator.

5. The radiation-sensitive composition according to claim 1, wherein B¹ in the formula (1), in a main chain of the polymer, comprises at least one selected from the group consisting of a tertiary carbon atom bound to an oxygen atom, a benzyl-position carbon atom bound to an oxygen atom, an allyl-position carbon atom bound to an oxygen atom, and a (thio)acetal ring.

6. The radiation-sensitive composition according to claim 1, wherein B¹ in the formula (1) comprises a partial structure represented by formula (b-1), (b-2), or (b-3): 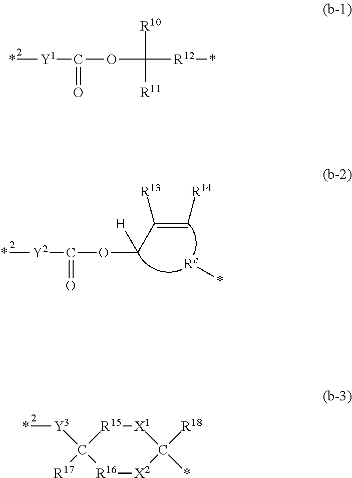
wherein, in the formula (b-1), R¹⁰ represents a C1 to C10 monovalent chain hydrocarbon group or a C3 to C20 monovalent alicyclic hydrocarbon group; R¹¹ represents a C1 to C10 monovalent chain hydrocarbon group or a C3 to C20 monovalent alicyclic hydrocarbon group, and R¹² represents a C1 to C20 divalent hydrocarbon group, or R¹¹ represents a hydrogen atom, and R¹² represents a C6 to C14 monovalent aromatic ring group, or R¹¹ and R¹² taken together represent a C3 to C20 alicyclic structure with the carbon atom to which R¹¹ and R¹² are bound; Y¹ represents a single bond or a divalent linking group; *2 represents a chemical bond to A¹ or A² in the formula (1); and * represents a chemical bond;
in the formula (b-2), each of R¹³ and R¹⁴ independently represents a hydrogen atom or a C1 to C20 monovalent hydrocarbon group, or R¹³ and R¹⁴ taken together represent a ring structure together with the carbon atom to which R¹³ is bound and the carbon atom to which R¹⁴ is bound; R^{c} represents an unsaturated alicyclic structure formed with the two carbon atoms in the formula (b-2) to which R^{c} is bound and a carbon atom to which R¹³ is bound; Y² represents a single bond or a divalent linking group; *2 represents a chemical bond to A¹ or A² in the formula (1); and * represents a chemical bond; and
in the formula (b-3), each of X¹ and X² independently represents an oxygen atom or a sulfur atom; R¹⁵ represents a single bond or a C1 to C10 alkanediyl group; R¹⁶ represents a C1 to C10 alkanediyl group; each of R¹⁷ and R¹⁸ independently represents a hydrogen atom or a C1 to C10 monovalent hydrocarbon group; Y³ represents a divalent linking group; “*2” represents a chemical bond to A¹ or A² in the formula (1); and * represents a chemical bond.

7. A resist pattern formation method, the method comprising
forming a resist film on a substrate by applying the radiation-sensitive composition according to claim 1;
exposing the resist film to light; and
developing the light-exposed resist film.

8. A polymer represented by formula (1): 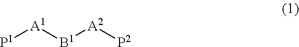
wherein each of A¹ and A² independently represents a group represented by formula (a-1), (a-2), (a-3), or (a-4): 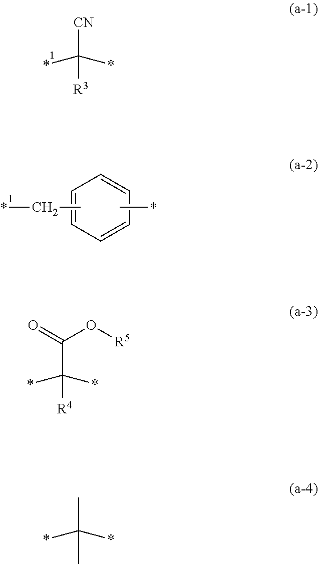
wherein each of R³, R⁴, and R⁵ independently represents a monovalent hydrocarbon group; *1 represents a chemical bond to P¹ or P²; and * represents a chemical bond;
B¹ represents a divalent group comprising a partial structure that can cleave the bond between A¹ and A² via B¹ by an action of acid; and
each of P¹ and P² independently represents a molecular chain.

9. A method for producing the polymer according to claim 1, the method comprising polymerizing a monomer in a presence of a compound represented by formula (2): 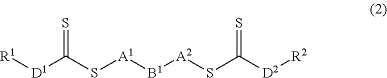
wherein each of A¹ and A² independently represents a group represented by formula (a-1), (a-2), (a-3), or (a-4): 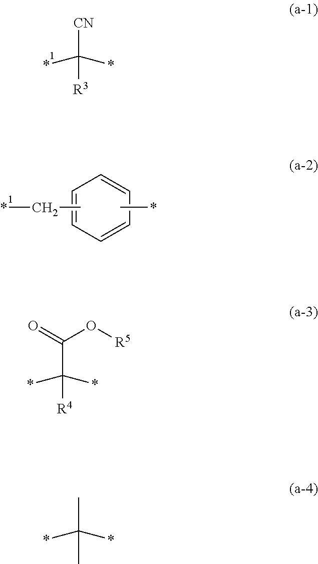
wherein each of R³, R⁴, and R⁵ independently represents a monovalent hydrocarbon group; *1 represents a chemical bond to the sulfur atom; and * represents a chemical bond;
B¹ represents a divalent group comprising a partial structure in which a bonding between A¹ and A² via B¹ can be broken by an action of acid;
each of D¹ and D² independently represents a sulfur atom, an oxygen atom, —NR⁷—, a phenylene group, or a divalent nitrogen-containing heterocyclic group;
R⁷ represents a hydrogen atom or a monovalent hydrocarbon group; and
each of R¹ and R² independently represents a hydrogen atom or a monovalent organic group.

10. The method according to claim 9, wherein the monomer comprises a compound comprising an acid-releasable group.

11. The method according to claim 9, wherein monomer comprises a compound comprising an aromatic ring to which a hydroxy group or a protected hydroxy group is bound.

12. A compound represented by formula (2): 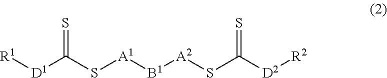
wherein each of A¹ and A² independently represents a group represented by formula (a-1), (a-2), (a-3), or (a-4): 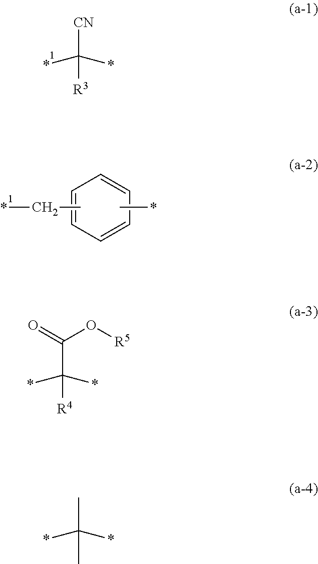
wherein each of R³, R⁴, and R⁵ independently represents a monovalent hydrocarbon group; *1 represents a chemical bond to the sulfur atom; and * represents a chemical bond;
B¹ represents a divalent group comprising a partial structure in which the bonding between A¹ and A² via B¹ can be broken by an action of acid; each of D¹ and D² independently represents a sulfur atom, an oxygen atom, —NR⁷—, a phenylene group, or a divalent nitrogen-containing heterocyclic group; R⁷ represents a hydrogen atom or a monovalent hydrocarbon group; and each of R¹ and R² independently represents a hydrogen atom or a monovalent organic group.
